(19) United States
(12) Patent Application Publication
(10) Pub. No.: US 2026/0223438 A1
(43) Pub. Date: Jul. 30, 2026

(54) SEMICONDUCTOR DEVICE

(71) Applicant: ROHM CO., LTD., Kyoto-shi (JP)

(72) Inventor: Nobutaka OI, Kyoto-shi (JP)

(73) Assignee: ROHM CO., LTD., Kyoto-shi (JP)

(21) Appl. No.: 19/578,952

(22) Filed: Mar. 26, 2026

Related U.S. Application Data
(63) Continuation of application No. PCT/JP2024/033664, filed on Sep. 20, 2024.

(30) Foreign Application Priority Data
Sep. 28, 2023 (JP) 2023-168421

(51) Int. Cl. H10D 84/00; H10D 1/66; H10D 8/00; H10D 12/00; H10D 30/66; H10D 62/10; H10D 62/60; H10D 64/23; H10D 64/27

(52) U.S. Cl. CPC H10D 84/161; H10D 1/665; H10D 8/411; H10D 12/481; H10D 62/126; H10D 64/232; H10D 64/518; H10D 30/668; H10D 62/60; H10D 84/143

(57) ABSTRACT

A semiconductor device includes a chip having a main surface, an active region provided in the main surface, a pad region provided outside the active region in the main surface, a transistor structure formed in the main surface in the active region, and a capacitor structure of a trench electrode type that is formed in the main surface in the pad region and forms capacitive coupling with the chip.

### CROSS-REFERENCE TO RELATED APPLICATIONS

The present application is a bypass continuation of International Patent Application No. PCT/JP 2024/033664 filed on Sep. 20, 2024, which claims priority to Japanese Patent Application No. 2023-168421 filed on Sep. 28, 2023 in the Japan Patent Office, and the entire contents of those applications are hereby incorporated herein by reference.

### BACKGROUND

### 1. Field of the Disclosure

The present disclosure relates to a semiconductor device.

### 2. Description of the Related Art

US 2023/0106733 A1 discloses a semiconductor device including a semiconductor substrate, a trench gate structure, an interlayer insulating film, a source electrode, a separation insulation film, and a gate pad. The trench gate structure is formed in the semiconductor substrate. The interlayer insulating film is formed on the trench gate structure. The source electrode is formed on the interlayer insulating film. The separation insulation film is formed on the source electrode. The gate pad is arranged on the source electrode via the separation insulation film.

### BRIEF DESCRIPTION OF THE DRAWINGS

FIG. 1 is a circuit diagram showing an electrical arrangement example of a semiconductor device according to a first embodiment.

FIG. 2 is a plan view of the semiconductor device shown in FIG. 1.

FIG. 3 is a plan view showing a layout example of a first main surface.

FIG. 4 is an enlarged plan view showing a principal portion of an active region.

FIG. 5 is an enlarged plan view showing another principal portion of the active region.

FIG. 6 is a sectional view taken along line VI-VI shown in FIG. 4.

FIG. 7 is a sectional view taken along line VII-VII shown in FIG. 4.

FIG. 8 is a sectional view taken along line VIII-VIII shown in FIG. 5.

FIG. 9 is an enlarged plan view showing a principal portion of a monitor region.

FIG. 10 is a sectional view taken along line X-X shown in FIG. 9.

FIG. 11 is a sectional view taken along line XI-XI shown in FIG. 9.

FIG. 12 is an enlarged plan view showing a temperature detecting region.

FIG. 13 is a sectional view taken along line XIII-XIII shown in FIG. 12.

FIG. 14 is an enlarged plan view showing an arrangement in a pad region together with a pad structure according to a first layout example and a pad opening according to the first layout example.

FIG. 15 is an enlarged plan view showing a principal portion of the pad region.

FIG. 16 is a sectional view taken along line XVI-XVI shown in FIG. 15.

FIG. 17 is a sectional view taken along line XVII-XVII shown in FIG. 15.

FIG. 18A is a plan view showing a pad structure according to a second layout example.

FIG. 18B is a plan view showing a pad structure according to a third layout example.

FIG. 18C is a plan view showing a pad structure according to a fourth layout example.

FIG. 18D is a plan view showing a pad structure according to a fifth layout example.

FIG. 18E is a plan view showing a pad structure according to a sixth layout example.

FIG. 18F is a plan view showing a pad structure according to a seventh layout example.

FIG. 18G is a plan view showing a pad structure according to an eighth layout example.

FIG. 18H is a plan view showing a pad structure according to a ninth layout example.

FIG. 18I is a plan view showing a pad structure according to a tenth layout example.

FIG. 18J is a plan view showing a pad structure according to an eleventh layout example.

FIG. 18K is a plan view showing a pad structure according to a twelfth layout example.

FIG. 18L is a plan view showing a pad structure according to a thirteenth layout example.

FIG. 18M is a plan view showing a pad structure according to a fourteenth layout example.

FIG. 18N is a plan view showing a pad structure according to a fifteenth layout example.

FIG. 18O is a plan view showing a pad structure according to a sixteenth layout example.

FIG. 18P is a plan view showing a pad structure according to a seventeenth layout example.

FIG. 18Q is a plan view showing a pad structure according to an eighteenth layout example.

FIG. 18R is a plan view showing a pad structure according to a nineteenth layout example.

FIG. 19A is a plan view showing a pad opening according to a second layout example.

FIG. 19B is a plan view showing a pad opening according to a third layout example.

FIG. 19C is a plan view showing a pad opening according to a fourth layout example.

FIG. 19D is a plan view showing a pad opening according to a fifth layout example.

FIG. 19E is a plan view showing a pad opening according to a sixth layout example.

FIG. 19F is a plan view showing a pad opening according to a seventh layout example.

FIG. 20 is a plan view for explaining an electric test on a gate pad electrode side.

FIG. 21 is a plan view for explaining an electric test on a monitor pad electrode side.

FIG. 22 is a plan view for explaining an electric test on an anode pad electrode side.

FIG. 23 is a plan view for explaining an electric test on a cathode pad electrode side.

FIG. 24 is a plan view showing a layout example of a first main surface of a semiconductor device according to a second embodiment.

FIG. 25 is an enlarged plan view showing a principal portion of an active region of the semiconductor device shown in FIG. 24.

FIG. 26 is a sectional view taken along line XXVI-XXVI shown in FIG. 25.

FIG. 27 is a sectional view showing a principal portion of a semiconductor device according to a third embodiment.

FIG. 28 is a sectional view showing a principal portion of a semiconductor device according to a fourth embodiment.

FIG. 29 is a sectional view showing a principal portion of a semiconductor device according to a fifth embodiment.

FIG. 30 is a plan view showing a pad region of a semiconductor device according to a sixth embodiment.

FIG. 31 is an enlarged plan view showing a principal portion of the pad region shown in FIG. 30.

FIG. 32 is a sectional view taken along line XXXII-XXXII shown in FIG. 31.

FIG. 33 is a plan view showing a first modification example of the semiconductor devices according to the first to sixth embodiments.

FIG. 34 is a plan view showing a second modification example of the semiconductor devices according to the first to sixth embodiments.

FIG. 35 is a plan view showing a third modification example of the semiconductor devices according to the first to sixth embodiments.

FIG. 36 is a plan view showing a fourth modification example of the semiconductor devices according to the first to sixth embodiments.

### DETAILED DESCRIPTION OF THE PREFERRED EMBODIMENTS

Hereinafter, specific embodiments shall be described in detail with reference to attached drawings. The attached drawings are all schematic views and are not strictly illustrated, and relative positional relationships, scales, proportions, angles and the like thereof do not always match. Identical reference signs are given to corresponding structures among the attached drawings, and duplicate descriptions thereof shall be omitted or simplified. For the structures whose description has been omitted or simplified, the description given before the omission or simplification shall apply.

When the wording “substantially equal” is used in this description, the wording includes a numerical value (shape) equal to a numerical value (shape) of a comparison target and also includes numerical errors (shape errors) in a range of ±10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “p-type” may be referred to as a “first conductivity type” and the “n-type” may be referred to as a “second conductivity type.” As a matter of course, the “n-type” may be referred to as the “first conductivity type” and the “p-type” may be referred to as the “second conductivity type” instead.

The “p-type” is a conductivity type due to a trivalent element and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

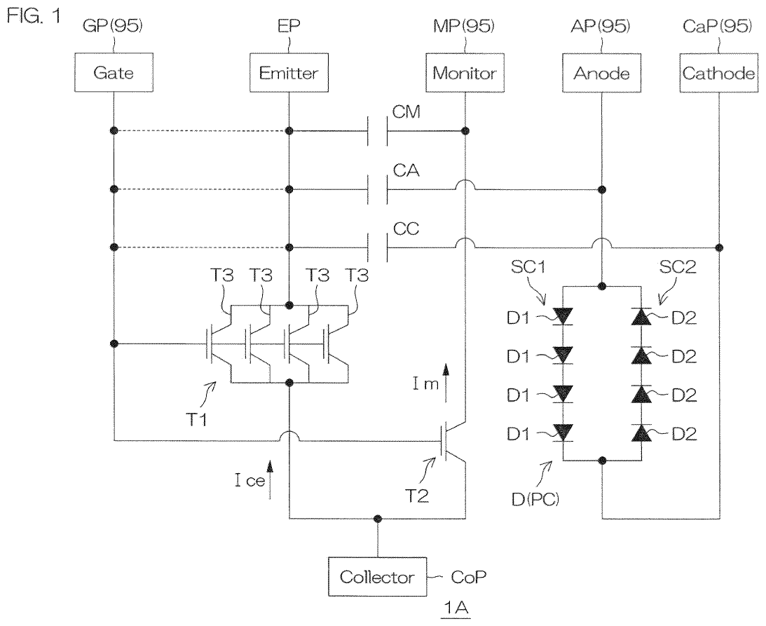

FIG. 1 is a circuit diagram showing an electrical arrangement example of a semiconductor device 1A according to a first embodiment. The semiconductor device 1A includes a gate pad GP, an emitter pad EP, a monitor pad MP, a collector pad CoP, an anode pad AP, a cathode pad CaP, a main transistor structure T1 of an insulated gate type, a monitor transistor structure T2 of the insulated gate type, and a temperature sensitive diode structure D. That is, the semiconductor device 1A is a semiconductor switching device.

The main transistor structure T1 includes one or a plurality of transistor structures T3. In this embodiment, the main transistor structure T1 includes a parallel circuit formed of a plurality of (in this embodiment, four) transistor structures T3. Each of the transistor structures T3 includes one or both of an MISFET structure and an IGBT structure. In this embodiment, the transistor structure T3 has an IGBT structure of a trench gate vertical type.

The main transistor structure T1 (transistor structure T3) includes a gate electrically connected to the gate pad GP, an emitter electrically connected to the emitter pad EP, and a collector electrically connected to the collector pad CoP.

The main transistor structure T1 is on/off controlled in response to a gate potential applied from the gate pad GP, and generates an output current Ice between the emitter pad EP and the collector pad CoP. The output current Ice is an emitter-collector current of the main transistor structure T1.

In this embodiment, the monitor transistor structure T2 is connected in parallel to the main transistor structure T1. In this embodiment, the monitor transistor structure T2 has an IGBT structure of a trench gate vertical type. The monitor transistor structure T2 includes a monitor gate electrically connected to the gate pad GP, a monitor emitter electrically connected to the monitor pad MP, and a monitor collector electrically connected to the collector pad CoP.

The monitor transistor structure T2 is on/off controlled at the same timing as the main transistor structure T1 according to the gate potential applied from the gate pad GP, and generates a monitor current Im for monitoring the output current Ice between the monitor pad MP and the collector pad CoP. The monitor current Im is an emitter-collector current of the monitor transistor structure T2.

The monitor current Im is less than the output current Ice. A current ratio Im/Ice of the monitor current Im to the output current Ice may be not less than 1/2000 and not more than 1/10. The current ratio Im/Ice may have a value belonging to at least one range among not less than 1/2000 and not more than 1/1750, not less than 1/1750 and not more than 1/1500, not less than 1/1500 and not more than 1/1250, not less than 1/1250 and not more than 1/1000, not less than 1/1000 and not more than 1/750, not less than 1/750 and not more than 1/500, not less than 1/500 and not more than 1/250, not less than 1/250 and not more than 1/100, not less than 1/100 and not more than 1/75, not less than 1/75 and not more than 1/50, not less than 1/50 and not more than 1/25, and not less than 1/25 and not more than 1/10.

The temperature sensitive diode structure D has a parallel circuit PC including one or a plurality of (in this embodiment, four) first diodes D1 and one or a plurality of (in this embodiment, four) second diodes D2. The number of second diodes D2 is the same as the number of first diodes D1. As a matter of course, the number of second diodes D2 may be larger than the number of first diodes D1, or may be smaller than the number of first diodes D1.

The plurality of first diodes D1 are connected in series in a forward direction and form a first series circuit SC1. An anode of the first series circuit SC1 is electrically connected to the anode pad AP. A cathode of the first series circuit SC1 is electrically connected to the cathode pad CaP.

The plurality of second diodes D2 are connected in series in the forward direction and forms a second series circuit SC2. A cathode of the second series circuit SC2 is electrically connected to the anode pad AP. An anode of the second series circuit SC2 is electrically connected to the cathode pad CaP. That is, the second series circuit SC2 is connected in reverse bias parallel to the first series circuit SC1 and forms the parallel circuit PC with the first series circuit SC1.

The first series circuit SC1 functions as a temperature sensor, and the second series circuit SC2 functions as a protection circuit. The first series circuit SC1 (the plurality of first diodes D1) has temperature characteristics (for example, positive temperature characteristics) in which a forward voltage varies according to a temperature change, and outputs a forward current according to the temperature of a chip 2.

The second series circuit SC2 provides tolerance to a noise signal. The second series circuit SC2 preferably has electrical characteristics (high-frequency impedance characteristics) substantially equal to those of the first series circuit SC1. When the protection function by the second series circuit SC2 is unnecessary, the second series circuit SC2 may be removed.

The semiconductor device 1A includes a monitor capacitor structure CM electrically interposed between the emitter pad EP and the monitor pad MP. The monitor capacitor structure CM functions as a capacitor between the emitter pad EP and the monitor pad MP when a voltage is applied between the emitter pad EP and the monitor pad MP.

The monitor capacitor structure CM also functions as a capacitor between the gate pad GP and the monitor pad MP when a voltage is applied between the gate pad GP and the monitor pad MP.

The semiconductor device 1A includes an anode capacitor structure CA electrically interposed between the emitter pad EP and the anode pad AP. The anode capacitor structure CA functions as a capacitor between the emitter pad EP and the anode pad AP when a voltage is applied between the emitter pad EP and the anode pad AP.

The anode capacitor structure CA also functions as a capacitor between the gate pad GP and the anode pad AP when a voltage is applied between the gate pad GP and the anode pad AP.

The semiconductor device 1A includes a cathode capacitor structure CC electrically interposed between the emitter pad EP and the cathode pad CaP. The cathode capacitor structure CC functions as a capacitor between the emitter pad EP and the cathode pad CaP when a voltage is applied between the emitter pad EP and the cathode pad CaP.

The cathode capacitor structure CC also functions as a capacitor between the gate pad GP and the cathode pad CaP when a voltage is applied between the gate pad GP and the cathode pad CaP.

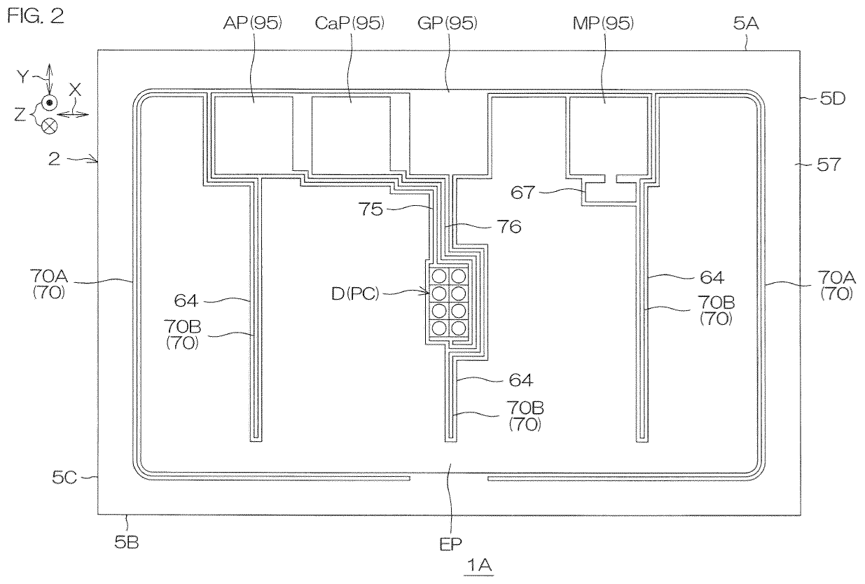

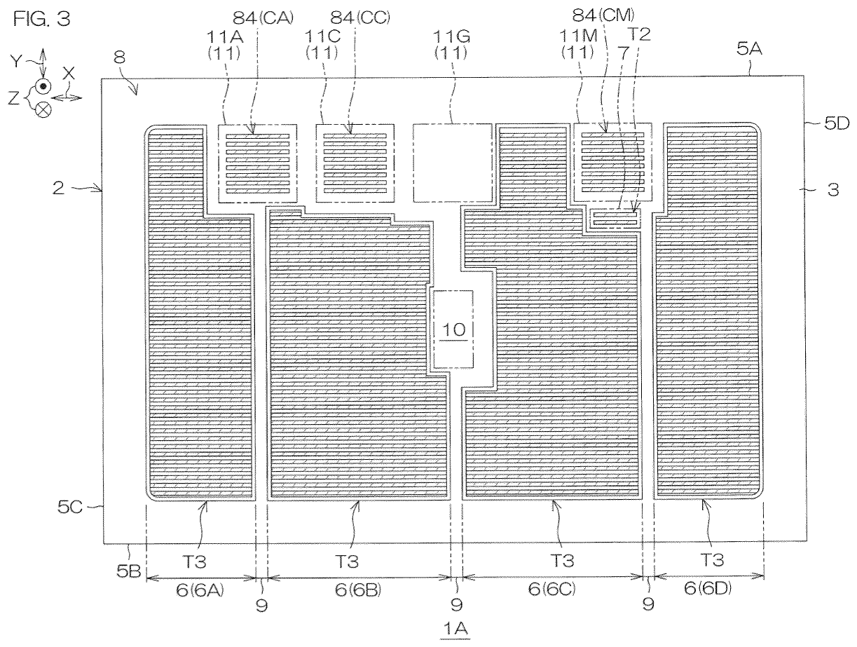

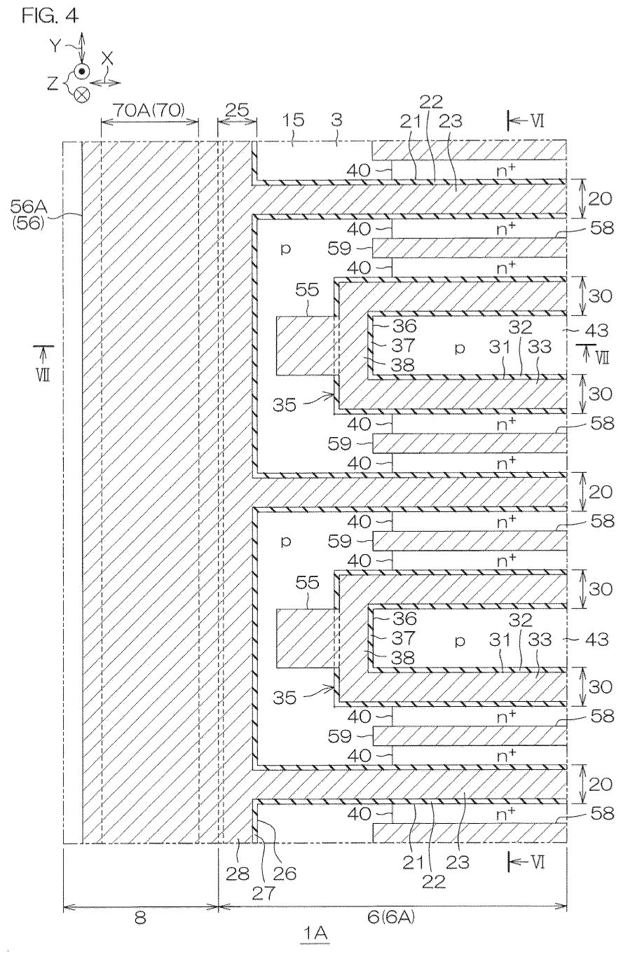

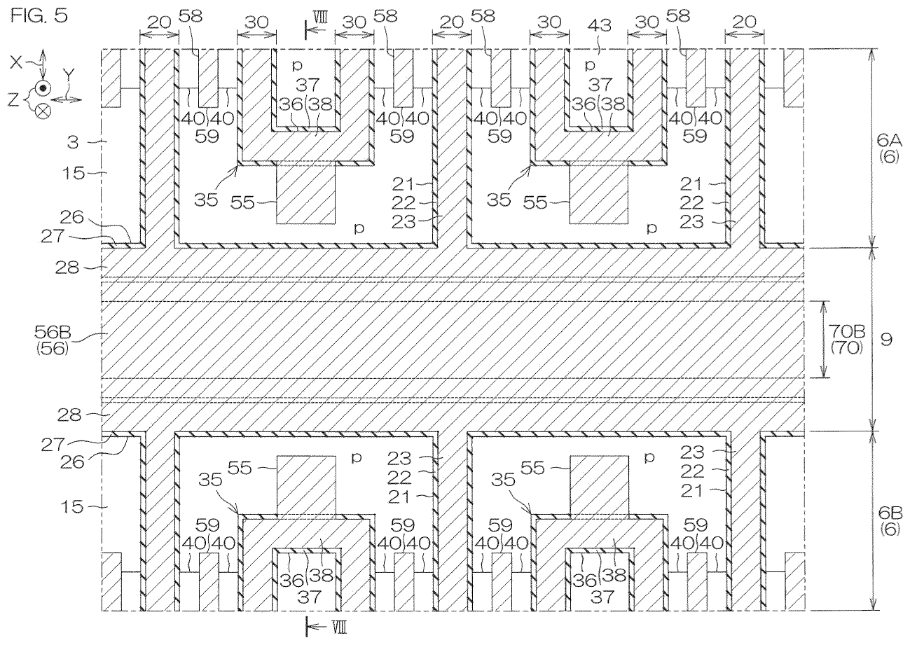

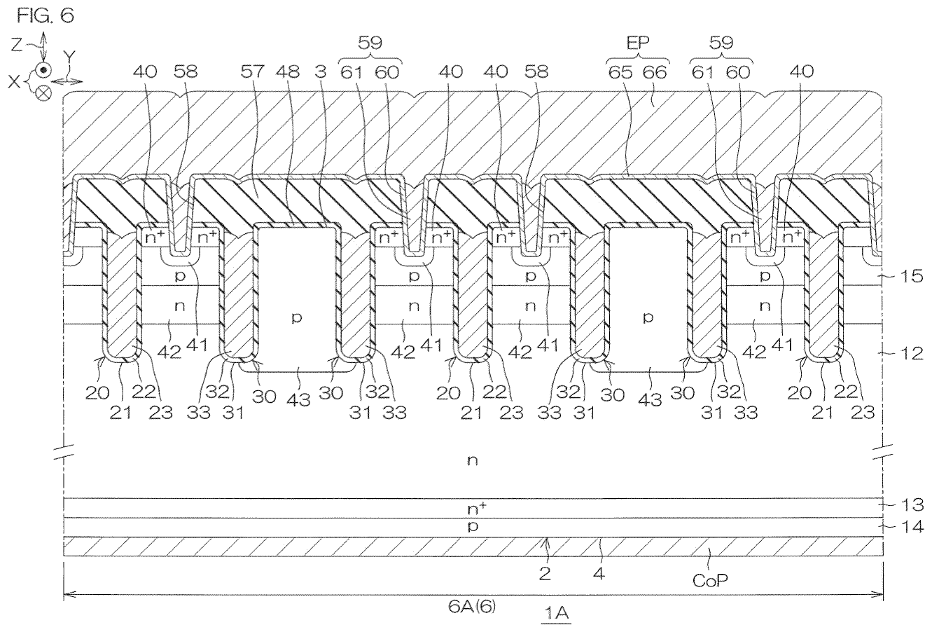

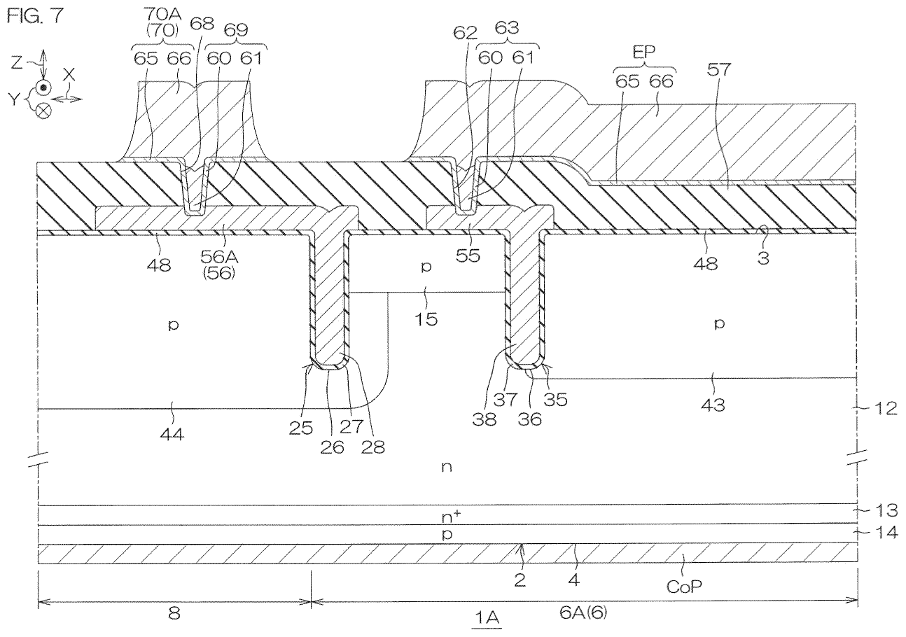

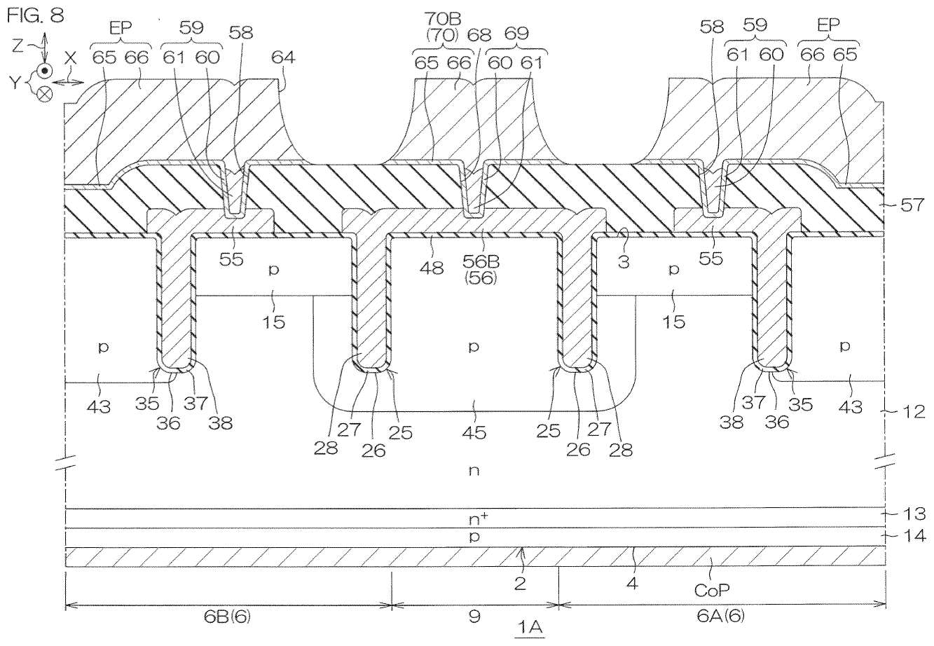

FIG. 2 is a plan view of the semiconductor device 1A shown in FIG. 1. FIG. 3 is a plan view showing a layout example of a first main surface 3. FIG. 4 is an enlarged plan view showing a principal portion of an active region 6. FIG. 5 is an enlarged plan view showing another principal portion of the active region 6. FIG. 6 is a sectional view taken along line VI-VI shown in FIG. 4. FIG. 7 is a sectional view taken along line VII-VII shown in FIG. 4. FIG. 8 is a sectional view taken along line VIII-VIII shown in FIG. 5.

With reference to FIG. 2 to FIG. 8, the semiconductor device 1A includes the chip 2 formed in a hexahedral shape (specifically, a rectangular parallelepiped shape). The chip 2 includes one or both of a silicon monocrystal and a wide bandgap semiconductor monocrystal.

The wide bandgap semiconductor is a semiconductor having a bandgap greater than a bandgap of silicon. GaN (gallium nitride), SiC (silicon carbide), C (diamond), etc., can be given as examples of the wide bandgap semiconductor. The chip 2 may also be referred to as a “semiconductor chip,” a “silicon chip,” or a “wide bandgap semiconductor chip,” etc.

When a SiC monocrystal is adopted as the wide bandgap semiconductor monocrystal, the chip 2 is preferably made of a hexagonal SiC monocrystal. The SiC monocrystal that is a hexagonal crystal has multiple polytypes including a 2H (hexagonal)-SiC monocrystal, a 4H-SiC monocrystal, a 6H-SiC monocrystal, etc. The chip 2 preferably contains a 4H-SiC monocrystal. As a matter of course, the chip 2 may include other polytypes. In this embodiment, the chip 2 has a single layer structure including a silicon monocrystal.

The chip 2 may have a thickness of not less than 50 μm and not more than 500 μm. The thickness of the chip 2 may have a value belonging to at least one range among not less than 50 μm and not more than 100 μm, not less than 100 μm and not more than 150 μm, not less than 150 μm and not more than 200 μm, not less than 200 μm and not more than 300 μm, not less than 300 μm and not more than 400 μm, and not less than 400 μm and not more than 500 μm.

The chip 2 has the first main surface 3 on one side, a second main surface 4 on the other side, and first to fourth side surfaces 5A to 5D connected to the first main surface 3 and the second main surface 4. In plan view as viewed in a vertical direction Z (hereinafter referred to simply as “plan view”), the first main surface 3 and the second main surface 4 are formed in quadrangular shapes. The vertical direction Z is also a thickness direction of the chip 2.

The first side surface 5A and the second side surface 5B extend in a first direction X along the first main surface 3 and oppose (face) each other in a second direction Y that intersects the first direction X along the first main surface 3. Specifically, the second direction Y is orthogonal to the first direction X. The third side surface 5C and the fourth side surface 5D extend in the second direction Y and oppose (face) each other in the first direction X.

In the following, the direction extending along the first main surface 3 is expressed at times as a “horizontal direction.” The horizontal direction is also an XY plane (horizontal plane) formed by the first direction X and the second direction Y and is orthogonal to the vertical direction Z.

The semiconductor device 1A includes one or a plurality of the active regions 6 provided on the first main surface 3. The active region 6 is a region having the transistor structure T3. The number of active regions 6 is arbitrary, and is appropriately adjusted according to the size of the chip 2 (the first main surface 3).

In this embodiment, the semiconductor device 1A includes a plurality of (in this embodiment, four) active regions 6. The plurality of active regions 6 include a first active region 6A, a second active region 6B, a third active region 6C, and a fourth active region 6D which are arrayed from the third side surface 5C side toward the fourth side surface 5D side.

The plurality of active regions 6 are provided in the inner portion of the first main surface 3 at an interval from a peripheral edge (the first to fourth side surfaces 5A to 5D) of the first main surface 3. The plurality of active regions 6 are arrayed at intervals in the first direction X and each extend in a band shape in the second direction Y. The plurality of active regions 6 are unevenly distributed on the second side surface 5B side with respect to the first side surface 5A.

Planar shapes of the plurality of active regions 6 are arbitrary. In this embodiment, the plurality of active regions 6 are demarcated in polygonal shapes having four sides parallel to the peripheral edge of the chip 2. The widths in the first direction X, the lengths in the second direction Y, the plane areas, and the like of the plurality of active regions 6 may be different from each other. At least two of the plurality of active regions 6 may be partially connected.

The semiconductor device 1A includes a monitor region 7 provided on the first main surface 3. The monitor region 7 is a region having the monitor transistor structure T2. The monitor region 7 is provided in a region outside the plurality of active regions 6. The layout location of the monitor region 7 is arbitrary. In this embodiment, the monitor region 7 is arranged on the first side surface 5A side with respect to the plurality of active regions 6.

In this embodiment, the monitor region 7 is arranged near a corner portion connecting the first side surface 5A and the fourth side surface 5D. The monitor region 7 may face at least one active region 6 in the second direction Y. The monitor region 7 has a plane area less than the plane area of the plurality of active regions 6. The plane area of the monitor region 7 is arbitrary, and is appropriately adjusted according to the size of the chip 2 (first main surface 3) and the monitor current Im.

The semiconductor device 1A includes an outer peripheral region 8 provided in a peripheral edge portion of the first main surface 3. The outer peripheral region 8 is a region not having the monitor transistor structure T2 and the transistor structure T3. The outer peripheral region 8 is provided in a region outside the plurality of active regions 6 and the monitor region 7 in the peripheral edge portion of the first main surface 3. The outer peripheral region 8 is formed in an annular shape extending along the peripheral edge of the first main surface 3 and surrounds the plurality of active regions 6 and the monitor region 7.

The semiconductor device 1A includes one or a plurality of (in this embodiment, a plurality of) street regions 9 provided on the first main surface 3. Each of the street regions 9 is a region not having the monitor transistor structure T2 and the transistor structure T3.

The plurality of street regions 9 are provided in a region outside the plurality of active regions 6 and the monitor region 7. The plurality of street regions 9 are respectively demarcated into regions between the plurality of adjacent active regions 6, and each extend in a band shape in the second direction Y in conformance to an extension direction of the plurality of active regions 6.

The semiconductor device 1A includes a temperature detecting region 10 provided on the first main surface 3. The temperature detecting region 10 is a region including the temperature sensitive diode structure D for temperature detection of the chip 2. The temperature detecting region 10 may be referred to as a “diode region,” a “temperature sensitive diode region,” or the like. The temperature detecting region 10 is provided in a region outside the plurality of active regions 6 and the monitor region 7.

In this embodiment, the temperature detecting region 10 is formed using a part of the street region 9 in a region between the plurality of active regions 6, and faces the plurality of active regions 6 in the first direction X. In this embodiment, the temperature detecting region 10 is formed in a region between the second active region 6B and the third active region 6C.

The temperature detecting region 10 has a plane area less than the plane area of the plurality of active regions 6. The layout location of the temperature detecting region 10 is arbitrary. The temperature of the inner portion of the first main surface 3 (the chip 2) is relatively likely to rise. Therefore, it is preferable that the temperature detecting region 10 is provided in the inner portion (for example, near the central portion) of the first main surface 3.

In this case, the temperature of the chip 2 is appropriately detected. When a first virtual line passing through the central portion of the first main surface 3 in the first direction X and a second virtual line passing through the central portion of the first main surface 3 in the second direction Y are set, a part of the temperature detecting region 10 may overlap one or both of the first virtual line and the second virtual line.

The semiconductor device 1A includes a plurality of pad regions 11 provided on the first main surface 3. The plurality of pad regions 11 are regions where external terminals for external connection are arranged. The plurality of pad regions 11 are provided in a region outside the plurality of active regions 6, the monitor region 7, the plurality of street regions 9, and temperature detecting region 10. The layout location of the plurality of pad regions 11 is arbitrary. In this embodiment, the plurality of pad regions 11 are formed using a part of the outer peripheral region 8 in a region on the first side surface 5A side with respect to the plurality of active regions 6.

The plurality of pad regions 11 include a gate pad region 11G, a monitor pad region 11M, an anode pad region 11A, and a cathode pad region 11C. The gate pad region 11G is a region where the gate pad GP is arranged.

The monitor pad region 11M is a region where the monitor pad MP is arranged. The anode pad region 11A is a region where the anode pad AP is arranged. The cathode pad region 11C is a region where the cathode pad CaP is arranged.

The gate pad region 11G is provided in a region on the first side surface 5A side with respect to the plurality of active regions 6. Specifically, the gate pad region 11G may be provided near the central portion of the first side surface 5A, and may face one or a plurality of the active regions 6 in one or both of the first direction X and the second direction Y. In this embodiment, the gate pad region 11G faces the temperature detecting region 10 in the second direction Y.

The monitor pad region 11M is provided in a region on the first side surface 5A side with respect to the plurality of active regions 6. Specifically, the monitor pad region 11M is provided in a region on the fourth side surface 5D side with respect to the gate pad region 11G, and faces the gate pad region 11G in the first direction X. In this embodiment, the monitor pad region 11M faces the gate pad region 11G with a portion of at least one of the active regions 6 (in this embodiment, the third active region 6C) interposed therebetween.

The monitor pad region 11M is provided in a region on the first side surface 5A side with respect to the monitor region 7, and faces the monitor region 7 in the second direction Y. The monitor pad region 11M faces one or a plurality of the active regions 6 (in this embodiment, the third active region 6C) in the second direction Y with the monitor region 7 interposed therebetween.

The anode pad region 11A is provided in a region on the first side surface 5A side with respect to the plurality of active regions 6. Specifically, the anode pad region 11A is provided in a region on the third side surface 5C side with respect to the gate pad region 11G, and faces the gate pad region 11G in the first direction X. The anode pad region 11A may face one or a plurality of the active regions 6 in the second direction Y.

The cathode pad region 11C is provided in a region on the first side surface 5A side with respect to the plurality of active regions 6. Specifically, the cathode pad region 11C is provided in a region on the third side surface 5C side with respect to the gate pad region 11G, and faces the gate pad region 11G in the first direction X.

More specifically, the cathode pad region 11C is provided in a region between the gate pad region 11G and the anode pad region 11A, and faces both of the gate pad region 11G and the anode pad region 11A in the first direction X. The cathode pad region 11C may face one or a plurality of the active regions 6 in the second direction Y.

The semiconductor device 1A includes a drift region 12 of an n-type formed in an interior of the chip 2. The drift region 12 may be referred to as a “semiconductor region.” The drift region 12 is formed over the entire region of a thickness range between the first main surface 3 and the second main surface 4, and extends in a layer shape along the first main surface 3 (the second main surface 4).

In this embodiment, the drift region 12 is formed in the entire region inside the chip 2 and is exposed from the first main surface 3 and the first to fourth side surfaces 5A to 5D. In this embodiment, the chip 2 is formed of the n-type semiconductor substrate (the chip 2 of the n-type), and the drift region 12 is formed using the n-type chip 2.

The semiconductor device 1A includes a buffer region 13 of the n-type formed in a surface layer portion of the second principal surface 4. The buffer region 13 has an n-type impurity concentration higher than the n-type impurity concentration of the drift region 12. In this embodiment, the buffer region 13 is formed in a layer shape extending along the second main surface 4 in the entire region of the second main surface 4, and is exposed from the first to fourth side surfaces 5A to 5D. The presence or absence of the buffer region 13 is arbitrary, and an embodiment without the buffer region 13 may be adopted instead.

The semiconductor device 1A includes a collector region 14 of a p-type formed in the surface layer portion of the second main surface 4. The collector region 14 forms a collector of the main transistor structure T1 (the transistor structure T3). The collector region 14 is formed in a region on the second main surface 4 side with respect to the buffer region 13. The collector region 14 has a p-type impurity concentration higher than the n-type impurity concentration of the drift region 12, and replaces the conductivity type of the drift region 12 from the n-type to the p-type.

The collector region 14 has a p-type impurity concentration higher than the n-type impurity concentration of the buffer region 13, and replaces the conductivity type of the buffer region 13 from the n-type to the p-type. In this embodiment, the collector region 14 is formed in a layer shape extending along the second main surface 4 in the entire region of the second main surface 4, and is exposed from the second main surface 4 and the first to fourth side surfaces 5A to 5D.

Hereinafter, arrangements of the plurality of active regions 6, the monitor region 7, the outer peripheral region 8, the plurality of street regions 9, the temperature detecting region 10, and the plurality of pad regions 11 shall be described. The semiconductor device 1A includes a plurality of transistor structures T3 respectively formed in the plurality of active regions 6.

The plurality of transistor structures T3 are connected in parallel to each other and form one main transistor structure T1. Since the plurality of transistor structures T3 have the same arrangement, the arrangement of one transistor structure T3 as one component of the semiconductor device 1A shall be described below.

The transistor structure T3 includes a base region 15 of the p-type formed in a surface layer portion of the first main surface 3 in the corresponding active region 6. The base region 15 may be referred to as a “body region,” a “channel region,” etc. The base region 15 is formed in a surface layer portion of the drift region 12. In this embodiment, the base region 15 has a p-type impurity concentration higher than the n-type impurity concentration of the drift region 12, and replaces the conductivity type of the drift region 12 from the n-type to the p-type.

The base regions 15 are each formed in a layer shape extending along the first main surface 3 in the corresponding active region 6. The base region 15 is formed at an interval from a depth position of an intermediate portion of the drift region 12 toward the first main surface 3 side, and faces the buffer region 13 and the collector region 14 with the drift region 12 interposed therebetween.

The transistor structure T3 includes a plurality of gate structures 20 of a trench electrode type formed in the first main surface 3 in the corresponding active region 6. The plurality of gate structures 20 form gates of the main transistor structure T1 (transistor structure T3). The gate structure 20 may be referred to as a “first trench structure,” a “trench gate structure,” etc. A gate potential is to be applied to the gate structure 20.

The plurality of gate structures 20 each extend in a band shape in the first direction X and are arrayed at intervals in the second direction Y. That is, the plurality of gate structures 20 are arrayed in a stripe shape extending in the first direction X. The plurality of gate structures 20 each have one end portion on one side (on the third side surface 5C side) and the other end portion on the other side (on the fourth side surface 5D side) in a longitudinal direction (first direction X).

The plurality of gate structures 20 may each have a width less than the width of the plurality of street regions 9. The width of the gate structure 20 is a width in a direction (the second direction Y) orthogonal to the extension direction of the gate structure 20 (the first direction X).

The width of the gate structure 20 may be not less than 0.5 μm and not more than 5 μm. The width of the gate structure 20 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The width of the gate structure 20 is preferably not less than 1 μm and not more than 2.5 μm.

The plurality of gate structures 20 pass through the base region 15 to reach the drift region 12. The plurality of gate structures 20 are each formed at an interval toward the first main surface 3 side from the depth position of the intermediate portion of the drift region 12, and face the buffer region 13 and the collector region 14 with a portion of the drift region 12 interposed therebetween in the thickness direction.

The plurality of gate structures 20 may each be formed in a shape tapering toward the bottom wall. As a matter of course, the plurality of gate structures 20 may be formed substantially perpendicular to the first main surface 3. The plurality of gate structures 20 may have bottom walls formed in a shape curved toward the second main surface 4. As a matter of course, the bottom walls of the plurality of gate structures 20 may be formed substantially parallel to the first main surface 3. In this case, bottom wall corner portions of the plurality of gate structures 20 may each be formed in a curved shape.

The plurality of gate structures 20 may each have a depth of not less than 1 μm and not more than 10 μm. The depth of the gate structure 20 may have a value belonging to at least one range among not less than 1 μm and not more than 2 μm, not less than 2 μm and not more than 4 μm, not less than 4 μm and not more than 6 μm, not less than 6 μm and not more than 8 μm, and not less than 8 μm and not more than 10 μm. The depth of the gate structure 20 is preferably not less than 4 μm and not more than 8 μm.

The plurality of gate structures 20 each include a gate trench 21, a gate insulating film 22, and a gate embedded electrode 23. The gate trench 21 is formed in the first main surface 3 and demarcates the wall surfaces (side walls and bottom wall) of the gate structure 20.

The gate insulating film 22 covers the wall surfaces of the gate trench 21. The gate insulating film 22 may include at least one among a silicon oxide film, a silicon nitride film, and a silicon oxynitride film. In this embodiment, the gate insulating film 22 has a single layer structure consisting of the silicon oxide film. The gate insulating film 22 particularly preferably includes the silicon oxide film that consists of the oxide of the chip 2.

The gate insulating film 22 may have a thickness of not less than 10 nm and not more than 200 nm. The thickness of the gate insulating film 22 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm. The thickness of the gate insulating film 22 is preferably not less than 100 nm and not more than 150 nm.

The gate embedded electrode 23 is embedded in the gate trench 21 with the gate insulating film 22 interposed therebetween. The gate embedded electrode 23 faces the drift region 12 and the base region 15 with the gate insulating film 22 interposed therebetween. An electrode surface of the gate embedded electrode 23 may be positioned on the bottom wall side of the gate trench 21 with respect to the first main surface 3. The gate embedded electrode 23 may contain one or both of a conductive polysilicon of the p-type and a conductive polysilicon of the n-type.

The transistor structure T3 includes a plurality of gate connection structures 25 of the trench electrode type formed in the first main surface 3 so as to be connected to the plurality of gate structures 20 in the corresponding active region 6. A gate potential is to be applied to the plurality of gate connection structures 25. Each of the gate connection structures 25 may be referred to as a “first trench connection structure,” a “trench gate connection structure,” etc.

The plurality of gate connection structures 25 are respectively arranged on both end portion sides of the plurality of gate structures 20 so as to be connected to one end portions and the other end portions of the plurality of gate structures 20 in the first direction X, and demarcate the corresponding active region 6 together with the outermost plurality of gate structures 20.

The plurality of gate connection structures 25 include a gate connection structure 25 on one end portion side of the plurality of gate structures 20 and a gate connection structure 25 on the other end portion side of the plurality of gate structures 20. The gate connection structure 25 on one end portion side extends in a band shape in the second direction Y and is connected to one end portions of the plurality of gate structures 20. The gate connection structure 25 on the other end portion side extends in a band shape in the second direction Y and is connected to the other end portions of the plurality of gate structures 20.

The plurality of gate connection structures 25 may each have a width substantially equal to the width of the gate structure 20. As a matter of course, the width of the gate connection structure 25 may be larger than the width of the gate structure 20, or may be smaller than the width of the gate structure 20.

The width of the gate connection structure 25 may be not less than 0.5 μm and not more than 5 μm. The width of the gate connection structure 25 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The width of the gate connection structure 25 is preferably not less than 1 μm and not more than 2.5 μm.

The plurality of gate connection structure 25 pass through the base region 15 to reach the drift region 12. The plurality of gate connection structures 25 are formed at an interval toward the first main surface 3 side from the depth position of the intermediate portion of the drift region 12, and face the buffer region 13 and the collector region 14 with a portion of the drift region 12 interposed therebetween in the thickness direction.

The plurality of gate connection structures 25 may each be formed in a shape tapering toward the bottom wall. As a matter of course, the plurality of gate connection structures 25 may be formed substantially perpendicular to the first main surface 3. The plurality of gate connection structures 25 may have bottom walls formed in a shape curved toward the second main surface 4. As a matter of course, the bottom walls of the plurality of gate connection structures 25 may be formed substantially parallel to the first main surface 3. In this case, bottom wall corner portions of the plurality of gate connection structures 25 may each be formed in a curved shape.

The plurality of gate connection structures 25 may each have a depth substantially equal to the depth of the gate structure 20. As a matter of course, the depth of the gate connection structure 25 may be larger than the depth of the gate structure 20, or may be smaller than the depth of the gate structure 20.

The depth of the plurality of gate connection structures 25 may be not less than 0.5 μm and not more than 10 μm. The depth of the gate connection structure 25 may have a value belonging to at least one range among not less than 0.5 μm and not more than 1 μm, not less than 1 μm and not more than 2 μm, not less than 2 μm and not more than 4 μm, not less than 4μm and not more than 6 μm, not less than 6 μm and not more than 8 μm, and not less than 8 μm and not more than 10 μm. The depth of the gate connection structure 25 is preferably not less than 4 μm and not more than 8 μm.

The plurality of gate connection structures 25 each include a gate connection trench 26, a gate connection insulating film 27, and a gate connection embedded electrode 28. The gate connection trench 26 is formed in the first main surface 3 and demarcates the wall surfaces (side walls and bottom wall) of the gate connection structure 25. The gate connection trench 26 communicates with a plurality of the gate trenches 21.

The gate connection insulating film 27 may include at least one among a silicon oxide film, a silicon nitride film, and a silicon oxynitride film. The gate connection insulating film 27 preferably includes the same type of insulator as the gate insulating film 22. In this embodiment, the gate connection insulating film 27 has a single layer structure constituted of a silicon oxide film. The gate connection insulating film 27 particularly preferably constituted of a silicon oxide film made of an oxide of the chip 2.

The gate connection insulating film 27 covers the wall surfaces of the gate connection trench 26 in a film shape. The gate connection insulating film 27 is connected to the gate insulating film 22 at a communication portion of the gate trench 21 and the gate connection trench 26.

The gate connection insulating film 27 may have a thickness substantially equal to the thickness of the gate insulating film 22. As a matter of course, the thickness of the gate connection insulating film 27 may be larger than the thickness of the gate insulating film 22, or may be smaller than the thickness of the gate insulating film 22.

The thickness of the gate connection insulating film 27 may be not less than 10 nm and not more than 200 nm. The thickness of the gate connection insulating film 27 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm. The thickness of the gate connection insulating film 27 is preferably not less than 100 nm and not more than 150 nm.

The gate connection embedded electrode 28 is embedded in the gate connection trench 26 with the gate connection insulating film 27 interposed therebetween. The gate connection embedded electrode 28 is connected to the gate embedded electrode 23 at a communication portion of the gate trench 21 and the gate connection trench 26. The gate connection embedded electrode 28 faces the drift region 12 and the base region 15 with the gate connection insulating film 27 interposed therebetween.

The electrode surface of the gate connection embedded electrode 28 may be positioned on the bottom wall side of the gate connection trench 26 with respect to the first main surface 3. The gate connection embedded electrode 28 may contain one or both of a conductive polysilicon of the p-type and a conductive polysilicon of the n-type. The gate connection embedded electrode 28 preferably includes the same type of conductor as the gate embedded electrode 23.

The transistor structure T3 includes a plurality of emitter structures 30 of the trench electrode type formed in the first main surface 3 in the corresponding active region 6. The emitter structure 30 may be referred to as a “second trench structure,” a “trench emitter structure,” etc. A potential different from the gate potential (in this embodiment, an emitter potential) is to be applied to the emitter structure 30.

In this embodiment, at least two emitter structures 30 are respectively arranged in regions between pairs of adjacent gate structures 20. Specifically, the plurality of emitter structures 30 are formed in a mesa region demarcated by the pair of gate structures 20 and a pair of gate connection structures 25.

The plurality of emitter structures 30 each extend in a band shape in the first direction X in conformance to the extension direction of the plurality of gate structures 20, and are formed at an interval from the plurality of gate connection structures 25 in the first direction X.

The plurality of emitter structures 30 each have a length shorter than the length of the plurality of gate structures 20 in the longitudinal direction (the first direction X). The plurality of emitter structures 30 each have one end portion on one side (third side surface 5C side) and the other end portion on the other side (on the fourth side surface 5D side) in a longitudinal direction (the first direction X).

The plurality of emitter structures 30 may each have a width less than the width of the plurality of street regions 9. The width of the emitter structure 30 is a width in a direction (the second direction Y) orthogonal to the extension direction of the emitter structure 30 (the first direction X). The width of the emitter structure 30 may be substantially equal to the width of the gate structure 20. As a matter of course, the width of the emitter structure 30 may be larger than the width of the gate structure 20, or may be smaller than the width of the gate structure 20.

The width of the emitter structure 30 may be not less than 0.5 μm and not more than 5 μm. The width of the emitter structure 30 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The width of the emitter structure 30 is preferably not less than 1 μm and not more than 2.5 μm.

The plurality of emitter structures 30 pass through the base region 15 so as to reach the drift region 12. The plurality of emitter structures 30 are each formed at an interval toward the first main surface 3 side from the depth position of the intermediate portion of the drift region 12, and face the buffer region 13 and the collector region 14 with a portion of the drift region 12 interposed therebetween in the thickness direction.

The plurality of emitter structures 30 may each be formed in a shape tapering toward the bottom wall. As a matter of course, the plurality of emitter structures 30 may be formed substantially perpendicular to the first main surface 3. The plurality of emitter structures 30 may have bottom walls formed in a shape curved toward the second main surface 4. As a matter of course, the bottom walls of the plurality of emitter structures 30 may be formed substantially parallel to the first main surface 3. In this case, bottom wall corner portions of the plurality of emitter structures 30 may each be formed in a curved shape.

The emitter structure 30 may have a depth substantially equal to the depth of the gate structure 20. As a matter of course, the depth of the emitter structure 30 may be larger than the depth of the gate structure 20, or may be smaller than the depth of the gate structure 20.

The depth of the plurality of emitter structures 30 may be not less than 0.5 μm and not more than 10 μm. The depth of the emitter structure 30 may have a value belonging to at least one range among not less than 0.5 μm and not more than 1 μm, not less than 1 μm and not more than 2 μm, not less than 2 μm and not more than 4 μm, not less than 4 μm and not more than 6 μm, not less than 6 μm and not more than 8 μm, and not less than 8 μm and not more than 10 μm. The depth of the emitter structure 30 is preferably not less than 4 μm and not more than 8 μm.

A first trench pitch between the central portion of the gate structure 20 and the central portion of the emitter structure 30 may be not less than 1 μm and not more than 5 μm. The first trench pitch may have a value belonging to at least one range among not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The first trench pitch is preferably not less than 1.5 μm and not more than 3.5 μm.

The plurality of emitter structures 30 each include an emitter trench 31, an emitter insulating film 32, and an emitter embedded electrode 33. The emitter trench 31 is formed in the first main surface 3 and demarcates the wall surfaces (side walls and bottom wall) of the emitter structure 30.

The emitter insulating film 32 covers the wall surfaces of the emitter trench 31. The emitter insulating film 32 may include at least one among a silicon oxide film, a silicon nitride film, and a silicon oxynitride film. The emitter insulating film 32 preferably includes the same type of insulator as the gate insulating film 22. In this embodiment, the emitter insulating film 32 has a single layer structure constituted of a silicon oxide film. The emitter insulating film 32 particularly preferably includes the silicon oxide film constituted of the oxide of the chip 2.

The emitter insulating film 32 may have a thickness substantially equal to the thickness of the gate insulating film 22. As a matter of course, the thickness of the emitter insulating film 32 may be larger than the thickness of the gate insulating film 22, or may be smaller than the thickness of the gate insulating film 22.

The emitter insulating film 32 may have a thickness of not less than 10 nm and not more than 200 nm. The thickness of the emitter insulating film 32 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm. The thickness of the emitter insulating film 32 is preferably not less than 100 nm and not more than 150 nm.

The emitter embedded electrode 33 is embedded in the emitter trench 31 with the emitter insulating film 32 interposed therebetween. The emitter embedded electrode 33 faces the drift region 12 and the base region 15 with the emitter insulating film 32 interposed therebetween.

An electrode surface of the emitter embedded electrode 33 may be positioned on the bottom wall side of the emitter trench 31 with respect to the first main surface 3. The emitter embedded electrode 33 may contain one or both of a conductive polysilicon of the p-type and a conductive polysilicon of the n-type. The emitter embedded electrode 33 preferably includes the same type of conductor as the gate embedded electrode 23.

The transistor structure T3 includes a plurality of emitter connection structures 35 formed in the first main surface 3 so as to be connected to the plurality of emitter structures 30 in the corresponding active region 6. An emitter potential is to be applied to the plurality of emitter connection structures 35. The emitter connection structure 35 may be referred to as a “second trench connection structure,” a “trench emitter connection structure,” etc.

The plurality of emitter connection structures 35 are respectively arranged on both end portion sides of the plurality of emitter structures 30 so as to be connected to one end portions and the other end portions of the plurality of emitter structures 30 in the first direction X.

The plurality of emitter connection structures 35 include the emitter connection structure 35 on one end portion side of the plurality of emitter structures 30 and the emitter connection structure 35 on the other end portion side of the plurality of emitter structures 30. The emitter connection structure 35 on one end portion side extends in a band shape in the second direction Y and is connected to one end portions of the plurality of adjacent emitter structures 30. The emitter connection structure 35 on the other end portion side extends in a band shape in the second direction Y and is connected to the other end portions of the plurality of adjacent emitter structures 30.

The plurality of emitter connection structures 35 pass through the base region 15 so as to reach the drift region 12. The plurality of emitter connection structures 35 are each formed at an interval toward the first main surface 3 side from the depth position of the intermediate portion of the drift region 12, and face the buffer region 13 and the collector region 14 with a portion of the drift region 12 interposed therebetween in the thickness direction.

The plurality of emitter connection structures 35 may each be formed in a shape tapering toward the bottom wall. As a matter of course, the plurality of emitter connection structures 35 may be formed substantially perpendicular to the first main surface 3. The plurality of emitter connection structures 35 may have bottom walls formed in a shape curved toward the second main surface 4.

As a matter of course, the bottom walls of the plurality of emitter connection structures 35 may be formed substantially parallel to the first main surface 3. In this case, bottom wall corner portions of the plurality of emitter connection structures 35 may each be formed in a curved shape.

The plurality of emitter connection structures 35 may each have a width substantially equal to the width of the emitter structure 30 (the gate structure 20). As a matter of course, the width of the emitter connection structure 35 may be larger than the width of the emitter structure 30, or may be smaller than the width of the emitter structure 30.

The width of the emitter connection structure 35 may be not less than 0.5 μm and not more than 5 μm. The width of the emitter connection structure 35 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The width of the emitter connection structure 35 is preferably not less than 1 μm and not more than 2.5 μm.

The plurality of emitter connection structures 35 may each have a depth substantially equal to the depth of the emitter structure 30 (the gate structure 20). As a matter of course, the depth of the emitter connection structure 35 may be larger than the depth of the emitter structure 30, or may be smaller than the depth of the emitter structure 30.

The depth of the emitter connection structure 35 may be not less than 0.5 μm and not more than 10 μm. The depth of the emitter connection structure 35 may have a value belonging to at least one range among not less than 0.5 μm and not more than 1 μm, not less than 1 μm and not more than 2 μm, not less than 2 μm and not more than 4 μm, not less than 4 μm and not more than 6 μm, not less than 6 μm and not more than 8 μm, and not less than 8 μm and not more than 10 μm. The depth of the emitter connection structure 35 is preferably not less than 4 μm and not more than 8 μm.

The plurality of emitter connection structures 35 each include an emitter connection trench 36, an emitter connection insulating film 37, and an emitter connection embedded electrode 38. The emitter connection trench 36 is formed in the first main surface 3 and demarcates the wall surfaces (side walls and bottom wall) of the emitter connection structure 35. The emitter connection trench 36 communicates with the plurality of emitter trenches 31.

The emitter connection insulating film 37 may include at least one among a silicon oxide film, a silicon nitride film, and a silicon oxynitride film. The emitter connection insulating film 37 preferably includes the same type of insulator as the emitter insulating film 32 (the gate insulating film 22). In this embodiment, the emitter connection insulating film 37 has a single layer structure constituted of a silicon oxide film. The emitter connection insulating film 37 particularly preferably includes the silicon oxide film constituted of the oxide of the chip 2.

The emitter connection insulating film 37 covers the wall surfaces of the emitter connection trench 36 in a film shape. The emitter connection insulating film 37 is connected to the emitter insulating film 32 at a communication portion of the emitter trench 31 and the emitter connection trench 36.

The emitter connection insulating film 37 may have a thickness substantially equal to the thickness of the emitter insulating film 32 (the gate insulating film 22). As a matter of course, the thickness of the emitter connection insulating film 37 may be larger than the thickness of the emitter insulating film 32 (the gate insulating film 22), or may be smaller than the thickness of the emitter insulating film 32 (the gate insulating film 22).

The emitter connection insulating film 37 may have a thickness of not less than 10 nm and not more than 200 nm. The thickness of the emitter connection insulating film 37 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm. The thickness of the emitter connection insulating film 37 is preferably not less than 100 nm and not more than 150 nm.

The emitter connection embedded electrode 38 is embedded in the emitter connection trench 36 with the emitter connection insulating film 37 interposed therebetween. The emitter connection embedded electrode 38 is connected to the emitter embedded electrode 33 at a communication portion of the emitter trench 31 and the emitter connection trench 36. The emitter connection embedded electrode 38 faces the drift region 12 and the base region 15 with the emitter connection insulating film 37 interposed therebetween.

The electrode surface of the emitter connection embedded electrode 38 may be positioned on the bottom wall side of the emitter connection trench 36 with respect to the first main surface 3. The emitter connection embedded electrode 38 may contain one or both of a conductive polysilicon of the p-type and a conductive polysilicon of the n-type. The emitter connection embedded electrode 38 preferably includes the same type of conductor as the emitter embedded electrode 33 (the gate embedded electrode 23).

The transistor structure T3 includes a plurality of emitter regions 40 (impurity regions) of the n-type formed in the surface layer portion of the first main surface 3 in the corresponding active region 6. The plurality of emitter regions 40 form emitters of the main transistor structure T1.

Each of the emitter regions 40 has an n-type impurity concentration higher than the n-type impurity concentration of the drift region 12. In this embodiment, the emitter region 40 has a n-type impurity concentration higher than the p-type impurity concentration of the base region 15, and replaces the conductivity type of the base region 15 from the p-type to the n-type.

The plurality of emitter regions 40 are respectively formed in a surface layer portion in the base region 15 on both sides of the plurality of gate structures 20, and each extend in a band shape in the first direction X in conformance to the extension direction of the plurality of gate structures 20. The plurality of emitter regions 40 are formed at an interval toward the first main surface 3 side from the bottom portion of the base region 15.

The plurality of emitter regions 40 faces the gate embedded electrode 23 of the corresponding gate structure 20 with the gate insulating film 22 of the corresponding gate structure 20 interposed therebetween. The plurality of emitter regions 40 may face the emitter embedded electrode 33 of the corresponding emitter structure 30 with the emitter insulating film 32 of the corresponding emitter structure 30 interposed therebetween. As a matter of course, the plurality of emitter regions 40 may be formed at an interval from the plurality of emitter structures 30.

The transistor structure T3 includes a plurality of contact regions 41 of the p-type formed in a region different from the plurality of emitter regions 40 in the surface layer portion of the base region 15. The plurality of contact regions 41 each have a p-type impurity concentration higher than the p-type impurity concentration of the base region 15. The plurality of contact regions 41 are respectively formed on both sides of the plurality of gate structures 20 at an interval from the plurality of gate structures 20 and the plurality of emitter structures 30.

The plurality of contact regions 41 are respectively formed in regions on the bottom portion side of the base region 15 with respect to the plurality of emitter regions 40. The plurality of contact regions 41 are formed at an interval from the bottom portion of the base region 15 toward the first main surface 3 side. The plurality of contact regions 41 each extend in a band shape in the first direction X in conformance to the extension direction of the plurality of gate structures 20.

The transistor structure T3 includes a plurality of storage regions 42 of the n-type formed in the surface layer portion of the first main surface 3 in the corresponding active region 6. The storage region 42 may be referred to as a “carrier storage region.” The plurality of storage regions 42 each have an n-type impurity concentration higher than the n-type impurity concentration of the drift region 12. The n-type impurity concentration of the plurality of storage regions 42 may be lower than the n-type impurity concentration of the emitter region 40.

The plurality of storage regions 42 are formed in regions directly below the base region 15 on both sides of the plurality of gate structures 20, and each face the corresponding emitter region 40 in the thickness direction. The plurality of storage regions 42 each extend in a band shape in the first direction X in conformance to the extension direction of the plurality of gate structures 20.

The plurality of storage regions 42 are formed in a thickness range between the bottom portion of the base region 15 and the bottom wall of the gate structure 20. The plurality of storage regions 42 are formed at an interval toward the bottom portion side of the base region 15 from a depth position of the bottom wall of the gate structure 20.

The bottom portions of the plurality of storage regions 42 may be positioned on the first main surface 3 side with respect to a depth position of an intermediate portion of the gate structure 20. The bottom portions of the plurality of storage regions 42 may be positioned on the bottom wall side of the gate structure 20 with respect to the depth position of the intermediate portion of the gate structure 20.

The transistor structure T3 includes a plurality of well regions 43 of the p-type formed in the surface layer portion of the first main surface 3 in the corresponding active region 6. The plurality of well regions 43 each have a p-type impurity concentration lower than the p-type impurity concentration of the contact regions 41.

The plurality of well regions 43 may have a p-type impurity concentration higher than the p-type impurity concentration of the base region 15. As a matter of course, the p-type impurity concentration of the plurality of well regions 43 may be lower than the p-type impurity concentration of the base region 15. In this embodiment, the plurality of well regions 43 are formed to be in an electrically floating state.

The plurality of well regions 43 is respectively formed in regions between pairs of adjacent emitter structures 30. Specifically, the plurality of well regions 43 are respectively formed in a mesa region demarcated by the plurality of emitter structures 30 and the plurality of emitter connection structures 35.

The plurality of well regions 43 respectively have a bottom portion positioned on the bottom wall side of the plurality of emitter structures 30 with respect to the depth position of the bottom portion of the base region 15. The bottom portions of the plurality of well regions 43 are each positioned further to the bottom wall side of the plurality of emitter structures 30 than depth positions of intermediate portions of the plurality of emitter structures 30. In this embodiment, the bottom portions of the plurality of well regions 43 are positioned on the second main surface 4 side with respect to the bottom walls of the plurality of emitter structures 30.

The plurality of well regions 43 may have portions (the bottom portions) covering the bottom walls of the plurality of emitter structures 30 and the bottom walls of the plurality of emitter connection structures 35. The plurality of well regions 43 each extend in a band shape in the first direction X in conformance to the extension direction of the emitter structure 30, and are connected to the plurality of emitter structures 30 and the plurality of emitter connection structures 35.

The plurality of well regions 43 form an IE structure (injection enhanced structure) together with the plurality of emitter structures 30. The IE structure restricts a movement path of holes flowing into the base region 15 and accumulates the holes in a region directly below the base region 15. That is, the IE structure promotes reduction in on-resistance and reduction in on-voltage from the inside of the chip 2.

Referring to FIG. 7, the semiconductor device 1A includes an outer peripheral well region 44 of the p-type formed in the surface layer portion of the first main surface 3 in the outer peripheral region 8. The outer peripheral well region 44 has a p-type impurity concentration lower than the p-type impurity concentration of the contact regions 41.

The outer peripheral well region 44 may have a p-type impurity concentration higher than the p-type impurity concentration of the base region 15. As a matter of course, the p-type impurity concentration of the outer peripheral well region 44 may be lower than the p-type impurity concentration of the base region 15.

The p-type impurity concentration of the outer peripheral well region 44 may be substantially equal to the p-type impurity concentration of the well region 43. As a matter of course, the p-type impurity concentration of the outer peripheral well region 44 may be higher than the p-type impurity concentration of the well region 43, or may be lower than the p-type impurity concentration of the well region 43.

The outer peripheral well region 44 is formed at an interval inward from the peripheral edge of the first main surface 3, and extends in a band shape along the peripheral edge of the first main surface 3. In this embodiment, the outer peripheral well region 44 is formed in an annular shape surrounding the plurality of active regions 6.

The outer peripheral well region 44 is formed deeper than the base region 15 and is in contact with the outermost gate connection structure 25. The outer peripheral well region 44 is formed deeper than the outermost gate connection structure 25 and has a portion along the bottom wall of the outermost gate connection structure 25. In this embodiment, the outer peripheral well region 44 has a portion led out from the outside of the plurality of active regions 6 to the inside of the plurality of active regions 6 and covering the bottom walls of the plurality of gate structures 20.

The outer peripheral well region 44 extends in the vertical direction Z along the side walls of the plurality of gate structures 20 and the side walls of the plurality of gate connection structures 25 in the plurality of active regions 6, and is connected to the plurality of base regions 15 in the surface layer portion of the first main surface 3. An emitter potential is to be applied to the outer peripheral well region 44 via the plurality of base regions 15.

The depth of the outer peripheral well region 44 may be substantially equal to the depth of the plurality of well regions 43. As a matter of course, the depth of the outer peripheral well region 44 may be larger than the depth of the plurality of well regions 43, or may be smaller than the depth of the plurality of well regions 43.

Referring to FIG. 8, the semiconductor device 1A includes a plurality of street well regions 45 of the p-type respectively formed in the surface layer portion of the first main surface 3 in the plurality of street regions 9. One street well region 45 has a portion formed in the surface layer portion of the first main surface 3 in the temperature detecting region 10.

The street well region 45 may have a p-type impurity concentration higher than the p-type impurity concentration of the base region 15. As a matter of course, the p-type impurity concentration of the street well region 45 may be lower than the p-type impurity concentration of the base region 15.

The p-type impurity concentration of the street well region 45 may be substantially equal to the p-type impurity concentration of the well region 43. As a matter of course, the p-type impurity concentration of the street well region 45 may be higher than the p-type impurity concentration of the well region 43, or may be lower than the p-type impurity concentration of the well region 43.

The p-type impurity concentration of the street well region 45 may be substantially equal to the p-type impurity concentration of the outer peripheral well region 44. As a matter of course, the p-type impurity concentration of the street well region 45 may be higher than the p-type impurity concentration of the outer peripheral well region 44, or may be lower than the p-type impurity concentration of the outer peripheral well region 44.

The plurality of street well regions 45 are formed in a layer shape extending along the first main surface 3 in a region between the gate connection structure 25 on one active region 6 side and the gate connection structure 25 on the other active region 6 side, and are exposed from the first main surface 3. The plurality of street well regions 45 each extend in a band shape in the second direction Y in conformance to the extension direction of the plurality of street regions 9. The plurality of street well regions 45 are connected to the outer peripheral well region 44 in the outer peripheral region 8.

The plurality of street well regions 45 are formed deeper than the plurality of base regions 15 and are in contact with the plurality of gate connection structures 25. Specifically, the plurality of street well regions 45 are formed deeper than the plurality of gate connection structures 25 and have portions along the bottom walls of the plurality of gate connection structures 25.

In this embodiment, the plurality of street well regions 45 each have a width larger than the width of the corresponding street region 9 and have portions that protrude from the corresponding street region 9 into the plurality of active regions 6 and cover the bottom walls of the plurality of gate structures 20.

The plurality of street well regions 45 extend in the vertical direction Z along the side walls of the plurality of gate structures 20 and the side walls of the plurality of gate connection structures 25 in the plurality of active regions 6, and are connected to the plurality of base regions 15 in the surface layer portion of the first main surface 3. An emitter potential is to be applied to the plurality of street well regions 45 via the plurality of base regions 15.

The depth of the plurality of street well regions 45 may be substantially equal to the depth of the plurality of well regions 43. As a matter of course, the depth of the plurality of street well regions 45 may be larger than the depth of the plurality of well regions 43, or may be smaller than the depth of the plurality of well regions 43.

The depth of the plurality of street well regions 45 may be substantially equal to the depth of the outer peripheral well region 44. As a matter of course, the depth of the plurality of street well regions 45 may be larger than the depth of the outer peripheral well region 44, or may be smaller than the depth of the outer peripheral well region 44.

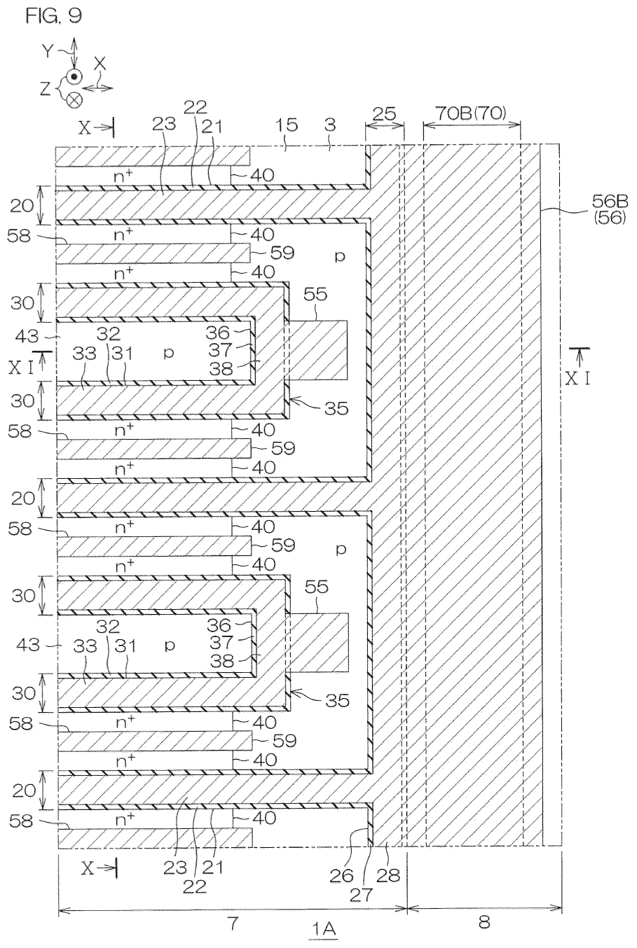

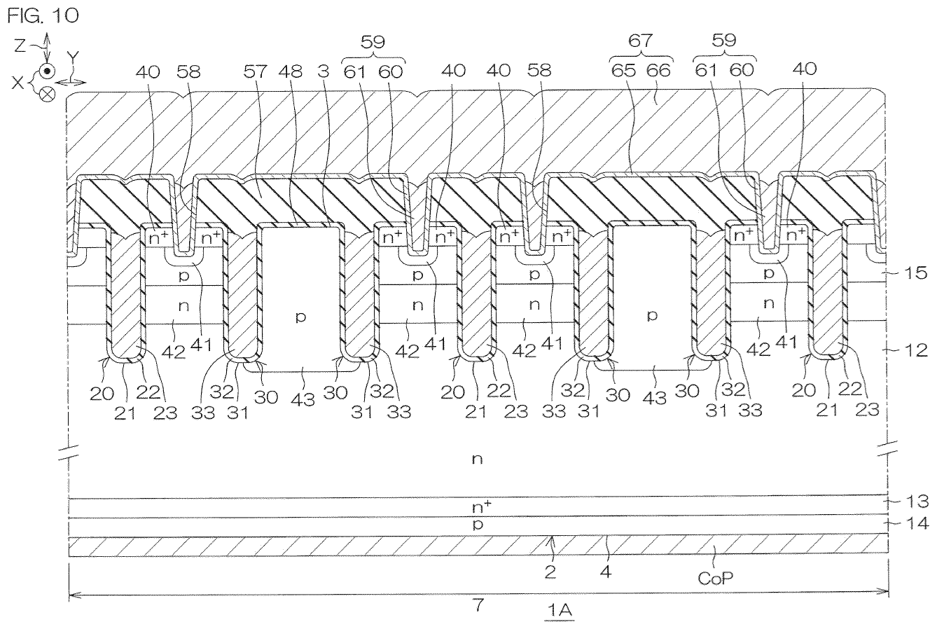

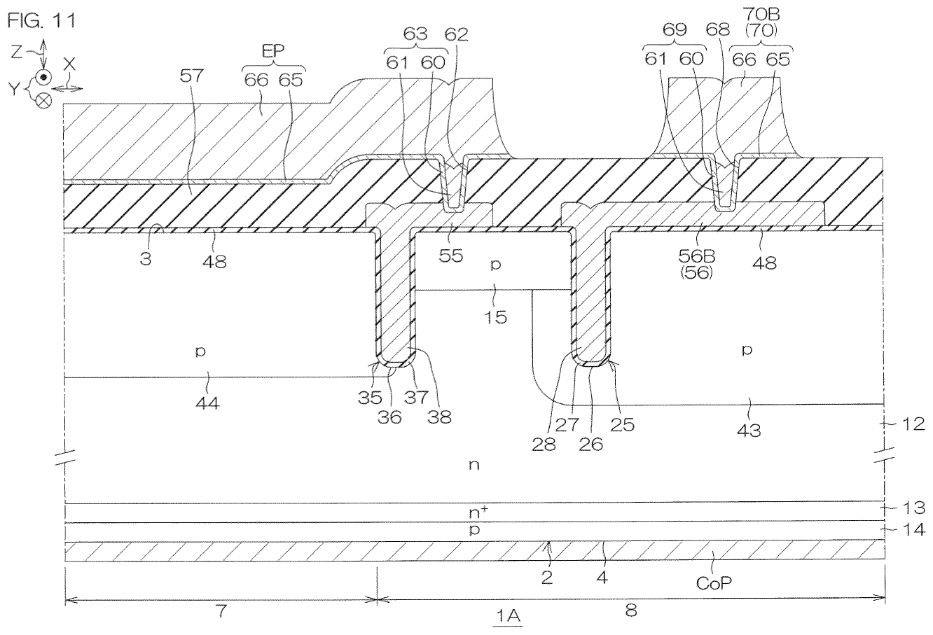

FIG. 9 is an enlarged plan view showing a principal portion of the monitor region 7. FIG. 10 is a sectional view taken along line X-X shown in FIG. 9. FIG. 11 is a sectional view taken along line XI-XI shown in FIG. 9.

Referring to FIG. 9 to FIG. 11, the semiconductor device 1A includes the monitor transistor structure T2 in the monitor region 7. Similarly to the transistor structure T3 (active region 6), the monitor transistor structure T2 (monitor region 7) includes the base region 15, the plurality of gate structures 20, the plurality of gate connection structures 25, the plurality of emitter structures 30, the plurality of emitter connection structures 35, the plurality of emitter regions 40, the contact region 41, the plurality of storage regions 42, and the plurality of well regions 43.

The base region 15, the gate structure 20, the gate connection structure 25, the emitter structure 30, the emitter connection structure 35, the emitter region 40, the contact region 41, the storage region 42, and the well region 43 of the monitor region 7 may be referred to as a “monitor base region (15),” a “monitor gate structure (20),” a “monitor gate connection structure (25),” a “monitor emitter structure (30),” a “monitor emitter connection structure (35),” a “monitor emitter region (40),” a “monitor contact region (41),” a “monitor storage region (42),” and a “monitor well region (43),” respectively.

These components in the monitor region 7 each have the same layout as the corresponding components in the active region 6. The description of the corresponding components in the active region 6 applies to the description of these components in the monitor region 7. These components of the monitor region 7 are laid out in a plane area smaller than the total plane area of the plurality of active regions 6.

That is, since the channel area of the monitor region 7 (total area of the emitter regions 40) is smaller than the channel area of the active regions 6 (total area of the emitter regions 40), the monitor current Im of the monitor transistor structure T2 is less than the output current Ice of the main transistor structure T1 (transistor structure T3).

The semiconductor device 1A includes a main surface insulating film 48 selectively covering the first main surface 3. The main surface insulating film 48 may include at least one among a silicon oxide film, a silicon nitride film, and a silicon oxynitride film.

The main surface insulating film 48 preferably includes the same type of insulator as the gate insulating film 22 (the emitter insulating film 32). In this embodiment, the main surface insulating film 48 has a single layer structure constituted of a silicon oxide film. The main surface insulating film 48 particularly preferably includes the silicon oxide film constituted of the oxide of the chip 2.

The main surface insulating film 48 has a portion selectively covering the plurality of active regions 6, a portion selectively covering the monitor region 7, a portion selectively covering the outer peripheral region 8, and a portion selectively covering the plurality of street regions 9.

The main surface insulating film 48 covers the plurality of base regions 15, the plurality of emitter regions 40, and the plurality of well regions 43 in the plurality of active regions 6. The main surface insulating film 48 is connected to the plurality of gate insulating films 22, the plurality of gate connection insulating films 27, the plurality of emitter insulating films 32, and the plurality of emitter connection insulating films 37 in the plurality of active regions 6, and exposes the plurality of gate embedded electrodes 23, the plurality of gate connection embedded electrodes 28, the plurality of emitter embedded electrodes 33, and the plurality of emitter connection embedded electrodes 38.

The main surface insulating film 48 covers the plurality of base regions 15, the plurality of emitter regions 40, and the plurality of well regions 43 in the monitor region 7. The main surface insulating film 48 is connected to the plurality of gate insulating films 22, the plurality of gate connection insulating films 27, the plurality of emitter insulating films 32, and the plurality of emitter connection insulating films 37 in the monitor region 7, and exposes the plurality of gate embedded electrodes 23, the plurality of gate connection embedded electrodes 28, the plurality of emitter embedded electrodes 33, and the plurality of emitter connection embedded electrodes 38.

The main surface insulating film 48 covers the outer peripheral well region 44 in the outer peripheral region 8. The main surface insulating film 48 is connected to the plurality of gate connection insulating films 27 in the outer peripheral region 8, and exposes the plurality of gate connection embedded electrodes 28.

The main surface insulating film 48 may be continuous with the peripheral edge (the first to fourth side surfaces 5A to 5D) of the chip 2. As a matter of course, the main surface insulating film 48 may be formed at an interval inward from the peripheral edge of the chip 2 and expose the drift region 12 from the peripheral edge portion of the chip 2.

The main surface insulating film 48 covers the plurality of street well regions 45 in the plurality of street regions 9. The main surface insulating film 48 is connected to the plurality of gate connection insulating films 27 in the plurality of street regions 9, and exposes the plurality of gate connection embedded electrodes 28.

The main surface insulating film 48 may have a thickness substantially equal to the thickness of the gate insulating film 22 (gate connection insulating film 27). As a matter of course, the thickness of the main surface insulating film 48 may be larger than the thickness of the gate insulating film 22 (gate connection insulating film 27), or may be smaller than the thickness of the gate insulating film 22 (gate connection insulating film 27).

The thickness of the main surface insulating film 48 may be substantially equal to the thickness of the emitter insulating film 32 (emitter connection insulating film 37). As a matter of course, the thickness of the main surface insulating film 48 may be larger than the thickness of the emitter insulating film 32 (emitter connection insulating film 37), or may be smaller than the thickness of the emitter insulating film 32 (emitter connection insulating film 37).

The thickness of the main surface insulating film 48 may be not less than 10 nm and not more than 200 nm. The thickness of the main surface insulating film 48 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm. The thickness of the main surface insulating film 48 is preferably not less than 100 nm and not more than 150 nm.

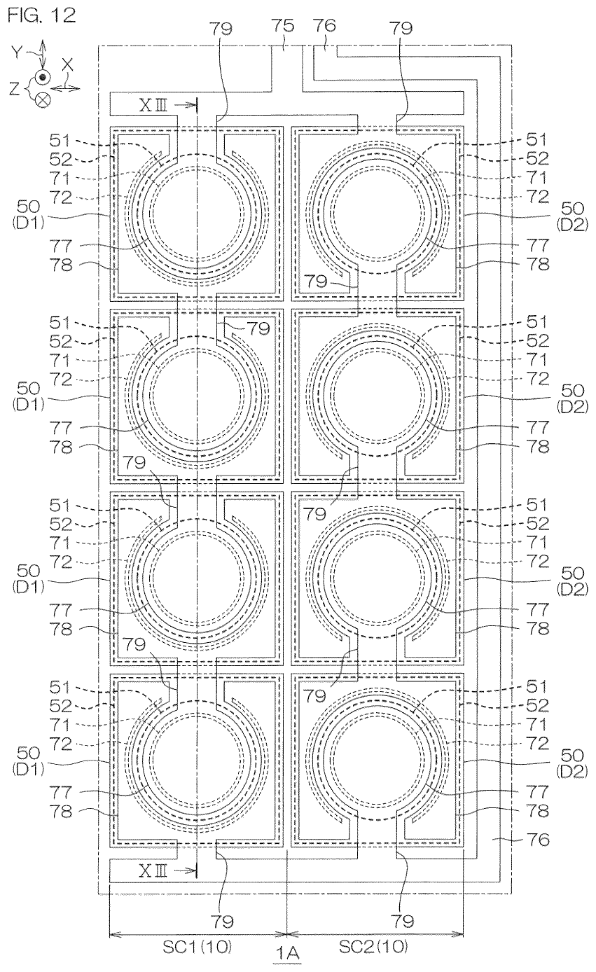

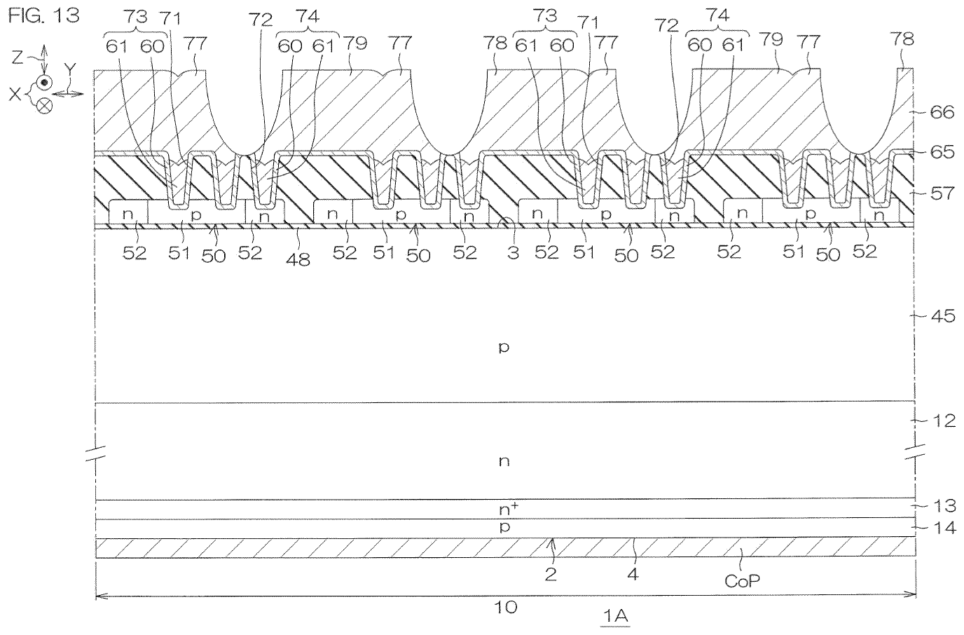

FIG. 12 is an enlarged plan view showing the temperature detecting region 10. FIG. 13 is a sectional view taken along line XIII-XIII shown in FIG. 12. Referring to FIG. 12 and FIG. 13, the semiconductor device 1A includes the temperature sensitive diode structure D arranged on the main surface insulating film 48 in the temperature detecting region 10. Hereinafter, the arrangement of the temperature sensitive diode structure D as one component of the semiconductor device 1A shall be described.

The temperature sensitive diode structure D includes one or a plurality of (in this embodiment, a plurality of) polysilicon layers 50 arranged on the main surface insulating film 48. The number of polysilicon layers 50 is arbitrary, and is appropriately adjusted according to the number of first diodes D1 and the number of second diodes D2.

In this embodiment, the semiconductor device 1A includes four polysilicon layers 50 for the first diode D1 and four polysilicon layers 50 for the second diode D2. In this embodiment, the plurality of polysilicon layer 50 are arrayed in a matrix pattern of 4 rows×2 columns at intervals in the first direction X and the second direction Y.

In this embodiment, four polysilicon layers 50 for the first diode D1 are arrayed in a row in the first column (one side in the second direction Y), and four polysilicon layers 50 for the second diode D2 are arranged in a row in the second column (the other side in the second direction Y).

The plurality of polysilicon layers 50 are directly arranged on the main surface insulating film 48, and face the street well region 45 with the main surface insulating film 48 interposed therebetween. In this embodiment, the plurality of polysilicon layers 50 are formed in polygonal shapes having four sides parallel to the peripheral edge of the chip 2 in plan view. The plurality of polysilicon layers 50 may each be formed in a quadrangular shape, a hexagonal shape, a circular shape, etc., in plan view.

The plurality of polysilicon layers 50 have a thickness larger than the thickness of the main surface insulating film 48. The thickness of the plurality of polysilicon layers 50 may be less than the depth (thickness) of the street well region 45. The thickness of the plurality of polysilicon layers 50 may be less than the depth of the gate structure 20 (emitter structure 30). The thickness of the plurality of polysilicon layers 50 may be less than the depth of the gate connection structure 25 (emitter connection structure 35).

The thickness of the plurality of polysilicon layers 50 may be not less than 0.1 μm and not more than 2 μm. The thickness of the polysilicon layer 50 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1.25 μm and not more than 1.5 μm, not less than 1.5 μm and not more than 1.75 μm, and not less than 1.75 μm and not more than 2 μm. The thickness of the polysilicon layer 50 is preferably not less than 0.25 μm and not more than 1.25 μm.

The temperature sensitive diode structure D includes a plurality of p-type anode regions 51 respectively formed in the plurality of polysilicon layers 50. The plurality of anode regions 51 are formed in the inner portion (preferably the central portion) of the corresponding polysilicon layer 50 at an interval from a peripheral edge of the corresponding polysilicon layer 50.

The plurality of anode regions 51 are formed in polygonal shapes or circular shapes in plan view. The plurality of anode regions 51 may each be formed in a quadrangular shape, a hexagonal shape, or the like in plan view. The plurality of anode regions 51 are formed over the entire region of the thickness range of the corresponding polysilicon layer 50.

The temperature sensitive diode structure D includes a plurality of n-type cathode regions 52 respectively formed in the plurality of polysilicon layers 50. The plurality of cathode regions 52 are each formed at a peripheral edge portion of the corresponding polysilicon layer 50.

The plurality of cathode regions 52 each extend in a band shape along the peripheral edge of the corresponding anode region 51 in plan view. In this embodiment, the plurality of cathode regions 52 each extend in an annular shape along the peripheral edge of the corresponding polysilicon layer 50 in plan view, and are each electrically connected to the corresponding anode region 51 over the entire periphery.

The plurality of cathode regions 52 are formed over the entire region of the thickness range of the corresponding polysilicon layer 50, and are exposed from the side walls of the corresponding polysilicon layer 50. The plurality of cathode regions 52 each form a pn-junction portion as the first diode D1 or a pn-junction portion as the second diode D2 with the corresponding anode region 51.

Hereinafter, the wiring structure on the first main surface 3 shall be described. Referring again to FIG. 1 to FIG. 11, the semiconductor device 1A includes a plurality of emitter wirings 55 each electrically connected to the corresponding emitter connection structure 35 on the first main surface 3 in the plurality of active regions 6 and the monitor region 7.

The plurality of emitter wirings 55 are each arranged on the main surface insulating film 48, and are each connected to the corresponding emitter connection structure 35. In this embodiment, the plurality of emitter wirings 55 are each formed integrally with the corresponding emitter connection embedded electrode 38, and each include a lead-out portion led out from the corresponding emitter connection embedded electrode 38 onto the main surface insulating film 48.

That is, the plurality of emitter wirings 55 are each made of the same type of conductor as the emitter connection embedded electrode 38 (one or both of the conductive polysilicon of the p-type and the conductive polysilicon of the n-type). The plurality of emitter wirings 55 are formed at an interval toward the corresponding emitter connection structure 35 side from the plurality of gate connection structures 25, and face the base region 15 in the thickness direction with the main surface insulating film 48 interposed therebetween.

The plurality of emitter wirings 55 have a thickness larger than the thickness of the main surface insulating film 48. The thickness of the plurality of emitter wirings 55 may be less than the depth (thickness) of the well region 43. The thickness of the plurality of emitter wirings 55 may be less than the depth of the gate structure 20 (gate connection structure 25) and the depth of the emitter structure 30 (emitter connection structure 35). As a matter of course, the thickness of the plurality of emitter wirings 55 may be larger than the depth of the gate structure 20 (gate connection structure 25) and the depth of the emitter structure 30 (emitter connection structure 35).

The thickness of the plurality of emitter wirings 55 may be substantially equal to the thickness of the plurality of polysilicon layers 50. As a matter of course, the thickness of the plurality of emitter wirings 55 may be larger than the thickness of the plurality of polysilicon layers 50, or may be smaller than the thickness of the plurality of polysilicon layers 50.

The thickness of the plurality of emitter wirings 55 may be not less than 0.1 μm and not more than 2 μm. The thickness of the emitter wiring 55 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1.25 μm and not more than 1.5 μm, not less than 1.5 μm and not more than 1.75 μm, and not less than 1.75 μm and not more than 2 μm. The thickness of the emitter wiring 55 is preferably not less than 0.25 μm and not more than 1.25 μm.

The semiconductor device 1A includes a plurality of gate wirings 56 each electrically connected to the corresponding gate connection structure 25 on the first main surface 3 in the outer peripheral region 8 and the plurality of street regions 9.

The plurality of gate wirings 56 are each arranged on the main surface insulating film 48, and are each connected to the corresponding gate connection structure 25. In this embodiment, the plurality of gate wirings 56 are each formed integrally with the corresponding gate connection embedded electrode 28, and each include a lead-out portion led out from the corresponding gate connection embedded electrode 28 onto the main surface insulating film 48. That is, the plurality of gate wirings 56 are each made of the same type of conductor as the gate connection embedded electrode 28 (one or both of the conductive polysilicon of the p-type and the conductive polysilicon of the n-type).

The plurality of gate wirings 56 include one or a plurality of (in this embodiment, a plurality of) first gate wirings 56A arranged in the outer peripheral region 8 and one or a plurality of (in this embodiment, a plurality of) second gate wirings 56B arranged in the plurality of street regions 9.

The plurality of first gate wirings 56A are arranged on the main surface insulating film 48 in the outer peripheral region 8, and are routed in a band shape in a region between the gate pad region 11G and the corresponding gate connection structure 25 (gate connection embedded electrode 28). The plurality of first gate wirings 56A are formed along the plurality of active regions 6, and each have a portion extending in the first direction X and a portion extending in the second direction Y.

The plurality of first gate wirings 56A face the outer peripheral well region 44 with the main surface insulating film 48 interposed therebetween. The plurality of first gate wirings 56A are led out from above the main surface insulating film 48 onto the gate connection structure 25 (gate connection embedded electrode 28) adjacent to the outer peripheral region 8, and are connected to the gate connection structure 25 (gate connection embedded electrode 28). The plurality of first gate wirings 56A are electrically connected to the plurality of gate structures 20 via the gate connection structure 25 (gate connection embedded electrode 28).

The plurality of second gate wirings 56B are respectively arranged on the main surface insulating film 48 in the plurality of street regions 9, and are routed in a band shape in a region between the gate pad region 11G and the corresponding gate connection structure 25 (gate connection embedded electrode 28).

The plurality of second gate wirings 56B each extend in a band shape in the second direction Y in conformance to the extension direction of the plurality of street regions 9. One second gate wiring 56B is routed in the street region 9 so as to bypass the plurality of polysilicon layers 50 (temperature sensitive diode structure D).

The plurality of second gate wirings 56B are respectively connected to the gate connection structures 25 (gate connection embedded electrodes 28) of one and the other active regions 6 adjacent to each other in the first direction X. That is, the plurality of second gate wirings 56B are electrically connected to the plurality of gate structures 20 via the plurality of gate connection structure 25 (gate connection embedded electrode 28) demarcating the plurality of street regions 9.

At least one gate wiring 56 (in this embodiment, one second gate wiring 56B) of the plurality of gate wirings 56 is connected to the gate connection structure 25 (gate connection embedded electrode 28) of the monitor region 7. The gate structure 20 of the monitor region 7 is thereby on/off controlled simultaneously with the gate structure 20 of the active region 6.

The plurality of gate wirings 56 have a thickness larger than the thickness of the main surface insulating film 48. The thickness of the plurality of gate wirings 56 may be less than the depth (thickness) of the well region 43. The thickness of of the plurality of gate wirings 56 may be less than the depth of the gate structure 20 (gate connection structure 25) and the depth of the emitter structure 30 (emitter connection structure 35). As a matter of course, the thickness of the plurality of gate wirings 56 may be larger than the depth of the gate structure 20 (gate connection structure 25) and the depth of the emitter structure 30 (emitter connection structure 35).

The thickness of the plurality of gate wirings 56 may be substantially equal to the thickness of the plurality of polysilicon layers 50. As a matter of course, the thickness of the plurality of gate wirings 56 may be larger than the thickness of the plurality of polysilicon layers 50, or may be smaller than the thickness of the plurality of polysilicon layers 50.

The thickness of the plurality of gate wirings 56 may be substantially equal to the thickness of the plurality of emitter wirings 55. As a matter of course, the thickness of the plurality of gate wirings 56 may be larger than the thickness of the plurality of emitter wirings 55, or may be smaller than the thickness of the plurality of emitter wirings 55.

The thickness of the plurality of gate wirings 56 may be not less than 0.1 μm and not more than 2 μm. The thickness of the gate wiring 56 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1.25 μm and not more than 1.5 μm, not less than 1.5 μm and not more than 1.75 μm, and not less than 1.75 μm and not more than 2 μm. The thickness of the gate wiring 56 is preferably not less than 0.25 μm and not more than 1.25 μm.

The semiconductor device 1A includes an interlayer film 57 selectively covering the main surface insulating film 48. The interlayer film 57 may include at least one among a silicon oxide film, a silicon nitride film, and a silicon oxynitride film. The interlayer film 57 may have a single layer structure constituted of a single insulating film or a laminated structure constituted of a plurality of insulating films.

The interlayer film 57 may include at least one among an NSG (non-doped silicate glass) film, a PSG (phosphor silicate glass) film, and a BPSG (boron phosphor silicate glass) film as an example of a silicon oxide film.

The interlayer film 57 has a portion covering the plurality of active regions 6, a portion covering the monitor region 7, a portion covering the outer peripheral region 8, a portion covering the plurality of street regions 9, and a portion covering the temperature detecting region 10.

The interlayer film 57 covers the plurality of base regions 15, the plurality of emitter regions 40, and the plurality of well regions 43 with the main surface insulating film 48 interposed therebetween in the plurality of active regions 6 and the monitor region 7. The interlayer film 57 covers the plurality of gate structures 20, the plurality of gate connection structures 25, the plurality of emitter structures 30, and the plurality of emitter connection structures 35 in the plurality of active regions 6 and the monitor region 7.

Specifically, the interlayer film 57 covers the plurality of gate embedded electrodes 23, the plurality of gate connection embedded electrodes 28, the plurality of emitter embedded electrodes 33, and the plurality of emitter connection embedded electrodes 38. In this embodiment, the interlayer film 57 enters the plurality of gate trenches 21, the plurality of gate connection trenches 26, the plurality of emitter trenches 31, and the plurality of emitter connection trenches 36 from above the main surface insulating film 48.

The interlayer film 57 has a portion covering the electrode surfaces of the plurality of gate embedded electrodes 23 in the plurality of gate trenches 21. The interlayer film 57 has a portion covering the electrode surfaces of the plurality of gate connection embedded electrodes 28 in the plurality of gate connection trenches 26.

The interlayer film 57 has a portion covering the electrode surfaces of the plurality of emitter embedded electrodes 33 in the plurality of emitter trenches 31. The interlayer film 57 has a portion covering the electrode surfaces of the plurality of emitter connection embedded electrodes 38 in the plurality of emitter connection trenches 36.

The interlayer film 57 covers the outer peripheral well region 44 with the main surface insulating film 48 interposed therebetween in the outer peripheral region 8. The interlayer film 57 may be continuous to the peripheral edge (the first to fourth side surfaces 5A to 5D) of the chip 2. As a matter of course, the interlayer film 57 may be formed at an interval inward from the peripheral edge of the chip 2 and expose the drift region 12 from the peripheral edge portion of the chip 2.

The interlayer film 57 covers the plurality of street well regions 45 with the main surface insulating film 48 interposed therebetween in the plurality of street regions 9. The interlayer film 57 covers the plurality of polysilicon layers 50 in the temperature detecting region 10.

The interlayer film 57 collectively covers the plurality of polysilicon layers 50 by filling a gap portion between the plurality of polysilicon layers 50. The interlayer film 57 is in contact with the main surface insulating film 48 in the gap portion. That is, the interlayer film 57 faces the street well region 45 with the main surface insulating film 48 interposed therebetween in the gap portion.

The interlayer film 57 has a thickness larger than the thickness of the main surface insulating film 48. The thickness of the interlayer film 57 may be less than the depth of the gate structure 20 (the gate connection structure 25) and the depth of the emitter structure 30 (the emitter connection structure 35). As a matter of course, the thickness of the interlayer film 57 may be larger than the depth of the gate structure 20 (the gate connection structure 25) and the depth of the emitter structure 30 (the emitter connection structure 35).

The thickness of the interlayer film 57 is preferably larger than the thicknesses of the plurality of polysilicon layers 50. As a matter of course, the thickness of the interlayer film 57 may be smaller than the thickness of the plurality of polysilicon layers 50. The thickness of the interlayer film 57 is preferably larger than the thicknesses of the plurality of emitter wirings 55.

As a matter of course, the thickness of the interlayer film 57 may be smaller than the thickness of the plurality of emitter wirings 55. The thickness of the interlayer film 57 is preferably larger than the thicknesses of the plurality of gate wirings 56. As a matter of course, the thickness of the interlayer film 57 may be smaller than the thickness of the plurality of gate wirings 56.

The interlayer film 57 may have a thickness of not less than 0.1 μm and not more than 3 μm. The thickness of the interlayer film 57 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The thickness of the interlayer film 57 is preferably not less than 0.5 μm and not more than 2 μm.

The semiconductor device 1A includes a plurality of first emitter openings 58 formed in the interlayer film 57 in the plurality of active regions 6 and the monitor region 7. The plurality of first emitter openings 58 are respectively formed on both sides of the plurality of gate structures 20 at an interval from the plurality of gate structures 20, and pass through the main surface insulating film 48 and the interlayer film 57 and expose the chip 2. Specifically, the plurality of first emitter openings 58 each expose the corresponding emitter region 40 and the corresponding contact region 41.

The plurality of first emitter openings 58 are recessed in the thickness direction of the chip 2 from the height position of the first main surface 3 and respectively have a bottom wall positioned inside the chip 2. The bottom walls of the plurality of first emitter openings 58 are formed at an interval toward the first main surface 3 side from the bottom portions of the corresponding base regions 15 and respectively expose the corresponding contact regions 41. The bottom walls of the plurality of first emitter openings 58 are formed at an interval toward the first main surface 3 side from the bottom portions of the corresponding contact regions 41.

The plurality of first emitter openings 58 may each be formed in a shape tapering toward the bottom wall. As a matter of course, the plurality of first emitter openings 58 may be formed substantially perpendicular to the first main surface 3. The plurality of first emitter openings 58 may have bottom walls formed in a shape curved toward the second main surface 4.

As a matter of course, the plurality of first emitter openings 58 may be formed substantially parallel to the first main surface 3. In this case, bottom wall corner portions of the plurality of first emitter openings 58 may each be formed in a curved shape.

The plurality of first emitter openings 58 each extend in a band shape in the first direction X in conformance to the extension direction of the plurality of gate structures 20. The plurality of first emitter openings 58 each have a length shorter than the length of the plurality of gate structures 20 in the longitudinal direction (the first direction X). The length of the plurality of first emitter openings 58 may be shorter than the length of the plurality of emitter structures 30.

The semiconductor device 1A includes a plurality of first emitter via electrodes 59 respectively embedded in the plurality of first emitter openings 58. The plurality of first emitter via electrodes 59 are each electrically connected to the corresponding emitter region 40 and the corresponding contact region 41 in the plurality of first emitter openings 58.

The plurality of first emitter via electrodes 59 may each have a laminated structure including a first electrode 60 and a second electrode 61 that are laminated in that order from the wall surface side of the plurality of first emitter openings 58.

The first electrode 60 is formed as a barrier electrode in a film shape on the wall surface of the first emitter opening 58. The first electrode 60 is electrically connected to the emitter region 40 and the contact region 41 in the first emitter opening 58.

The first electrode 60 may have a single layer structure that includes a titanium film or a titanium nitride film. The first electrode 60 may have a laminated structure that includes a titanium film and a titanium nitride film. In this case, the titanium nitride film may be laminated on the titanium film.

The second electrode 61 is embedded in the first emitter opening 58 with the first electrode 60 interposed therebetween, and is electrically connected to the emitter region 40 and the contact region 41 via the first electrode 60. The second electrode 61 may include at least one of a tungsten film, a molybdenum film, a nickel film, a pure aluminum film, a pure copper film, an AlCu alloy film, an AlSi alloy film, and an AlSiCu alloy film. The second electrode 61 preferably includes a tungsten film.

The semiconductor device 1A includes a plurality of second emitter openings 62 formed in the interlayer film 57 in the plurality of active regions 6 and the monitor region 7. The plurality of second emitter openings 62 pass through the interlayer film 57 and each expose the corresponding emitter wiring 55.

In this embodiment, the plurality of second emitter openings 62 are further recessed from the wiring surface of the corresponding emitter wiring 55 toward the main surface insulating film 48 side and each have a bottom wall positioned in the corresponding emitter wiring 55.

The plurality of second emitter openings 62 may each be formed in a shape tapering toward the bottom wall. As a matter of course, the plurality of second emitter openings 62 may be formed substantially perpendicular to the first main surface 3. The plurality of second emitter openings 62 may each be formed in a polygonal shape, a circular shape, etc., in plan view. The plurality of second emitter openings 62 may each be formed in a quadrangular shape or a hexagonal shape in plan view.

The semiconductor device 1A includes a plurality of second emitter via electrodes 63 respectively embedded in the plurality of second emitter openings 62. The plurality of second emitter via electrodes 63 are mechanically and electrically connected to the corresponding emitter wirings 55 in the plurality of second emitter openings 62, respectively. Similarly to the first emitter via electrode 59, the plurality of second emitter via electrodes 63 may each have a laminated structure including the first electrode 60 and the second electrode 61.

The semiconductor device 1A includes the above-described emitter pad EP that collectively covers the plurality of active regions 6 on the first main surface 3. The emitter pad EP is a terminal to which an emitter potential is to be applied from the exterior. The emitter pad EP may be referred to as an “emitter pad electrode,” an “emitter terminal electrode,” an “emitter external terminal,” etc.

The emitter pad EP is arranged on a portion of the interlayer film 57 covering the plurality of active regions 6. The emitter pad EP is electrically separated from the plurality of gate structures 20 and the plurality of gate connection structures 25 by the interlayer film 57.

The emitter pad EP is mechanically and electrically connected to the plurality of first emitter via electrodes 59 and the plurality of second emitter via electrodes 63 on the interlayer film 57, and is electrically connected to the plurality of emitter structures 30, the plurality of emitter connection structures 35, the plurality of emitter regions 40, and the plurality of contact regions 41 via the plurality of first emitter via electrodes 59 and the plurality of second emitter via electrodes 63.

The emitter pad EP includes a plurality of street removed portions 64. The plurality of street removed portions 64 respectively expose portions of the interlayer film 57 covering the plurality of street regions 9 and each extend in a band shape in the second direction Y in conformance to the extension direction of the corresponding street region 9.

The emitter pad EP may have a thickness larger than the thickness of the interlayer film 57. The thickness of the emitter pad EP may be not less than 0.5 μm and not more than 10 μm. The thickness of the emitter pad EP may have a value belonging to at least one range among not less than 0.5 μm and not more than 1 μm, not less than 1 μm and not more than 2 μm, not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 7 μm and not more than 8 μm, not less than 8 μm and not more than 9 μm, and not less than 9 μm and not more than 10 μm.

The emitter pad EP may have a laminated structure including a first electrode film 65 and a second electrode film 66 that are laminated in that order from the interlayer film 57 side. The first electrode film 65 covers the interlayer film 57 in a film shape as a barrier electrode. The first electrode film 65 is electrically connected to the plurality of first emitter via electrodes 59 and the plurality of second emitter via electrodes 63 on the interlayer film 57.

The first electrode film 65 is electrically connected to the first electrodes 60 of the plurality of first emitter via electrodes 59 and the first electrodes 60 of the plurality of second emitter via electrodes 63. As a matter of course, the first electrode film 65 may cover the first electrodes 60 of the plurality of first emitter via electrodes 59 and the first electrodes 60 of the plurality of second emitter via electrodes 63.

The first electrode film 65 may have a single layer structure that includes a titanium film or a titanium nitride film. The first electrode film 65 may have a laminated structure that includes a titanium film and a titanium nitride film. In this case, the titanium nitride film may be laminated on the titanium film.

The second electrode film 66 has a thickness larger than the thickness of the first electrode film 65 and covers the first electrode film 65 in a film shape. The second electrode film 66 covers the plurality of first emitter via electrodes 59 and the plurality of second emitter via electrodes 63 in a film shape.

The second electrode film 66 is electrically connected to the plurality of first emitter via electrodes 59 and the plurality of second emitter via electrodes 63. The second electrode film 66 may include at least one of a pure aluminum film, a pure copper film, an AlCu alloy film, an AlSi alloy film, and an AlSiCu alloy film.

The semiconductor device 1A includes a monitor electrode 67 covering the monitor region 7 on the first main surface 3. The monitor electrode 67 is arranged on a portion of the interlayer film 57 covering the monitor region 7. The monitor electrode 67 is electrically separated from the plurality of gate structures 20 and the plurality of gate connection structures 25 by the interlayer film 57 in the monitor region 7. The monitor electrode 67 is mechanically and electrically connected to the plurality of first emitter via electrodes 59 and the plurality of second emitter via electrodes 63 on the interlayer film 57 in the monitor region 7.

The monitor electrode 67 is electrically connected to the plurality of emitter structures 30, the plurality of emitter connection structures 35, the plurality of emitter regions 40, and the plurality of contact regions 41 via the plurality of first emitter via electrodes 59 and the plurality of second emitter via electrodes 63. As with the emitter pad EP, the monitor electrode 67 may have a laminated structure including the first electrode film 65 and the second electrode film 66 that are laminated in that order from the interlayer film 57 side.

The monitor electrode 67 may have a thickness larger than the thickness of the interlayer film 57. The thickness of the monitor electrode 67 may be substantially equal to the thickness of the emitter pad EP. The thickness range of the monitor electrode 67 is similar to the thickness range (not less than 0.5 μm and not more than 10 μm) of the emitter pad EP.

The semiconductor device 1A includes a plurality of gate openings 68 formed in the interlayer film 57 in the outer peripheral region 8 and the plurality of street regions 9. The plurality of gate openings 68 pass through the interlayer film 57 and selectively expose a portion of the plurality of gate wirings 56.

The plurality of gate openings 68 may each extend in a band shape in conformance to the extension direction of the plurality of gate wirings 56. The plurality of gate openings 68 may be formed at intervals in conformance to the extension direction of the plurality of gate wirings 56. In this case, the plurality of gate openings 68 may each be formed in a polygonal shape or a circular shape in plan view. The plurality of gate openings 68 may each be formed in a quadrangular shape, a hexagonal shape, etc., in plan view.

In this embodiment, the plurality of gate openings 68 are further dug in from the wiring surface of the corresponding gate wiring 56 toward the main surface insulating film 48 side and each have a bottom wall positioned in the corresponding gate wiring 56. The plurality of gate openings 68 may each be formed in a shape tapering toward the bottom wall. As a matter of course, the plurality of gate openings 68 may be formed substantially perpendicular to the first main surface 3.

The semiconductor device 1A includes a plurality of gate via electrodes 69 respectively embedded in the plurality of gate openings 68. The plurality of gate via electrodes 69 are mechanically and electrically connected to the corresponding gate wirings 56 in the plurality of gate openings 68, respectively. As with the first emitter via electrode 59, the plurality of gate via electrodes 69 may each have a laminated structure including the first electrode 60 and the second electrode 61.

The semiconductor device 1A includes a plurality of gate fingers 70 arranged on the interlayer film 57. The gate finger 70 may be referred to as a “gate finger electrode,” a “finger electrode,” etc. The plurality of gate fingers 70 are arranged on a portion of the interlayer film 57 covering the plurality of gate wirings 56.

The plurality of gate fingers 70 are mechanically and electrically connected to the plurality of gate via electrodes 69 on the interlayer film 57, and are electrically connected to the plurality of gate wirings 56 via the plurality of gate via electrodes 69. The plurality of gate fingers 70 are electrically connected to the plurality of gate structures 20 in the plurality of active regions 6 and the plurality of gate structures 20 in the monitor region 7 via the plurality of gate wirings 56.

The plurality of gate fingers 70 include a plurality of first gate fingers 70A arranged in the outer peripheral region 8 and a plurality of second gate fingers 70B arranged in the plurality of street regions 9.

The plurality of first gate fingers 70A are respectively arranged on the plurality of first gate wirings 56A in the outer peripheral region 8. The plurality of first gate fingers 70A are routed in a band shape in a region between the gate pad region 11G and the corresponding gate connection structure 25 (the gate connection embedded electrode 28) in conformance to the extension direction of the plurality of first gate wirings 56A.

The plurality of first gate fingers 70A are formed along the plurality of active regions 6, and each have a portion extending in the first direction X and a portion extending in the second direction Y. The plurality of first gate fingers 70A are mechanically and electrically connected to the plurality of gate via electrodes 69 on the interlayer film 57, and are electrically connected to the plurality of first gate wirings 56A via the plurality of gate via electrodes 69.

The plurality of second gate fingers 70B are respectively arranged on the plurality of second gate wirings 56B in the plurality of street regions 9. The plurality of second gate fingers 70B are routed in a band shape in a region between the gate pad region 11G and the corresponding gate connection structure 25 (the gate connection embedded electrode 28) in conformance to the extension direction of the plurality of first gate wirings 56A.

The plurality of second gate fingers 70B each have a portion interposed in the plurality of street removed portions 64 of the emitter pad EP, and each extend in a band shape in the second direction Y in conformance to the extension direction of the corresponding street region 9. One second gate finger 70B is routed in the street region 9 so as to bypass the plurality of polysilicon layers 50 (the temperature sensitive diode structure D).

The plurality of second gate fingers 70B are mechanically and electrically connected to the plurality of gate via electrodes 69 on the interlayer film 57, and are electrically connected to the plurality of second gate wirings 56B via the plurality of gate via electrodes 69. As with the emitter pad EP, the plurality of gate fingers 70 may each have a laminated structure including the first electrode film 65 and the second electrode film 66 that are laminated in that order from the interlayer film 57 side.

The gate finger 70 may have a thickness larger than the thickness of the interlayer film 57. The thickness of the gate finger 70 may be substantially equal to the thickness of the emitter pad EP. The thickness range of the gate finger 70 is similar to the thickness range (not less than 0.5 μm and not more than 10 μm) of the emitter pad EP.

Referring again to FIG. 12 and FIG. 13, the semiconductor device 1A includes a plurality of anode openings 71 respectively formed in portions of the interlayer film 57 covering the plurality of polysilicon layers 50 in the temperature detecting region 10. The plurality of anode openings 71 pass through the interlayer film 57 and respectively expose the corresponding anode regions 51. The plurality of anode openings 71 each extend in a band shape along the corresponding anode region 51 in plan view.

In this embodiment, the plurality of anode openings 71 are formed in annular shapes extending along the corresponding anode region 51 in plan view and surround the corresponding cathode region 52. The plurality of anode openings 71 may each be formed in a quadrangular annular shape, a hexagonal annular shape, a polygonal annular shape, a circular annular shape, etc., in plan view. As a matter of course, the plurality of anode openings 71 may each be formed in an open ring shape extending along the corresponding anode openings 71.

The semiconductor device 1A includes a plurality of cathode openings 72 respectively formed in portions of the interlayer film 57 covering the plurality of polysilicon layers 50 in the temperature detecting region 10. The plurality of cathode openings 72 pass through the interlayer film 57 at an interval from the plurality of anode openings 71 and respectively expose the corresponding cathode regions 52. The plurality of cathode openings 72 each extend in a band shape along the corresponding cathode region 52.

In this embodiment, the plurality of cathode openings 72 are formed in open ring shapes extending along the corresponding cathode region 52 in plan view and surround the corresponding anode region 51. The plurality of cathode openings 72 may each be formed in an open quadrangular ring shape, an open hexagonal ring shape, an open polygonal ring shape, an open circular ring shape, etc., in plan view. As a matter of course, the plurality of cathode openings 72 may each be formed in a quadrangular shape, a hexagonal shape, a polygonal shape, or a circular shape in plan view.

The semiconductor device 1A includes a plurality of anode via electrodes 73 respectively embedded in the plurality of anode openings 71. The plurality of anode via electrodes 73 are mechanically and electrically connected to the corresponding anode regions 51 within the corresponding anode openings 71. As with the plurality of first emitter via electrode 59, the plurality of anode via electrodes 73 may each have a laminated structure including the first electrode 60 and the second electrode 61.

The semiconductor device 1A includes a plurality of cathode via electrodes 74 respectively embedded in the plurality of cathode openings 72. The plurality of cathode via electrodes 74 are mechanically and electrically connected to the corresponding cathode regions 52 within the corresponding cathode openings 72. As with the plurality of first emitter via electrode 59, the plurality of cathode via electrodes 74 may each have a laminated structure including the first electrode 60 and the second electrode 61.

The semiconductor device 1A includes an anode wiring 75 arranged on the interlayer film 57. The anode wiring 75 is routed from the temperature detecting region 10 to the anode pad region 11A via the street region 9. The anode wiring 75 has a portion extending in a band shape in the second direction Y in conformance to the extension direction of the street region 9 in the street region 9, and a portion extending in a band shape in an arbitrary direction (the first direction X) toward the anode pad region 11A outside the street region 9.

The anode wiring 75 has a portion extending parallel to the gate finger 70 in the street region 9. As with the emitter pad EP, the anode wiring 75 may have a laminated structure including the first electrode film 65 and the second electrode film 66 that are laminated in that order from the interlayer film 57 side.

The anode wiring 75 may have a thickness larger than the thickness of the interlayer film 57. The thickness of the anode wiring 75 may be substantially equal to the thickness of the emitter pad EP. The thickness range of the anode wiring 75 is similar to the thickness range (not less than 0.5 μm and not more than 10 μm) of the emitter pad EP.

The semiconductor device 1A includes a cathode wiring 76 arranged on the interlayer film 57. The cathode wiring 76 is routed from the temperature detecting region 10 to the cathode pad region 11C via the street region 9. The cathode wiring 76 has a portion extending in a band shape in the second direction Y in conformance to the extension direction of the street region 9 in the street region 9, and a portion extending in a band shape in an arbitrary direction (the first direction X) toward the cathode pad region 11C outside the street region 9.

The cathode wiring 76 has a portion extending parallel to both of the gate finger 70 and the anode wiring 75 in the street region 9. As with the emitter pad EP, the cathode wiring 76 may have a laminated structure including the first electrode film 65 and the second electrode film 66 that are laminated in that order from the interlayer film 57 side.

The cathode wiring 76 may have a thickness larger than the thickness of the interlayer film 57. The thickness of the cathode wiring 76 may be substantially equal to the thickness of the emitter pad EP. The thickness range of the cathode wiring 76 is similar to the thickness range (not less than 0.5 μm and not more than 10 μm) of the emitter pad EP.

The semiconductor device 1A includes a plurality of anode connection wirings 77 respectively formed on portions of the interlayer film 57 covering the plurality of polysilicon layers 50. The plurality of anode connection wirings 77 have portions extending along the corresponding anode via electrodes 73 on the interlayer film 57, and are mechanically and electrically connected to the corresponding anode via electrodes 73, respectively.

The plurality of anode connection wirings 77 may each be formed in a polygonal shape, a circular shape, etc., in plan view. The plurality of anode connection wirings 77 may each be formed in a quadrangular shape, a hexagonal shape, etc., in plan view. As with the emitter pad EP, the plurality of anode connection wirings 77 may each have a laminated structure including the first electrode film 65 and the second electrode film 66 that are laminated in that order from the interlayer film 57 side.

The anode connection wiring 77 may have a thickness larger than the thickness of the interlayer film 57. The thickness of the anode connection wiring 77 may be substantially equal to the thickness of the emitter pad EP. The thickness range of the anode connection wiring 77 is similar to the thickness range (not less than 0.5 μm and not more than 10 μm) of the emitter pad EP.

The semiconductor device 1A includes a plurality of cathode connection wirings 78 respectively formed on portions of the interlayer film 57 covering the plurality of polysilicon layers 50. The plurality of cathode connection wirings 78 have portions extending in a band shape along the corresponding cathode via electrodes 74 on the interlayer film 57, and are mechanically and electrically connected to the corresponding cathode via electrodes 74, respectively.

As with the emitter pad EP, the plurality of cathode connection wirings 78 may each have a laminated structure including the first electrode 60 and the second electrode 61 that are laminated in that order from the interlayer film 57 side.

The cathode connection wiring 78 may have a thickness larger than the thickness of the interlayer film 57. The thickness of the cathode connection wiring 78 may be substantially equal to the thickness of the emitter pad EP. The thickness range of the cathode connection wiring 78 is similar to the thickness range (not less than 0.5 μm and not more than 10 μm) of the emitter pad EP.

The semiconductor device 1A includes a plurality of connection wirings 79 respectively formed on portions of the interlayer film 57 covering the plurality of polysilicon layers 50. The plurality of connection wirings 79 are interposed in regions between the plurality of polysilicon layers 50 adjacent in the second direction Y on the interlayer film 57, and electrically connect the corresponding anode wiring 75 to the corresponding cathode wiring 76, respectively. The plurality of connection wirings 79 each extend in a band shape in the second direction Y in plan view.

One connection wiring 79 positioned on the outermost side on one side in the second direction Y electrically connects the outermost anode connection wiring 77 to the anode wiring 75. The other connection wiring 79 positioned on the outermost side on one side in the second direction Y electrically connects the outermost cathode connection wiring 78 to the anode wiring 75. The first series circuit SC1 including the plurality of first diodes D1 is thereby formed.

One connection wiring 79 positioned on the outermost side on the other side in the second direction Y electrically connects the outermost cathode connection wiring 78 to the cathode wiring 76. The other connection wiring 79 positioned on the outermost side on the other side in the second direction Y electrically connects the outermost anode connection wiring 77 to the cathode wiring 76. The second series circuit SC2 including the plurality of second diode D2 is thereby formed.

The connection wiring 79 may have a thickness larger than the thickness of the interlayer film 57. The thickness of the connection wiring 79 may be substantially equal to the thickness of the emitter pad EP. The thickness range of the connection wiring 79 is similar to the thickness range (not less than 0.5 μm and not more than 10 μm) of the emitter pad EP.

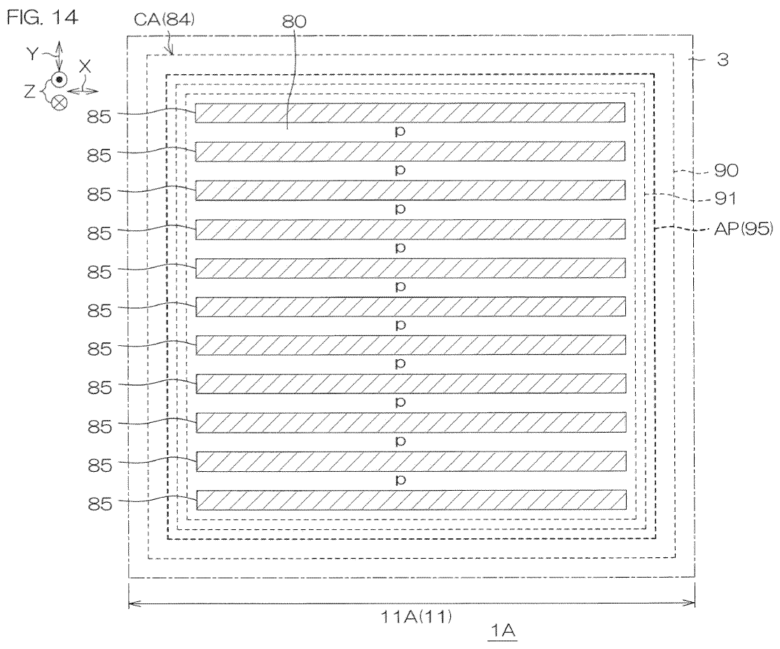

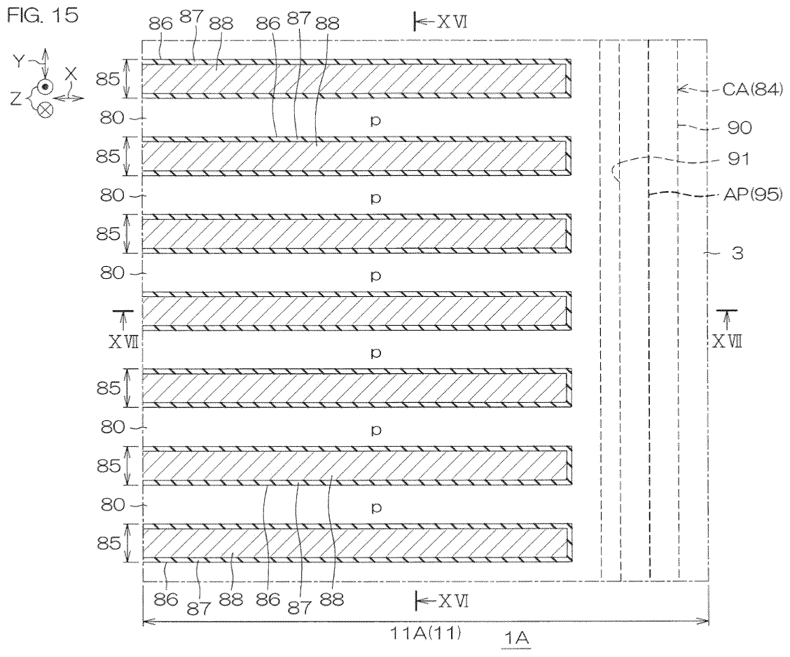

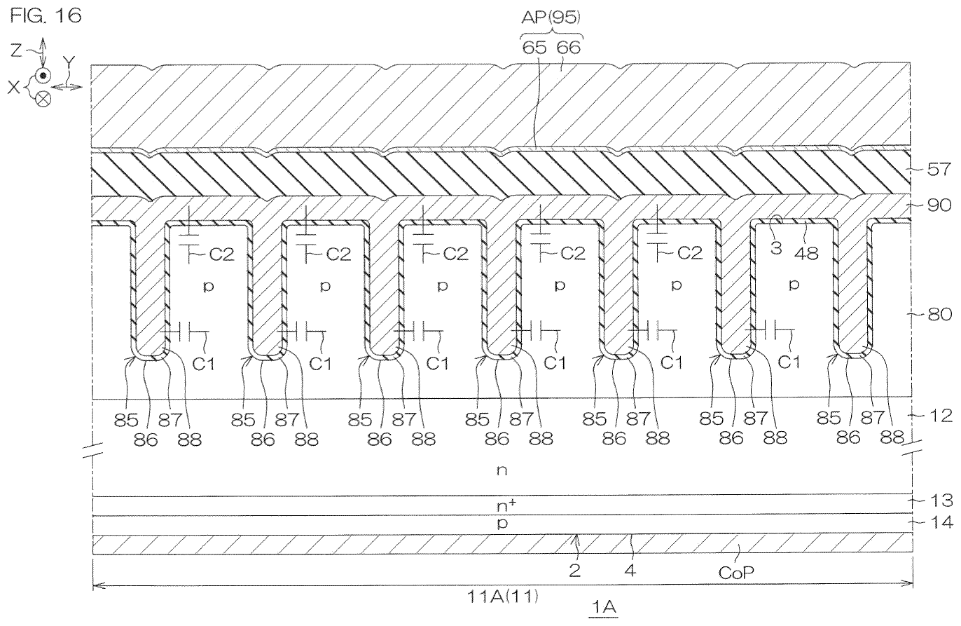

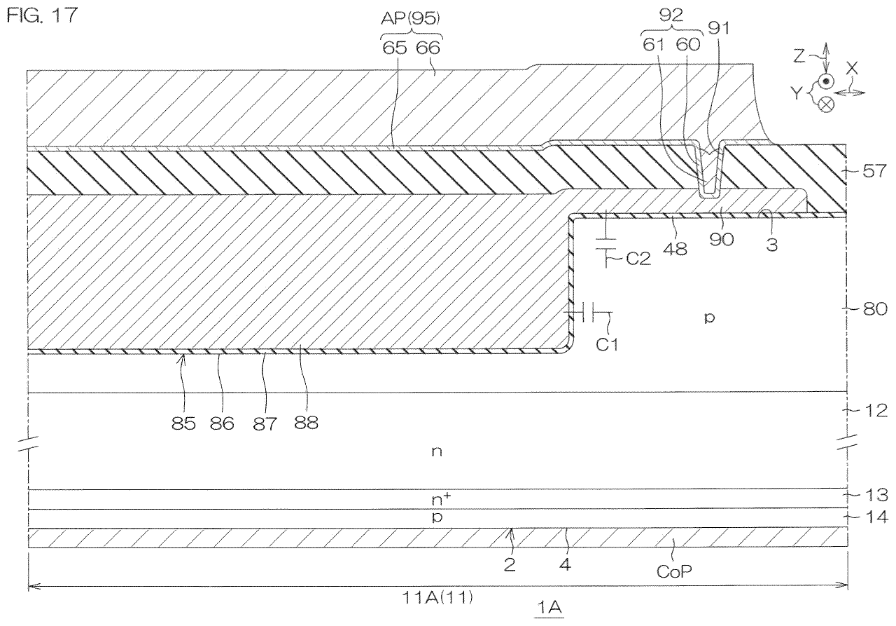

Hereinafter, the arrangement in the plurality of pad regions 11 shall be described. FIG. 14 is an enlarged plan view showing an arrangement in the pad region 11 together with a pad capacitor structure 84 according to a first layout example and a pad opening 91 according to a first layout example. FIG. 15 is an enlarged plan view showing a principal portion of the pad region 11. FIG. 16 is a sectional view taken along line XVI-XVI shown in FIG. 15. FIG. 17 is a sectional view taken along line XVII-XVII shown in FIG. 15.

The semiconductor device 1A includes a plurality of pad well regions 80 of the p-type respectively formed in the surface layer portion of the first main surface 3 in the plurality of pad regions 11. The pad well region 80 has a p-type impurity concentration higher than the n-type impurity concentration of the drift region 12, and replaces the conductivity type of the drift region 12 from the n-type to the p-type.

The pad well region 80 may have a p-type impurity concentration higher than the p-type impurity concentration of the base region 15. As a matter of course, the p-type impurity concentration of the pad well region 80 may be lower than the p-type impurity concentration of the base region 15. The p-type impurity concentration of the pad well region 80 is lower than the p-type impurity concentration of the contact region 41.

The p-type impurity concentration of the pad well region 80 may be substantially equal to the p-type impurity concentration of the outer peripheral well region 44. As a matter of course, the p-type impurity concentration of the pad well region 80 may be higher than the p-type impurity concentration of the outer peripheral well region 44, or may be lower than the p-type impurity concentration of the outer peripheral well region 44.

The p-type impurity concentration of the pad well region 80 may be substantially equal to the p-type impurity concentration of the street well region 45. As a matter of course, the p-type impurity concentration of the pad well region 80 may be higher than the p-type impurity concentration of the street well region 45, or may be lower than the p-type impurity concentration of the street well region 45.

An emitter potential is to be applied to the plurality of pad well regions 80. The plurality of pad well regions 80 are formed in the entire region of the corresponding pad region 11. In this embodiment, the plurality of pad well regions 80 are connected to the outer peripheral well region 44 and the plurality of street well regions 45, and are integrally formed with the plurality of street well regions 45 and the outer peripheral well region 44.

That is, the plurality of pad well regions 80 are electrically connected to the plurality of base regions 15 via the plurality of street well regions 45 and the outer peripheral well region 44. In this embodiment, the plurality of pad well regions 80 have a width larger than the width of the plurality of street well regions 45 in the first direction X.

The plurality of pad well regions 80 are formed deeper than the plurality of base regions 15. Specifically, the plurality of pad well regions 80 are formed deeper than the plurality of gate structures 20, the plurality of gate connection structures 25, the plurality of emitter structures 30, and the plurality of emitter connection structures 35.

The plurality of pad well regions 80 may have a depth substantially equal to the depth of the plurality of well regions 43. As a matter of course, the depth of the pad well regions 80 may be larger than the depth of the plurality of well regions 43, or may be smaller than the depth of the plurality of well regions 43.

The depth of the plurality of pad well regions 80 may be substantially equal to the depth of the outer peripheral well region 44. As a matter of course, the depth of the plurality of pad well regions 80 may be larger than the depth of the outer peripheral well region 44, or may be smaller than the depth of the outer peripheral well region 44.

The depth of the plurality of pad well regions 80 may be substantially equal to the depth of the plurality of street well regions 45. As a matter of course, the depth of the plurality of pad well regions 80 may be larger than the depth of the plurality of street well regions 45, or may be smaller than the depth of the plurality of street well regions 45.

The semiconductor device 1A includes a plurality of pad capacitor structures 84 respectively formed in the plurality of pad regions 11 (see also FIG. 3). In this embodiment, the plurality of pad capacitor structures 84 include the monitor capacitor structure CM formed in the monitor pad region 11M, the anode capacitor structure CA formed in the anode pad region 11A, and the cathode capacitor structure CC formed in the cathode pad region 11C.

A monitor potential is to be applied to the monitor capacitor structure CM, an anode potential is to be applied to the anode capacitor structure CA, and a cathode potential is to be applied to the cathode capacitor structure CC. The plurality of pad capacitor structures 84 have the same arrangement. Hereinafter, the arrangement of the anode capacitor structure CA shall be described as an example of the pad capacitor structure 84.

The arrangement of the monitor capacitor structure CM is obtained by replacing the “anode capacitor structure CA” with the “monitor capacitor structure CM” and replacing the “anode pad region 11A” with the “monitor pad region 11M” in the following description.

The arrangement of the cathode capacitor structure CC is obtained by replacing the “anode capacitor structure CA” with the “cathode capacitor structure CC” and replacing the “anode pad region 11A” with the “cathode pad region 11C” in the following description.

The anode capacitor structure CA includes a plurality of capacitor structures 85 of the trench electrode type formed on the first main surface 3 and forming capacitive coupling with the chip 2. The number of capacitor structures 85 is less than the number of gate structures 20.

The total area (total extension) of the plurality of capacitor structures 85 is less than the total area (total extension) of the plurality of gate structures 20. The number of capacitor structures 85 is less than the number of emitter structures 30. The total area (total extension) of the plurality of capacitor structures 85 is less than the total area (total extension) of the plurality of emitter structures 30.

The plurality of capacitor structures 85 each extend in a band shape in the first direction X and are arrayed at intervals in the second direction Y in the anode pad region 11A. That is, the plurality of capacitor structures 85 are arrayed in a stripe shape extending in the first direction X. The extension direction of the plurality of capacitor structures 85 coincides with the extension direction of the plurality of gate structures 20. The extension direction of the plurality of capacitor structures 85 coincides with the extension direction of the plurality of emitter structures 30.

The plurality of capacitor structures 85 may each have a width less than the width of the plurality of street regions 9. The width of the capacitor structure 85 is a width in a direction (the second direction Y) orthogonal to the extension direction of the capacitor structure 85 (the first direction X).

The width of the capacitor structure 85 may be substantially equal to the width of the gate structure 20. As a matter of course, the width of the capacitor structure 85 may be larger than the width of the gate structure 20, or may be smaller than the width of the gate structure 20. The width of the capacitor structure 85 may be substantially equal to the width of the gate connection structure 25. As a matter of course, the width of the capacitor structure 85 may be larger than the width of the gate connection structure 25, or may be smaller than the width of the gate connection structure 25.

The width of the capacitor structure 85 may be substantially equal to the width of the emitter structure 30. As a matter of course, the width of the capacitor structure 85 may be larger than the width of the emitter structure 30, or may be smaller than the width of the emitter structure 30. The width of the capacitor structure 85 may be substantially equal to the width of the emitter connection structure 35. As a matter of course, the width of the capacitor structure 85 may be larger than the width of the emitter connection structure 35, or may be smaller than the width of the emitter connection structure 35.

The width of the capacitor structure 85 may be not less than 0.5 μm and not more than 5 μm. The width of the capacitor structure 85 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The width of the capacitor structure 85 is preferably not less than 1 μm and not more than 2.5 μm.

A second trench pitch between the central portions of the plurality of capacitor structures 85 may be substantially equal to the first trench pitch between the central portion of the gate structure 20 and the central portion of the emitter structure 30. As a matter of course, the second trench pitch may be larger than the first trench pitch, or may be smaller than the first trench pitch.

The second trench pitch may be not less than 1 μm and not more than 5 μm. The second trench pitch may have a value belonging to at least one range among not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The second trench pitch is preferably not less than 1.5 μm and not more than 3.5 μm.

The plurality of capacitor structures 85 are each formed at an interval toward the first main surface 3 side from the depth position of the intermediate portion of the drift region 12. Specifically, the plurality of capacitor structures 85 are formed on the first main surface 3 so as to be positioned in the pad well region 80, and form capacitive coupling with the pad well region 80.

More specifically, the plurality of capacitor structures 85 are formed at an interval toward the first main surface 3 side, and face the drift region 12 from the bottom portion of the pad well region 80 with a portion of the pad well region 80 interposed therebetween in the thickness direction. That is, the plurality of capacitor structures 85 form capacitive coupling with the pad well region 80 over the entire region in a depth direction.

The plurality of capacitor structures 85 may each have a bottom wall positioned on the bottom portion side of the pad well region 80 with respect to a depth position of an intermediate portion of the pad well region 80. As a matter of course, the bottom walls of the plurality of capacitor structures 85 may be positioned on the first main surface 3 side with respect to the depth position of the intermediate portion of the pad well region 80. Also, the plurality of capacitor structures 85 may pass through the pad well region 80 so as to reach the drift region 12.

The plurality of capacitor structures 85 may each be formed in a shape tapering toward the bottom wall. As a matter of course, the plurality of capacitor structures 85 may be formed substantially perpendicular to the first main surface 3. The bottom walls of the plurality of capacitor structures 85 may each be formed in a shape curved toward the second main surface 4. As a matter of course, the bottom walls of the plurality of capacitor structures 85 may be formed substantially parallel to the first main surface 3. In this case, bottom wall corner portions of the plurality of capacitor structures 85 may each be formed in a curved shape.

The plurality of capacitor structures 85 may have a depth substantially equal to the depth of the plurality of gate structures 20. As a matter of course, the depth of the capacitor structure 85 may be larger than the depth of the gate structure 20, or may be smaller than the depth of the gate structure 20.

The depth of the capacitor structure 85 may be substantially equal to the depth of the gate connection structure 25. As a matter of course, the depth of the capacitor structure 85 may be larger than the depth of the gate connection structure 25, or may be smaller than the depth of the gate connection structure 25.

The depth of the capacitor structure 85 may be substantially equal to the depth of the emitter structure 30. As a matter of course, the depth of the capacitor structure 85 may be larger than the depth of the emitter structure 30, or may be smaller than the depth of the emitter structure 30.

The depth of the capacitor structure 85 may be substantially equal to the depth of the emitter connection structure 35. As a matter of course, the depth of the capacitor structure 85 may be larger than the depth of the emitter connection structure 35, or may be smaller than the depth of the emitter connection structure 35.

The depth of the capacitor structure 85 may be not less than 0.5 μm and not more than 10 μm. The depth of the capacitor structure 85 may have a value belonging to at least one range among not less than 0.5 μm and not more than 1 μm, not less than 1 μm and not more than 2 μm, not less than 2 μm and not more than 4 μm, not less than 4 μm and not more than 6 μm, not less than 6 μm and not more than 8 μm, and not less than 8 μm and not more than 10 μm. The depth of the capacitor structure 85 is preferably not less than 4 μm and not more than 8 μm.

The plurality of capacitor structures 85 respectively include a capacitor trench 86, a capacitor insulating film 87 (dielectric film), and a capacitor embedded electrode 88. The capacitor trench 86 is formed in the first main surface 3 and demarcates the wall surfaces (side walls and bottom wall) of the capacitor structure 85.

The capacitor insulating film 87 covers the wall surface of the capacitor trench 86. The capacitor insulating film 87 may include at least one among a silicon oxide film, a silicon nitride film, and a silicon oxynitride film.

The capacitor insulating film 87 preferably includes the same type of insulator as the gate insulating film 22 (the emitter insulating film 32). In this embodiment, the capacitor insulating film 87 has a single layer structure constituted of a silicon oxide film. The capacitor insulating film 87 particularly preferably includes the silicon oxide film constituted of the oxide of the chip 2.

The thickness of the capacitor insulating film 87 may be substantially equal to the thickness of the gate insulating film 22. As a matter of course, the thickness of the capacitor insulating film 87 may be larger than the thickness of the gate insulating film 22, or may be smaller than the thickness of the gate insulating film 22.

The thickness of the capacitor insulating film 87 may be substantially equal to the thickness of the gate connection insulating film 27. As a matter of course, the thickness of the capacitor insulating film 87 may be larger than the thickness of the gate connection insulating film 27, or may be smaller than the thickness of the gate connection insulating film 27.

The thickness of the capacitor insulating film 87 may be substantially equal to the thickness of the emitter insulating film 32. As a matter of course, the thickness of the capacitor insulating film 87 may be larger than the thickness of the emitter insulating film 32, or may be smaller than the thickness of the emitter insulating film 32.

The thickness of the capacitor insulating film 87 may be substantially equal to the thickness of the emitter connection insulating film 37. As a matter of course, the thickness of the capacitor insulating film 87 may be larger than the thickness of the emitter connection insulating film 37, or may be smaller than the thickness of the emitter connection insulating film 37.

The thickness of the capacitor insulating film 87 may be not less than 10 nm and not more than 200 nm. The thickness of the capacitor insulating film 87 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm. The thickness of the capacitor insulating film 87 is preferably not less than 100 nm and not more than 150 nm.

The capacitor embedded electrode 88 is embedded in the capacitor trench 86 with the capacitor insulating film 87 interposed therebetween, and forms capacitive coupling with the chip 2. Specifically, the capacitor embedded electrode 88 faces the pad well region 80 with the capacitor insulating film 87 interposed therebetween, and forms capacitive coupling with the pad well region 80.

In this embodiment, the capacitor embedded electrode 88 forms a capacitive coupling with the pad well region 80 on the side wall and the bottom wall of the capacitor trench 86. The plurality of capacitor structures 85 forms a plurality of first capacitors C1 with the chip 2 (pad well region 80). The plurality of first capacitors C1 are connected in parallel.

When the capacitor trench 86 passes through the pad well region 80, the capacitor embedded electrode 88 may have a portion forming capacitive coupling with the pad well region 80 via the capacitor insulating film 87 and a portion forming capacitive coupling with the drift region 12 via the capacitor insulating film 87.

The capacitor embedded electrode 88 may contain one or both of a conductive polysilicon of the p-type and a conductive polysilicon of the n-type. The capacitor embedded electrode 88 preferably includes the same type of conductor as the gate embedded electrode 23 (emitter embedded electrode 33).

The anode capacitor structure CA includes the above-described main surface insulating film 48 covering the first main surface 3 in the anode pad region 11A. The main surface insulating film 48 covers the pad well region 80 on the first main surface 3.

The main surface insulating film 48 is connected to the capacitor insulating film 87 in the anode pad region 11A. The thickness of the main surface insulating film 48 may be substantially equal to the thickness of the capacitor insulating film 87. As a matter of course, the thickness of the main surface insulating film 48 may be larger than the thickness of the capacitor insulating film 87, or may be smaller than the thickness of the capacitor insulating film 87.

The anode capacitor structure CA includes one or a plurality of (in this embodiment, one) capacitor electrode films 90 covering the plurality of capacitor structures 85 on the main surface insulating film 48 in the anode pad region 11A. In this embodiment, the capacitor electrode film 90 collectively covers the plurality of capacitor structures 85 in a film shape in the anode pad region 11A.

In this embodiment, the capacitor electrode film 90 is formed integrally with the plurality of capacitor embedded electrodes 88, and constituted of lead-out portions led out from the plurality of capacitor embedded electrodes 88 onto the main surface insulating film 48. That is, the capacitor electrode film 90 is each constituted of the same type of conductor as the capacitor embedded electrode 88 (one or both of the conductive polysilicon of the p-type and the conductive polysilicon of the n-type).

As a matter of course, the capacitor electrode film 90 may be constituted of a metal film. In this case, the capacitor electrode film 90 may be mechanically and electrically connected to the plurality of capacitor structures 85 (capacitor embedded electrodes 88) on the main surface insulating film 48.

The capacitor electrode film 90 faces the first main surface 3 via the main surface insulating film 48 as a main surface dielectric film, and forms capacitive coupling with the chip 2. Specifically, the capacitor electrode film 90 faces the pad well region 80 via the main surface insulating film 48, and forms capacitive coupling with the pad well region 80.

The capacitor electrode film 90 forms a plurality of second capacitors C2 with the chip 2 (pad well region 80) in regions between the plurality of capacitor structures 85. The plurality of second capacitors C2 are connected in parallel. The plurality of second capacitors C2 are connected in parallel to the plurality of first capacitors C1.

In this embodiment, the capacitor electrode film 90 is formed in a polygonal shape having four sides parallel to the peripheral edge of the chip 2 in plan view (in this embodiment, a quadrangular shape). The capacitor electrode film 90 may be formed in a circular shape in plan view.

The capacitor electrode film 90 has a thickness larger than the thickness of the main surface insulating film 48. The thickness of the capacitor electrode film 90 is preferably less than the depth (thickness) of the pad well region 80.

The thickness of the capacitor electrode film 90 is preferably less than the depth of the capacitor structure 85. The thickness of the capacitor electrode film 90 is preferably less than the depth of the gate structure 20 (emitter structure 30). The thickness of the capacitor electrode film 90 is preferably less than the depth of the gate connection structure 25 (emitter connection structure 35).

The thickness of the capacitor electrode film 90 may be substantially equal to the thickness of the polysilicon layer 50. As a matter of course, the thickness of capacitor electrode film 90 may be larger than the thickness of the polysilicon layer 50, or may be smaller than the thickness of the polysilicon layer 50.

The thickness of the capacitor electrode film 90 may be substantially equal to the thickness of the emitter wiring 55. As a matter of course, the thickness of the capacitor electrode film 90 may be larger than the thickness of the emitter wiring 55, or may be smaller than the thickness of the emitter wiring 55.

The thickness of the capacitor electrode film 90 may be substantially equal to the thickness of the gate wiring 56. As a matter of course, the thickness of the capacitor electrode film 90 may be larger than the thickness of the gate wiring 56, or may be smaller than the thickness of the gate wiring 56.

The thickness of the capacitor electrode film 90 may be not less than 0.1 μm and not more than 2 μm. The thickness of the capacitor electrode film 90 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1.25 μm and not more than 1.5 μm, not less than 1.5 μm and not more than 1.75 μm, and not less than 1.75 μm and not more than 2 μm. The thickness of the capacitor electrode film 90 is preferably not less than 0.25 μm and not more than 1.25 μm.

The anode capacitor structure CA includes the above-described interlayer film 57 covering the capacitor electrode film 90 in the anode pad region 11A. The interlayer film 57 covers the pad well region 80 with the main surface insulating film 48 and the capacitor electrode film 90 interposed therebetween, and covers the plurality of capacitor structures 85 with the capacitor electrode film 90 interposed therebetween. The thickness of the interlayer film 57 is preferably larger than the thickness of the capacitor electrode film 90. As a matter of course, the thickness of the interlayer film 57 may be smaller than the thickness of the capacitor electrode film 90.

The anode capacitor structure CA includes one or a plurality (in this embodiment, one) of the pad openings 91 formed in the interlayer film 57 in the anode pad region 11A. The pad opening 91 is formed around the plurality of capacitor structures 85 in plan view and extends in a band shape along the peripheral edge of the capacitor electrode film 90.

In this embodiment, the pad opening 91 is formed in an annular shape extending along the peripheral edge of the capacitor electrode film 90 in plan view and surrounds the plurality of capacitor structures 85. The pad opening 91 passed through the interlayer film 57 and exposes the capacitor electrode film 90. In this embodiment, the pad opening 91 is further dug in from the electrode surface of the capacitor electrode film 90 toward the first main surface 3 side and has a bottom wall positioned in the capacitor electrode film 90.

The bottom wall of the pad opening 91 is preferably formed at an interval toward the electrode surface side of the capacitor electrode film 90 from a thickness position of an intermediate portion of the capacitor electrode film 90. As a matter of course, the bottom wall of the pad opening 91 may be positioned on the chip 2 side with respect to the thickness position of the intermediate portion of the capacitor electrode film 90. The pad opening 91 may be formed in a shape tapering toward the bottom wall. As a matter of course, the pad opening 91 may be formed substantially perpendicular to the first main surface 3.

The anode capacitor structure CA includes a pad via electrode 92 embedded in the pad opening 91 in the anode pad region 11A. The pad via electrode 92 has portions each in contact with the interlayer film 57 and the capacitor electrode film 90. The pad via electrode 92 is mechanically and electrically connected to the capacitor electrode film 90 in the pad opening 91, and is electrically connected to the plurality of capacitor embedded electrodes 88 via the capacitor electrode film 90.

As with the first emitter via electrode 59, the pad via electrode 92 may have a laminated structure including the first electrode 60 and the second electrode 61 that are laminated in that order from the wall surface side of the pad opening 91. The first electrode 60 is formed in a film shape in the wall surface of the pad opening 91, and is mechanically and electrically connected to the capacitor electrode film 90 in the pad opening 91. The second electrode 61 is embedded in the pad opening 91 with the first electrode 60 interposed therebetween, and is electrically connected to the capacitor electrode film 90 via the first electrode 60.

The semiconductor device 1A does not have the pad capacitor structure 84 (the capacitor structure 85, the capacitor electrode film 90, the pad opening 91, and the pad via electrode 92) in the gate pad region 11G. This is because the capacitance value between the gate pad region 11G and the chip 2 is secured by the plurality of gate structures 20 arranged in the plurality of active regions 6.

Referring again to FIG. 2, the semiconductor device 1A includes a plurality of pad electrodes 95 respectively arranged in the plurality of pad regions 11. The pad electrode 95 may be referred to as a “pad,” a “terminal electrode,” an “external terminal,” etc.

The plurality of pad electrodes 95 include the gate pad GP arranged in the gate pad region 11G, the monitor pad MP arranged in the monitor pad region 11M, the anode pad AP arranged in the anode pad region 11A, and the cathode pad CaP arranged in the cathode pad region 11C.

The gate pad GP is a terminal to which a gate potential is to be applied from the exterior. The gate pad GP may be referred to as a “gate pad electrode,” a “gate terminal electrode,” a “gate external terminal,” etc. The gate pad GP is arranged on a portion of the interlayer film 57 covering the gate pad region 11G, and is connected to the plurality of gate fingers 70. Thereby, the gate potential applied to the gate pad GP is to be applied to the plurality of gate structures 20 via the plurality of gate wirings 56 and the plurality of gate fingers 70.

In this embodiment, the gate pad GP faces the pad well region 80 with the main surface insulating film 48 and the interlayer film 57 interposed therebetween. In this embodiment, the gate pad GP is formed in a polygonal shape having four sides parallel to the peripheral edge of the chip 2 in plan view (in this embodiment, a quadrangular shape). The gate pad GP may be formed in a circular shape in plan view.

The gate pad GP may have a thickness larger than the thickness of the interlayer film 57. The thickness of the gate pad GP is preferably larger than the thickness of the capacitor electrode film 90. The thickness of the gate pad GP may be not less than 0.5 μm and not more than 10 μm.

The thickness of the gate pad GP may have a value belonging to at least one range among not less than 0.5 μm and not more than 1 μm, not less than 1 μm and not more than 2 μm, not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 7 μm and not more than 8 μm, not less than 8 μm and not more than 9 μm, and not less than 9 μm and not more than 10 μm.

As with the emitter pad EP, the gate pad GP may have a laminated structure including the first electrode film 65 and the second electrode film 66 that are laminated in that order from the interlayer film 57 side. The first electrode film 65 covers the interlayer film 57 in a film shape as a barrier electrode. The first electrode film 65 is connected to the first electrode films 65 of the plurality of gate fingers 70 on the interlayer film 57.

The second electrode film 66 has a thickness larger than the thickness of the first electrode film 65 and covers the first electrode film 65 in a film shape. The second electrode film 66 is connected to the second electrode films 66 of the plurality of gate fingers 70 on the first electrode film 65.

The monitor pad MP is a terminal to which a monitor potential is to be applied from the exterior. The monitor pad MP may be referred to as a “monitor pad electrode,” a “monitor terminal electrode,” a “monitor external terminal,” etc. The monitor pad MP is arranged on a portion of the interlayer film 57 covering the monitor pad region 11M.

In this embodiment, the monitor pad MP has a plane area smaller than the plane area of the capacitor electrode film 90 of the monitor capacitor structure CM, and is arranged on the inner portion of the capacitor electrode film 90 at an interval from the peripheral edge of the capacitor electrode film 90. That is, the monitor pad MP has a peripheral edge (electrode side wall) positioned inside the peripheral edge of the capacitor electrode film 90.

As a matter of course, the monitor pad MP may have a plane area larger than the plane area of the capacitor electrode film 90. In this case, the peripheral edge (electrode side wall) of the monitor pad MP may be positioned outside the peripheral edge of the capacitor electrode film 90 to surround the capacitor electrode film 90.

In this embodiment, the monitor pad MP is formed in a polygonal shape having four sides parallel to the peripheral edge of the chip 2 in plan view (in this embodiment, a quadrangular shape). The monitor pad MP may be formed in a circular shape in plan view.

The monitor pad MP is mechanically and electrically connected to the pad via electrode 92 on the interlayer film 57. The monitor pad MP is thereby electrically connected to the plurality of capacitor structures 85 (the capacitor embedded electrodes 88) via the capacitor electrode film 90. That is, the monitor pad MP applies a monitor potential to the plurality of capacitor structures 85 and the capacitor electrode film 90 of the monitor capacitor structure CM.

The monitor pad MP is arranged on the first side surface 5A side with respect to the monitor electrode 67, and has a lead-out portion led out toward the monitor electrode 67. The lead-out portion extends in a band shape in the second direction Y, and is mechanically and electrically connected to the monitor electrode 67.

Thereby, the monitor potential applied to the monitor pad MP is to be applied to the plurality of emitter structures 30, the plurality of emitter connection structures 35, the plurality of emitter regions 40, and the plurality of contact regions 41 via the monitor electrode 67, the plurality of first emitter via electrodes 59, and the plurality of second emitter via electrodes 63.

The monitor pad MP may have a thickness larger than the thickness of the interlayer film 57. The thickness of the monitor pad MP is preferably larger than the thickness of the capacitor electrode film 90. The thickness range of the monitor pad MP is similar to the thickness range (not less than 0.5 μm and not more than 10 μm) of the gate pad GP.

As with the emitter pad EP, the monitor pad MP may have a laminated structure including the first electrode film 65 and the second electrode film 66 that are laminated in that order from the interlayer film 57 side. The first electrode film 65 covers the interlayer film 57 in a film shape as a barrier electrode. The first electrode film 65 is mechanically and electrically connected to the pad via electrode 92 on the interlayer film 57.

Specifically, the first electrode film 65 is connected to the first electrode 60 of the pad via electrode 92. As a matter of course, the first electrode film 65 may cover the first electrode 60 of the pad via electrode 92. The first electrode film 65 is connected to the first electrode film 65 of the monitor electrode 67 on the interlayer film 57.

The second electrode film 66 has a thickness larger than the thickness of the first electrode film 65 and covers the first electrode film 65 and the pad via electrode 92 in a film shape. The second electrode film 66 is mechanically and electrically connected to the pad via electrode 92. The second electrode film 66 is connected to the second electrode film 66 of the monitor electrode 67 on the first electrode film 65.

The anode pad AP is a terminal to which an anode potential is to be applied from the exterior. The anode pad AP may be referred to as an “anode pad electrode,” an “anode terminal electrode,” an “anode external terminal,” etc. The anode pad AP is arranged on a portion of the interlayer film 57 covering the anode pad region 11A, and is connected to the anode wiring 75. Thereby, the anode potential applied to the anode pad AP is to be applied to the temperature sensitive diode structure D via the anode wiring 75.

In this embodiment, the anode pad AP has a plane area smaller than the plane area of the capacitor electrode film 90 of the anode capacitor structure CA, and is arranged on the inner portion of the capacitor electrode film 90 at an interval from the peripheral edge of the capacitor electrode film 90. That is, the anode pad AP has a peripheral edge (electrode side wall) positioned inside the peripheral edge of the capacitor electrode film 90.

As a matter of course, the anode pad AP may have a plane area larger than the plane area of the capacitor electrode film 90. In this case, the peripheral edge (electrode side wall) of the anode pad AP may be positioned outside the peripheral edge of the capacitor electrode film 90 to surround the capacitor electrode film 90.

In this embodiment, the anode pad AP is formed in a polygonal shape having four sides parallel to the peripheral edge of the chip 2 in plan view (in this embodiment, a quadrangular shape). The anode pad AP may be formed in a circular shape in plan view.

The anode pad AP is mechanically and electrically connected to the pad via electrode 92 on the interlayer film 57. The anode pad AP is thereby electrically connected to the plurality of capacitor structures 85 (the capacitor embedded electrodes 88) via the capacitor electrode film 90. That is, the anode pad AP applies an anode potential to the plurality of capacitor structures 85 and the capacitor electrode film 90 of the anode capacitor structure CA.

The anode pad AP may have a thickness larger than the thickness of the interlayer film 57. The thickness of the anode pad AP is preferably larger than the thickness of the capacitor electrode film 90. The thickness range of the anode pad AP is similar to the thickness range (not less than 0.5 μm and not more than 10 μm) of the gate pad GP.

As with the emitter pad EP, the anode pad AP may have a laminated structure including the first electrode film 65 and the second electrode film 66 that are laminated in that order from the interlayer film 57 side. The first electrode film 65 covers the interlayer film 57 in a film shape as a barrier electrode. The first electrode film 65 is mechanically and electrically connected to the pad via electrode 92 on the interlayer film 57.

Specifically, the first electrode film 65 is connected to the first electrode 60 of the pad via electrode 92. As a matter of course, the first electrode film 65 may cover the first electrode 60 of the pad via electrode 92. The first electrode film 65 is connected to the first electrode film 65 of the anode wiring 75 on the interlayer film 57.

The second electrode film 66 has a thickness larger than the thickness of the first electrode film 65 and covers the first electrode film 65 and the pad via electrode 92 in a film shape. The second electrode film 66 is mechanically and electrically connected to the pad via electrode 92. The second electrode film 66 is connected to the second electrode film 66 of the anode wiring 75 on the first electrode film 65.

The cathode pad CaP is a terminal to which a cathode potential is to be applied from the exterior. The cathode pad CaP may be referred to as a “cathode pad electrode,” a “cathode terminal electrode,” a “cathode external terminal,” etc.

The cathode pad CaP is arranged on a portion of the interlayer film 57 covering the cathode pad region 11C, and is connected to the cathode wiring 76. Thereby, the cathode potential applied to the cathode pad CaP is to be applied to the temperature sensitive diode structure D via the cathode wiring 76.

The cathode pad CaP is arranged on a portion of the interlayer film 57 covering the cathode pad region 11C. In this embodiment, the cathode pad CaP has a plane area smaller than the plane area of the capacitor electrode film 90 of the cathode capacitor structure CC, and is arranged on the inner portion of the capacitor electrode film 90 at an interval from the peripheral edge of the capacitor electrode film 90. That is, the cathode pad CaP has a peripheral edge (electrode side wall) positioned inside the peripheral edge of the capacitor electrode film 90.

As a matter of course, the cathode pad CaP may have a plane area larger than the plane area of the capacitor electrode film 90. In this case, the peripheral edge (electrode side wall) of the cathode pad CaP may be positioned outside the peripheral edge of the capacitor electrode film 90 to surround the capacitor electrode film 90.

In this embodiment, the cathode pad CaP is formed in a polygonal shape having four sides parallel to the peripheral edge of the chip 2 in plan view (in this embodiment, a quadrangular shape). The cathode pad CaP may be formed in a circular shape in plan view.

The cathode pad CaP is mechanically and electrically connected to the pad via electrode 92 on the interlayer film 57. The cathode pad CaP is thereby electrically connected to the plurality of capacitor structures 85 (the capacitor embedded electrodes 88) via the capacitor electrode film 90. That is, the cathode pad CaP applies a cathode potential to the plurality of capacitor structures 85 and the capacitor electrode film 90 of the cathode capacitor structure CC.

The cathode pad CaP may have a thickness larger than the thickness of the interlayer film 57. The thickness of the cathode pad CaP is preferably larger than the thickness of the capacitor electrode film 90. The thickness range of the cathode pad CaP is similar to the thickness range (not less than 0.5 μm and not more than 10 μm) of the gate pad GP.

As with the emitter pad EP, the cathode pad CaP may have a laminated structure including the first electrode film 65 and the second electrode film 66 that are laminated in that order from the interlayer film 57 side. The first electrode film 65 covers the interlayer film 57 in a film shape as a barrier electrode. The first electrode film 65 is mechanically and electrically connected to the pad via electrode 92 on the interlayer film 57.

Specifically, the first electrode film 65 is connected to the first electrode 60 of the pad via electrode 92. As a matter of course, the first electrode film 65 may cover the first electrode 60 of the pad via electrode 92. The first electrode film 65 is connected to the first electrode film 65 of the cathode wiring 76 on the interlayer film 57.

The second electrode film 66 has a thickness larger than the thickness of the first electrode film 65 and covers the first electrode film 65 and the pad via electrode 92 in a film shape. The second electrode film 66 is mechanically and electrically connected to the pad via electrode 92. The second electrode film 66 is connected to the second electrode film 66 of the cathode wiring 76 on the first electrode film 65.

The semiconductor device 1A includes a collector pad CoP covering the second main surface 4. The collector pad CoP is a terminal to which a collector potential is to be applied from the exterior. The collector pad CoP may be referred to as a “collector pad electrode,” a “collector terminal electrode,” a “collector external terminal,” etc. The collector pad CoP is formed in a film shape along the second main surface 4 and is electrically connected to the collector region 14.

The collector pad CoP covers the plurality of active regions 6, the monitor region 7, the outer peripheral region 8, the plurality of street regions 9, the plurality of temperature detecting regions 10, and the plurality of pad regions 11 from the second main surface 4 side. The collector pad CoP may cover the entire region of the second main surface 4. As a matter of course, the collector pad CoP may be formed at an interval inward from the peripheral edge of the second main surface 4 (the first to fourth side surfaces 5A to 5D) and expose the peripheral edge portion of the second main surface 4 (the collector region 14).

A breakdown voltage applicable between the emitter pad EP and the collector pad CoP (between the first main surface 3 and the second main surface 4) may be not less than 500 V and not more than 3000 V. The breakdown voltage may have a value belonging to at least one range among not less than 500 V and not more than 750V, not less than 750 V and not more than 1000V, not less than 1000 V and not more than 1250V, not less than 1250 V and not more than 1500V, not less than 1500 V and not more than 1750V, not less than 1750 V and not more than 2000V, not less than 2000 V and not more than 2250V, not less than 2250 V and not more than 2500V, not less than 2500 V and not more than 2750V, and not less than 2750 V and not more than 3000V.

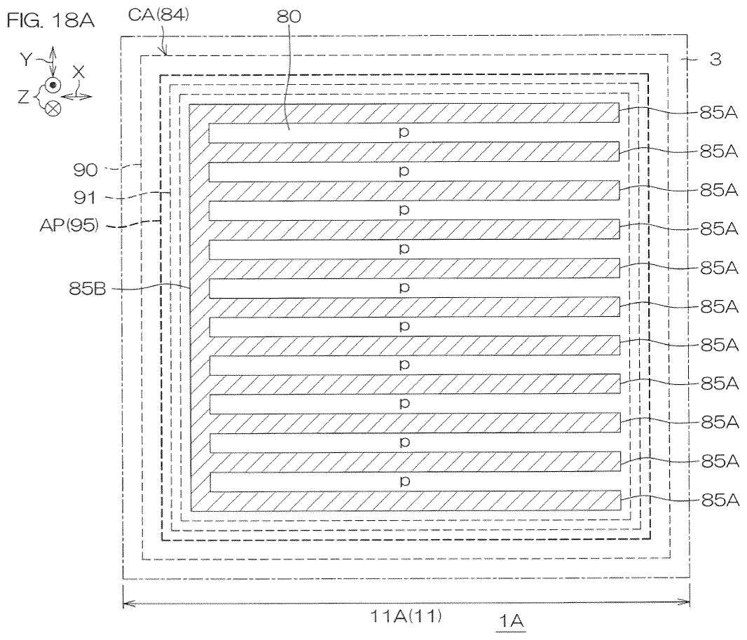

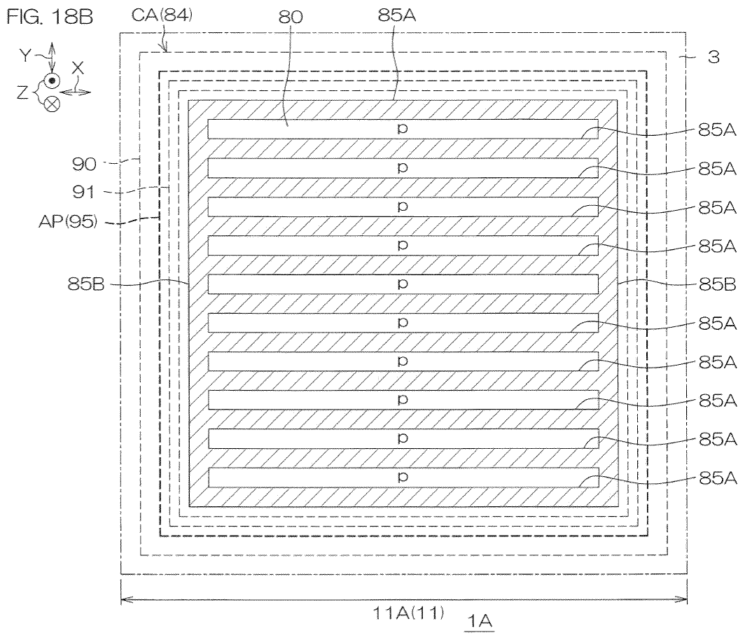

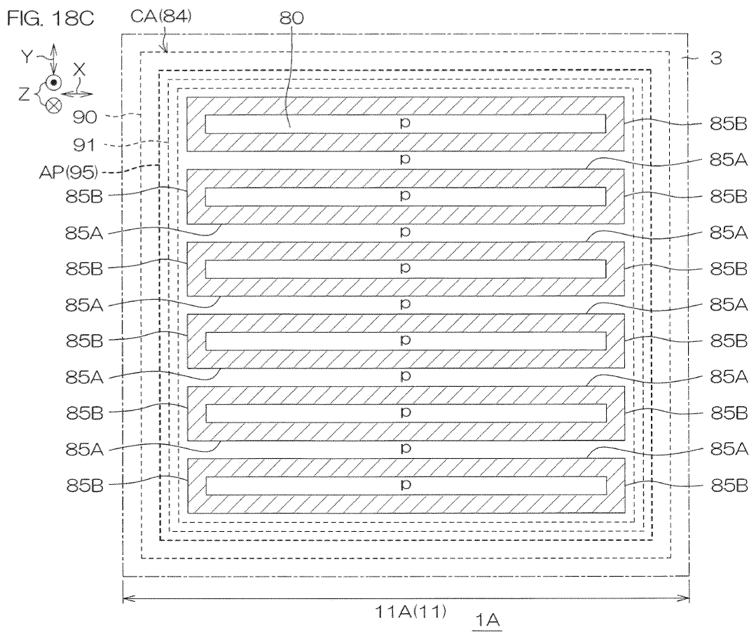

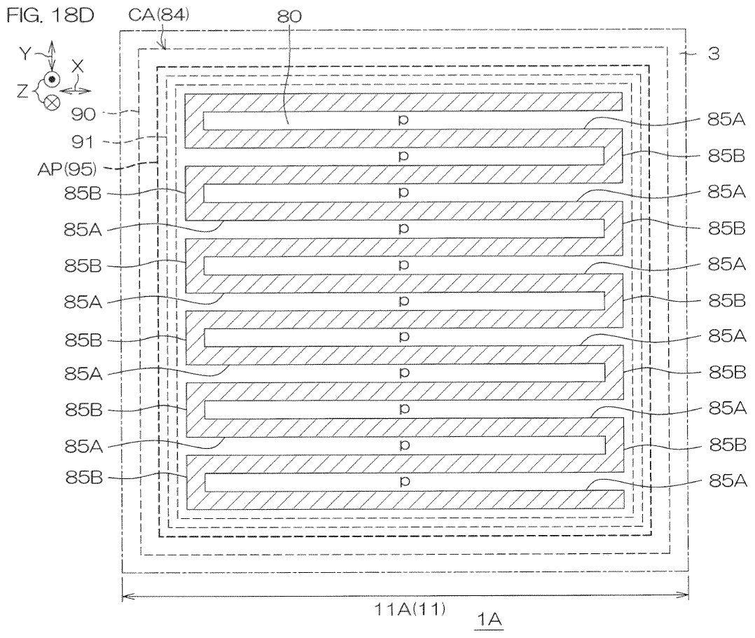

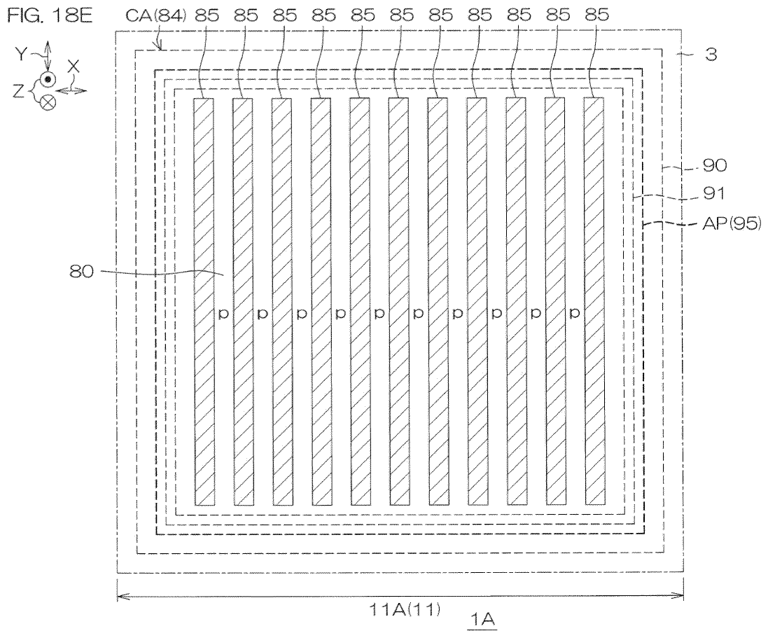

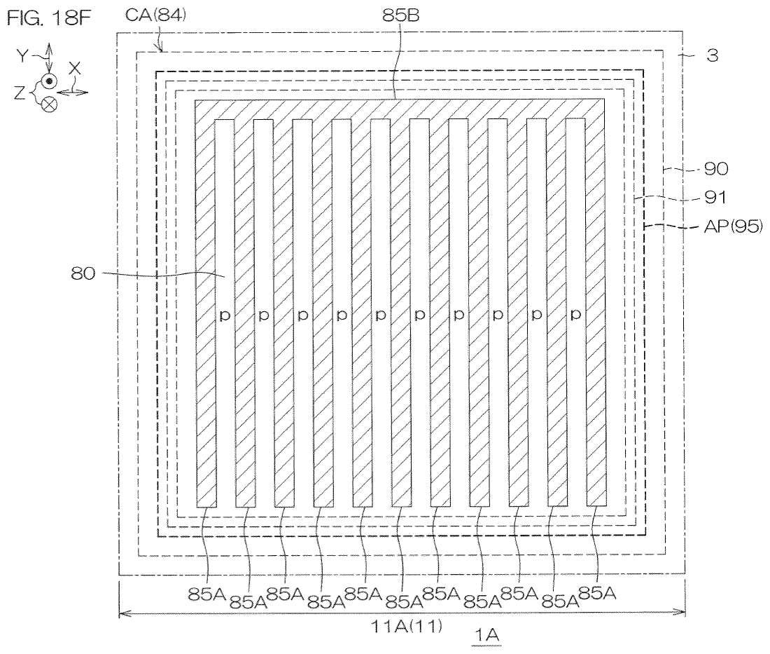

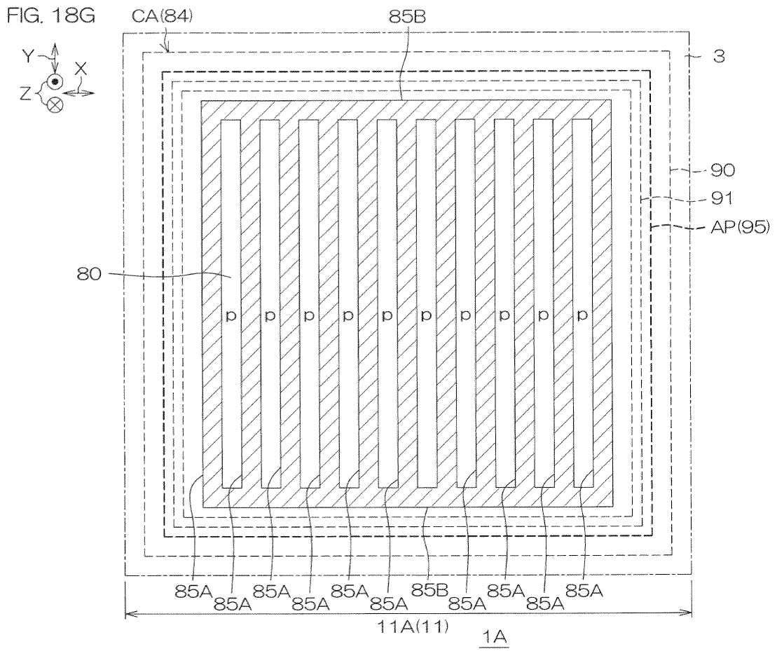

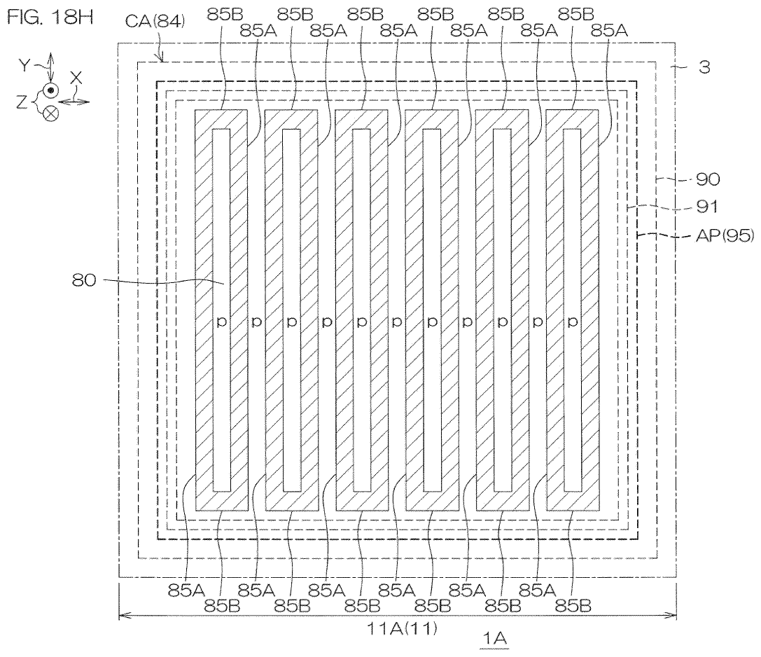

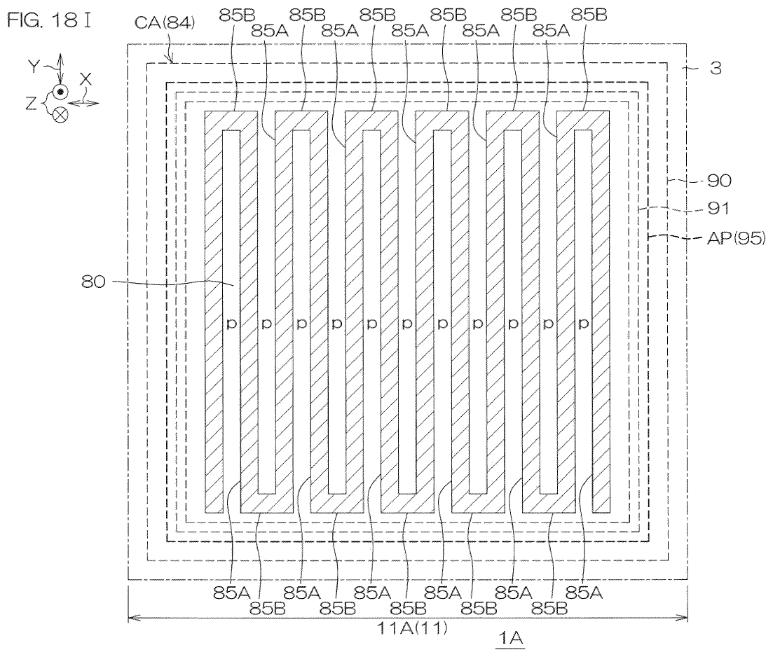

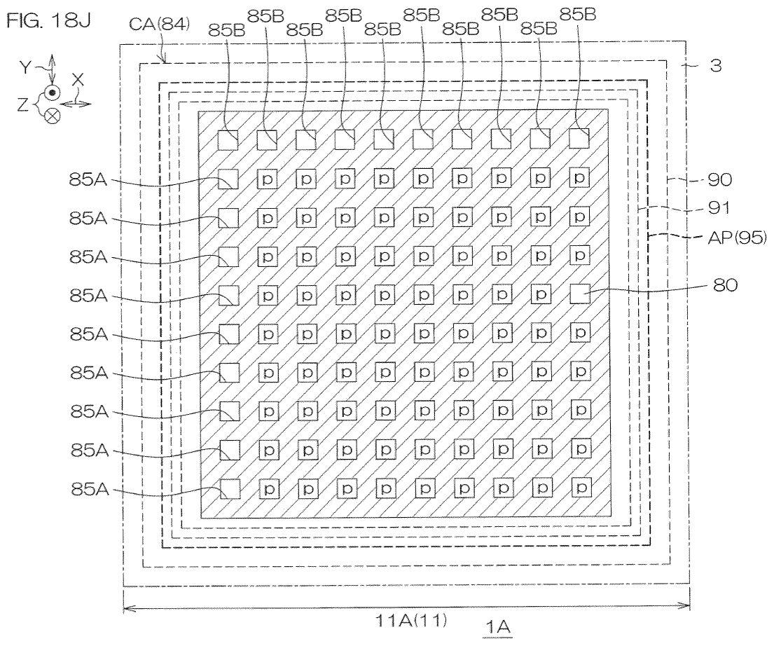

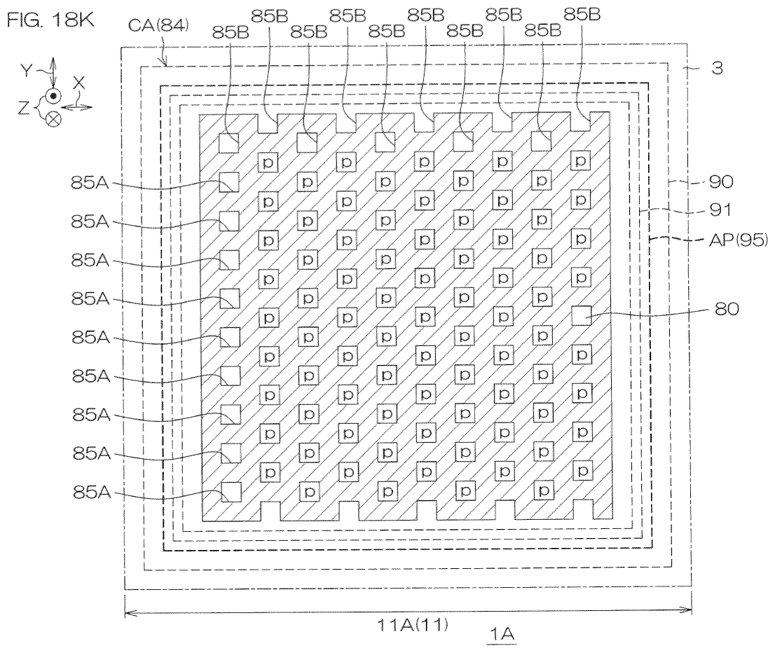

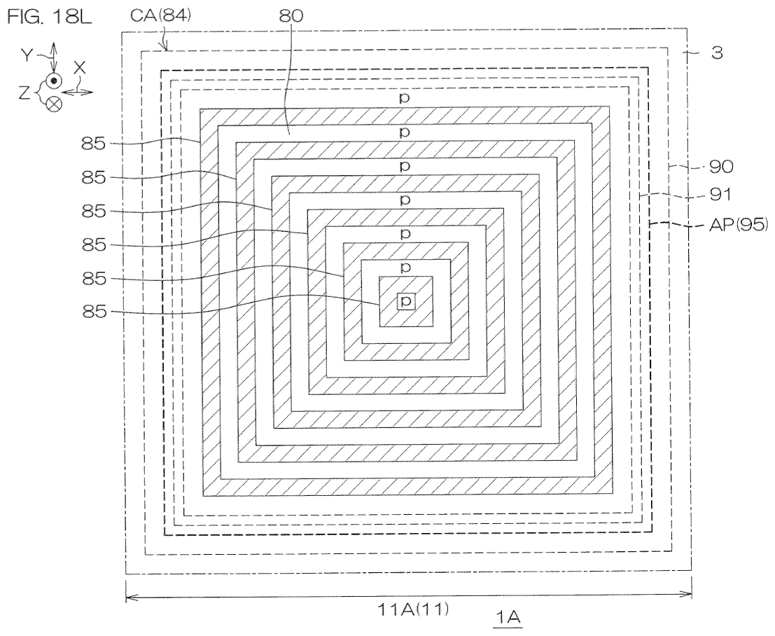

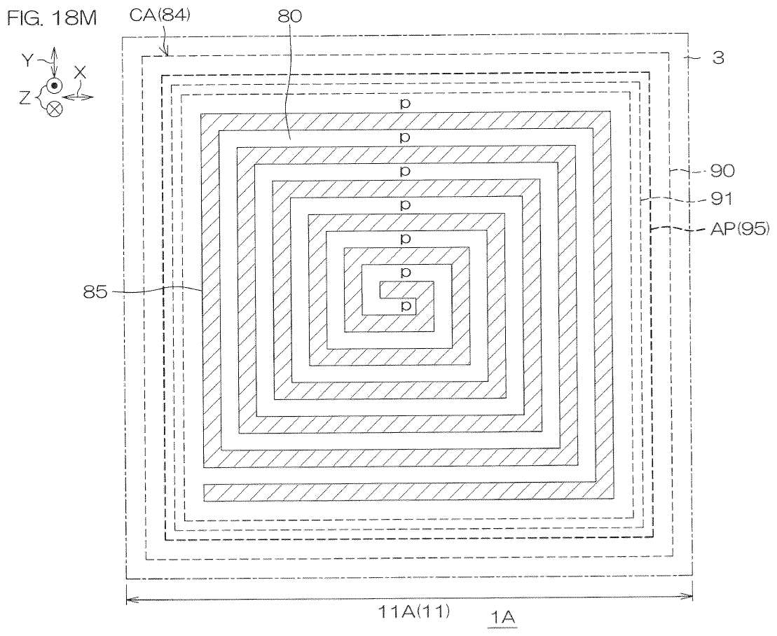

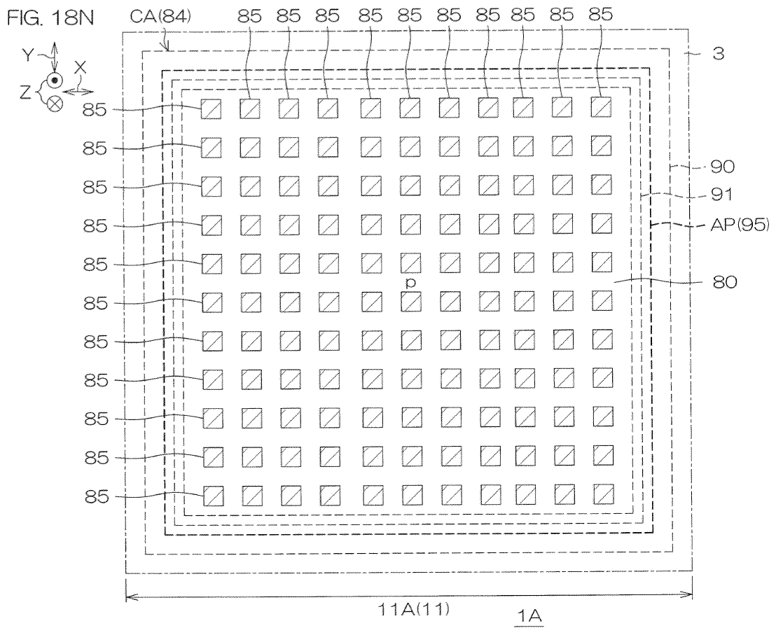

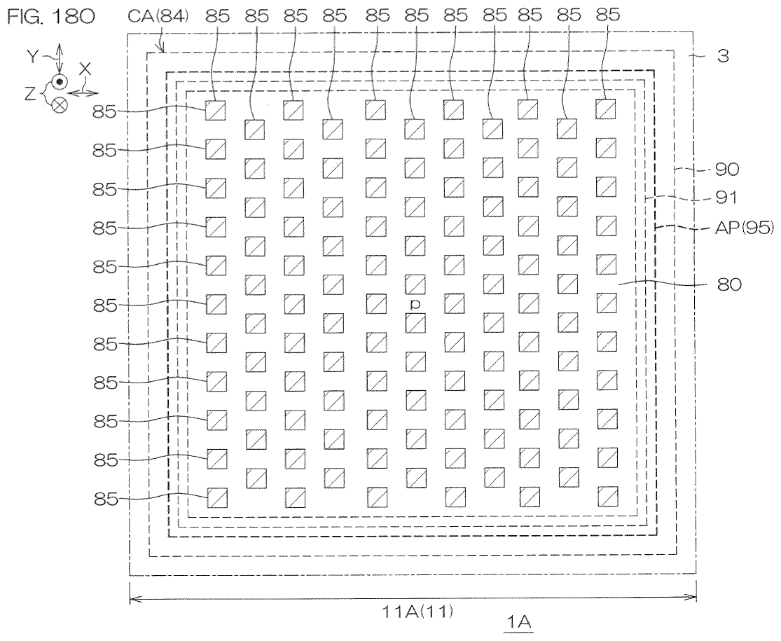

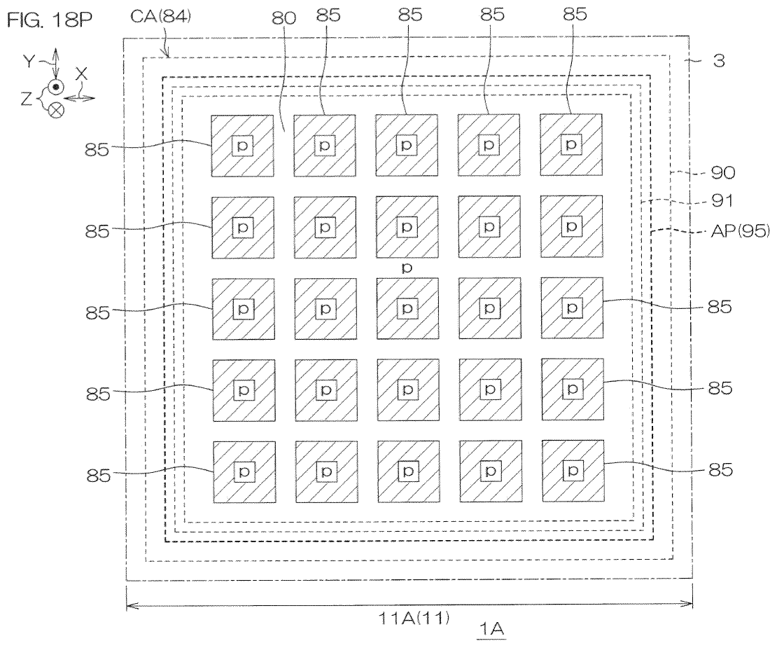

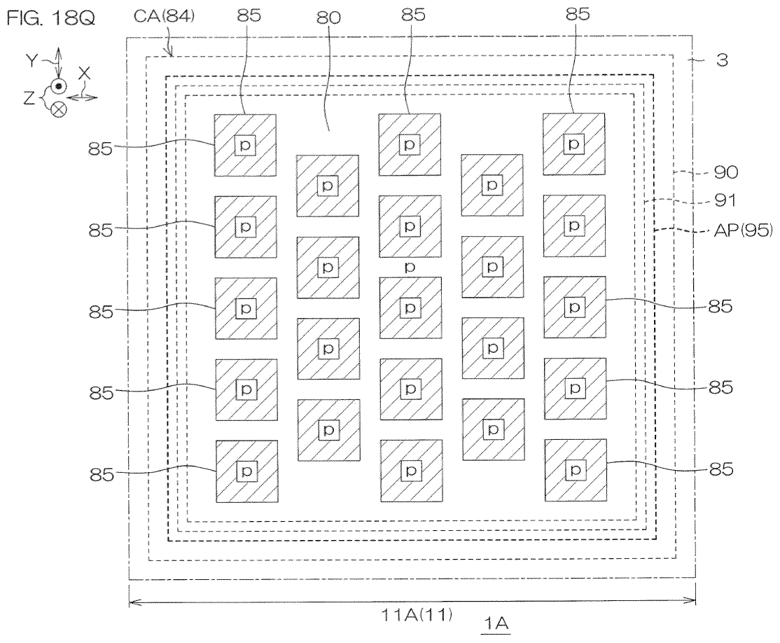

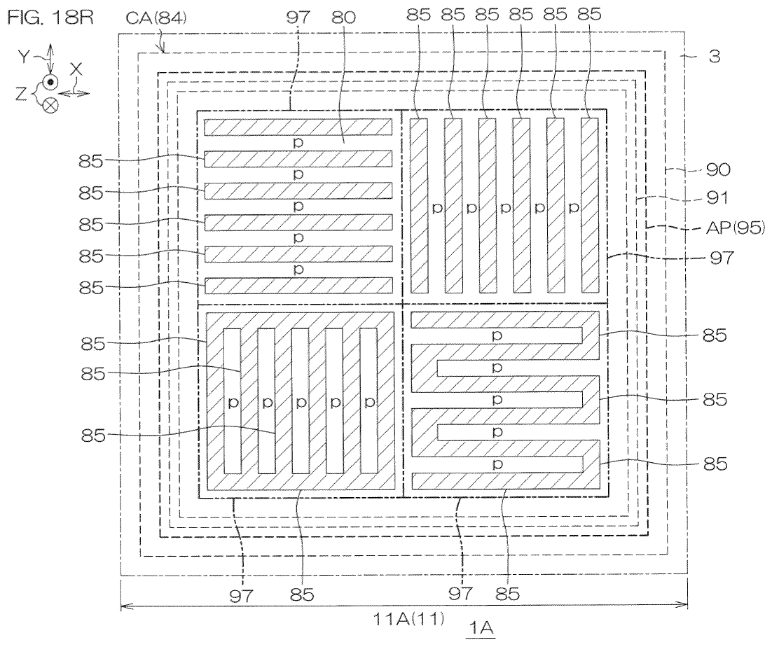

Hereinafter, another layout example of the pad capacitor structure 84 shall be described. FIG. 18A to FIG. 18R are plan views showing pad capacitor structures 84 according to second to nineteenth layout examples. The plurality of pad regions 11 may each include at least one of the pad capacitor structures 84 according to the second to nineteenth layout examples instead of or in addition to the pad capacitor structure 84 according to the first layout example.

That is, the monitor pad region 11M may include at least one of the pad capacitor structures 84 (the monitor capacitor structures CM) according to the first to nineteenth layout examples. The anode pad region 11A may include at least one of the pad capacitor structures 84 (the anode capacitor structures CA) according to the first to nineteenth layout examples.

The cathode pad region 11C may include at least one of the pad capacitor structures 84 (the cathode capacitor structures CC) according to the first to nineteenth layout examples. The monitor pad region 11M, the anode pad region 11A, and the cathode pad region 11C do not necessarily have the pad capacitor structure 84 according to the same layout example, and may have the pad capacitor structures 84 according to different layout examples.

Referring to FIG. 18A (second layout example), the pad capacitor structure 84 includes a plurality of capacitor structures 85 as in the case of the first layout example. In this embodiment, the plurality of capacitor structures 85 include a plurality of first capacitor structures 85A extending in a stripe shape in the first direction X and one second capacitor structure 85B extending in the second direction Y.

The plurality of first capacitor structures 85A each have one end portion on one side (third side surface 5C side) in the longitudinal direction (the first direction X) and the other end portion on the other side (fourth side surface 5D side) in the longitudinal direction (the first direction X).

The second capacitor structure 85B extends in a band shape in the second direction Y and is connected to one end portions of the plurality of first capacitor structures 85A. That is, the plurality of capacitor structures 85 form one comb-teeth shaped capacitor structure 85 in plan view. As a matter of course, the second capacitor structure 85B may be connected to the other end portions of the plurality of first capacitor structures 85A.

Referring to FIG. 18B (third layout example), the pad capacitor structure 84 includes the plurality of capacitor structures 85 as in the case of the first layout example. In this embodiment, the plurality of capacitor structures 85 include the plurality of first capacitor structures 85A extending in a stripe shape in the first direction X and a plurality of the second capacitor structures 85B extending in the second direction Y.

The plurality of first capacitor structures 85A each have one end portion on one side (third side surface 5C side) in the longitudinal direction (the first direction X) and the other end portion on the other side (fourth side surface 5D side) in the longitudinal direction (the first direction X).

The plurality of second capacitor structures 85B are respectively arranged on both sides of the plurality of first capacitor structures 85A in the first direction X. One second capacitor structure 85B extends in a band shape in the second direction Y and is connected to one end portion of the first capacitor structure 85A.

The other second capacitor structure 85B extends in a band shape in the second direction Y and is connected to the other end portion of the first capacitor structure 85A. That is, the plurality of capacitor structures 85 form the single ladder-shaped capacitor structure 85 in plan view.

Referring to FIG. 18C (fourth layout example), the pad capacitor structure 84 includes the plurality of capacitor structures 85 as in the case of the first layout example. In this embodiment, the plurality of capacitor structures 85 include the plurality of first capacitor structures 85A extending in a stripe shape in the first direction X and a plurality of the second capacitor structures 85B extending in the second direction Y.

The plurality of first capacitor structures 85A each have one end portion on one side (third side surface 5C side) in the longitudinal direction (the first direction X) and the other end portion on the other side (fourth side surface 5D side) in the longitudinal direction (the first direction X).

The plurality of second capacitor structures 85B are respectively arranged on both sides of the plurality of first capacitor structures 85A in the first direction X. The plurality of second capacitor structures 85B on one side are formed at intervals in the second direction Y, and are each connected to one end portions of the plurality of (in this embodiment, two) first capacitor structures 85A adjacent to each other in the second direction Y.

The plurality of second capacitor structures 85B on the other side are formed at intervals in the second direction Y so as to face the plurality of second capacitor structures 85B on the one side in the first direction X in a one-to-one correspondence, and are respectively connected to the other end portions of the plurality of (in this embodiment, two) first capacitor structures 85A adjacent to each other in the second direction Y. That is, the plurality of capacitor structures 85 form a plurality of annular (quadrangular annular) capacitor structures 85 extending in the first direction X in plan view.

Referring to FIG. 18D (fifth layout example), the pad capacitor structure 84 includes a plurality of capacitor structures 85 as in the case of the first layout example. In this embodiment, the plurality of capacitor structures 85 include the plurality of first capacitor structures 85A extending in a stripe shape in the first direction X and a plurality of the second capacitor structures 85B extending in the second direction Y.

The plurality of first capacitor structures 85A each have one end portion on one side (third side surface 5C side) in the longitudinal direction (the first direction X) and the other end portion on the other side (fourth side surface 5D side) in the longitudinal direction (the first direction X).

The plurality of second capacitor structures 85B are respectively arranged on both sides of the plurality of first capacitor structures 85A in the first direction X. The plurality of second capacitor structures 85B on one side are formed at intervals in the second direction Y, and are each connected to one end portions of the plurality of (in this embodiment, two) first capacitor structures 85A adjacent to each other in the second direction Y.

The plurality of second capacitor structures 85B on the other side are arranged to be shifted in the second direction Y with respect to the plurality of second capacitor structures 85B on the one side so as to face the two second capacitor structures 85B in the one side in the first direction X.

The plurality of second capacitor structures 85B on the other side are formed at intervals in the second direction Y, and are each connected to the other end portions of the plurality of (in this embodiment, two) first capacitor structures 85A adjacent to each other in the second direction Y. That is, the plurality of capacitor structures 85 form the single zigzag-shaped capacitor structure 85 having a portion extending in the first direction X and a portion extending in the second direction Y in plan view.

Referring to FIG. 18E (sixth layout example), the pad capacitor structure 84 includes the plurality of capacitor structures 85 as in the case of the first layout example. The plurality of capacitor structures 85 have a layout in which the extension direction of the capacitor structure 85 according to the first layout example is changed from the first direction X to the second direction Y.

That is, the plurality of capacitor structures 85 extend in a stripe shape extending in the second direction Y. In this embodiment, the extension direction of the plurality of capacitor structures 85 is a direction intersecting (specifically, orthogonal to) the extension direction of the plurality of gate structures 20 (the plurality of emitter structures 30).

Referring to FIG. 18F (seventh layout example), the pad capacitor structure 84 includes the plurality of capacitor structures 85 as in the case of the first layout example. In this embodiment, the plurality of capacitor structures 85 include a plurality of first capacitor structures 85A extending in a stripe shape in the second direction Y and one second capacitor structure 85B extending in the first direction X.

The plurality of first capacitor structures 85A each have one end portion on one side (first side surface 5A side) in the longitudinal direction (the second direction Y) and the other end portion on the other side (second side surface 5B side) in the longitudinal direction (the second direction Y).

The second capacitor structure 85B extends in a band shape in the first direction X and is connected to one end portions of the plurality of first capacitor structures 85A. That is, the plurality of capacitor structures 85 form one comb-teeth shaped capacitor structure 85 in plan view. As a matter of course, the second capacitor structure 85B may be connected to the other end portions of the plurality of second capacitor structure 85B.

Referring to FIG. 18G (eighth layout example), the pad capacitor structure 84 includes the plurality of capacitor structures 85 as in the case of the first layout example. In this embodiment, the plurality of capacitor structures 85 include a plurality of first capacitor structures 85A extending in a stripe shape in the second direction Y and a plurality of second capacitor structures 85B extending in the first direction X.

The plurality of first capacitor structures 85A each have one end portion on one side (first side surface 5A side) in the longitudinal direction (the second direction Y) and the other end portion on the other side (second side surface 5B side) in the longitudinal direction (the second direction Y).

The plurality of second capacitor structures 85B are respectively arranged on both sides of the plurality of first capacitor structures 85A in the second direction Y. One second capacitor structure 85B extends in a band shape in the second direction Y and is connected to one end portions of the plurality of first capacitor structures 85A.

The other second capacitor structure 85B extends in a band shape in the second direction Y and is connected to the other end portions of the plurality of first capacitor structures 85A. That is, the plurality of capacitor structures 85 form the single ladder-shaped capacitor structure 85 in plan view.

Referring to FIG. 18H (ninth layout example), the pad capacitor structure 84 includes the plurality of capacitor structures 85 as in the case of the first layout example. In this embodiment, the plurality of capacitor structures 85 include a plurality of first capacitor structures 85A extending in a stripe shape in the second direction Y and a plurality of second capacitor structures 85B extending in the first direction X.

The plurality of first capacitor structures 85A each have one end portion on one side (first side surface 5A side) in the longitudinal direction (the second direction Y) and the other end portion on the other side (second side surface 5B side) in the longitudinal direction (the second direction Y).

The plurality of second capacitor structures 85B are respectively arranged on both sides of the plurality of first capacitor structures 85A in the second direction Y. The plurality of second capacitor structures 85B on one side are formed at intervals in the first direction X, and are each connected to one end portions of the plurality of (in this embodiment, two) first capacitor structures 85A adjacent to each other in the first direction X.

The plurality of second capacitor structures 85B on the other side are formed at intervals in the first direction X so as to face the plurality of second capacitor structures 85B on the one side in the second direction Y in a one-to-one correspondence, and are respectively connected to the other end portions of the plurality of (in this embodiment, two) first capacitor structures 85A adjacent to each other in the first direction X. That is, the plurality of capacitor structures 85 form a plurality of annular (quadrangular annular) capacitor structures 85 extending in the second direction Y in plan view.

Referring to FIG. 18I (tenth layout example), the pad capacitor structure 84 includes the plurality of capacitor structures 85 as in the case of the first layout example. In this embodiment, the plurality of capacitor structures 85 include a plurality of first capacitor structures 85A extending in a stripe shape in the second direction Y and a plurality of second capacitor structures 85B extending in the first direction X.

The plurality of first capacitor structures 85A each have one end portion on one side (first side surface 5A side) in the longitudinal direction (the second direction Y) and the other end portion on the other side (second side surface 5B side) in the longitudinal direction (the second direction Y).

The plurality of second capacitor structures 85B are respectively arranged on both sides of the plurality of first capacitor structures 85A in the second direction Y. The plurality of second capacitor structures 85B on one side are formed at intervals in the first direction X, and are each connected to one end portions of the plurality of (in this embodiment, two) first capacitor structures 85A adjacent to each other in the first direction X.

The plurality of second capacitor structures 85B on the other side are arranged to be shifted in the first direction X with respect to the plurality of second capacitor structures 85B on the one side so as to face the two second capacitor structures 85B in the one side in the second direction Y.

The plurality of second capacitor structures 85B on the other side are formed at intervals in the first direction X, and are each connected to the other end portions of the plurality of (in this embodiment, two) first capacitor structures 85A adjacent to each other in the first direction X. That is, the plurality of capacitor structures 85 form the single zigzag-shaped capacitor structure 85 having a portion extending in the first direction X and a portion extending in the second direction Y in plan view.

Referring to FIG. 18J (eleventh layout example), the pad capacitor structure 84 includes the plurality of capacitor structures 85 as in the case of the first layout example. The plurality of capacitor structures 85 include a plurality of first capacitor structures 85A extending in a stripe shape in the first direction X and a plurality of second capacitor structures 85B extending in the second direction Y.

The plurality of second capacitor structures 85B are respectively arranged in regions between the plurality of first capacitor structures 85A adjacent to each other in the second direction Y, and are arrayed at intervals in the first direction X. The plurality of second capacitor structures 85B arranged on one side in the second direction Y with respect to one first capacitor structure 85A respectively face the plurality of second capacitor structures 85B arranged on the other side in the second direction Y with respect to the one first capacitor structure 85A in a one-to-one correspondence.

The plurality of second capacitor structures 85B form a plurality of intersections with the plurality of first capacitor structures 85A, and demarcate a plurality of mesa portions arrayed in a matrix in the first direction X and the second direction Y. That is, the plurality of capacitor structures 85 form one capacitor structure 85 extending in a lattice shape (mesh shape) in the first direction X and the second direction Y in plan view.

Referring to FIG. 18K (twelfth layout example), the pad capacitor structure 84 includes the plurality of capacitor structures 85 as in the case of the first layout example. The plurality of capacitor structures 85 include a plurality of first capacitor structures 85A extending in a stripe shape in the first direction X and a plurality of second capacitor structures 85B extending in the second direction Y.

The plurality of second capacitor structures 85B are respectively arranged in regions between the plurality of first capacitor structures 85A adjacent to each other in the second direction Y, and are arrayed at intervals in the first direction X. The plurality of second capacitor structures 85B arranged on one side in the second direction Y with respect to one first capacitor structure 85A respectively face regions between the plurality of second capacitor structures 85B arranged on the other side in the second direction Y with respect to the one first capacitor structure 85A in a one-to-one correspondence.

The plurality of second capacitor structures 85B form a plurality of T-junctions with the plurality of first capacitor structures 85A, and demarcate a plurality of mesa portions arrayed in a staggered manner in the first direction X and the second direction Y. That is, the plurality of capacitor structures 85 form one capacitor structure 85 extending in a staggered lattice shape (mesh shape) in the first direction X and the second direction Y in plan view.

Referring to FIG. 18L (thirteenth layout example), the pad capacitor structure 84 includes the plurality of capacitor structures 85 each formed in an annular shape in plan view. The plurality of capacitor structures 85 are formed at an interval toward the peripheral edge portion of the pad region 11 from the inner portion of the pad region 11 so as to sequentially surround the capacitor structure 85 on the inner side.

In this embodiment, the plurality of capacitor structures 85 are formed in a polygonal annular shape in plan view (in this embodiment, a quadrangular annular shape), and respectively have a plurality of portions extending in the first direction X and a plurality of portions extending in the second direction Y. The plurality of capacitor structures 85 may each be formed in a hexagonal annular shape, a circular annular shape, etc.

Referring to FIG. 18M (fourteenth layout example), the pad capacitor structure 84 includes the single capacitor structure 85 formed in a spiral shape in plan view. In this embodiment, the capacitor structure 85 is formed in a polygonal spiral shape (in this embodiment, a quadrangular spiral shape), and has a plurality of portions extending in the first direction X and a plurality of portions extending in the second direction Y. The capacitor structure 85 may be formed in a hexagonal spiral shape, a circular spiral shape, etc.

Referring to FIG. 18N (fifteenth layout example), the pad capacitor structure 84 includes the plurality of capacitor structures 85 arrayed in a matrix at intervals in the first direction X and the second direction Y in plan view. That is, the plurality of capacitor structures 85 may demarcate a mesa portion in a lattice shape (mesh shape) having a plurality of intersections in the first main surface 3.

The plurality of capacitor structures 85 are formed in polygonal shapes in plan view (in this embodiment, quadrangular shapes). The plurality of capacitor structures 85 may each be formed in a hexagonal shape, a circular shape, etc., in plan view. As a matter of course, the plurality of capacitor structures 85 may each be formed in a band shape (rectangular shape) extending in the first direction X or a belt shape (rectangular shape) extending in the second direction Y in plan view.

Referring to FIG. 18O (sixteenth layout example), the pad capacitor structure 84 includes the plurality of capacitor structures 85 arrayed in a staggered manner at intervals in the first direction X and the second direction Y in plan view. That is, the plurality of capacitor structures 85 may demarcate a mesa portion in a lattice shape (mesh shape) having a plurality of T-junctions in the first main surface 3.

The plurality of capacitor structures 85 are formed in polygonal shapes in plan view (in this embodiment, quadrangular shapes). The plurality of capacitor structures 85 may each be formed in a hexagonal shape, a circular shape, etc., in plan view. As a matter of course, the plurality of capacitor structures 85 may each be formed in a band shape (rectangular shape) extending in the first direction X or a belt shape (rectangular shape) extending in the second direction Y in plan view.

Referring to FIG. 18P (seventeenth layout example), the pad capacitor structure 84 includes the plurality of capacitor structures 85 arrayed in a matrix at intervals in the first direction X and the second direction Y in plan view.

That is, the plurality of capacitor structures 85 may demarcate a mesa portion in a lattice shape (mesh shape) having a plurality of intersections in the first main surface 3. The plurality of capacitor structures 85 may each be formed in a polygonal annular shape in plan view (in this embodiment, a quadrangular annular shape). The plurality of capacitor structures 85 may each be formed in a polygonal annular shape, a circular annular shape, etc., in plan view.

Referring to FIG. 18Q (eighteenth layout example), the pad capacitor structure 84 includes the plurality of capacitor structures 85 arrayed in a staggered manner at intervals in the first direction X and the second direction Y in plan view.

That is, the plurality of capacitor structures 85 may demarcate a mesa portion in a lattice shape (mesh shape) having a plurality of T-junctions in the first main surface 3. The plurality of capacitor structures 85 are formed in polygonal annular shapes in plan view (in this embodiment, quadrangular annular shapes). The plurality of capacitor structures 85 may each be formed in a polygonal annular shape, a circular annular shape, etc., in plan view.

Referring to FIG. 18R (nineteenth layout example), the pad capacitor structure 84 may include two or more layout regions 97. For example, the number of layout regions 97 may be not more than ten. In this embodiment, the pad capacitor structure 84 includes four layout regions 97 as an example.

The plurality of layout regions 97 may be arrayed in a line in the first direction X. The plurality of layout regions 97 may be arrayed in a line in the second direction Y. The plurality of layout regions 97 may be arrayed in a matrix in the first direction X and the second direction Y. The plurality of layout regions 97 may have plane areas substantially equal to each other, or may have plane areas different from each other.

The pad capacitor structure 84 includes the plurality of capacitor structures 85 respectively formed in the plurality of layout regions 97 at intervals from each other. The plurality of capacitor structures 85 may have the same layout or different layouts. The plurality of capacitor structures 85 may each have any one layout example of the first to nineteenth layout examples.

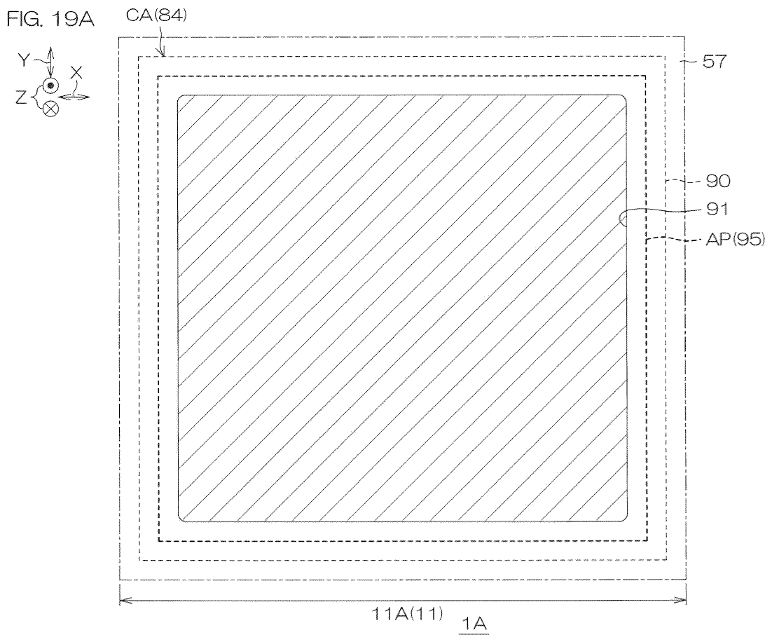

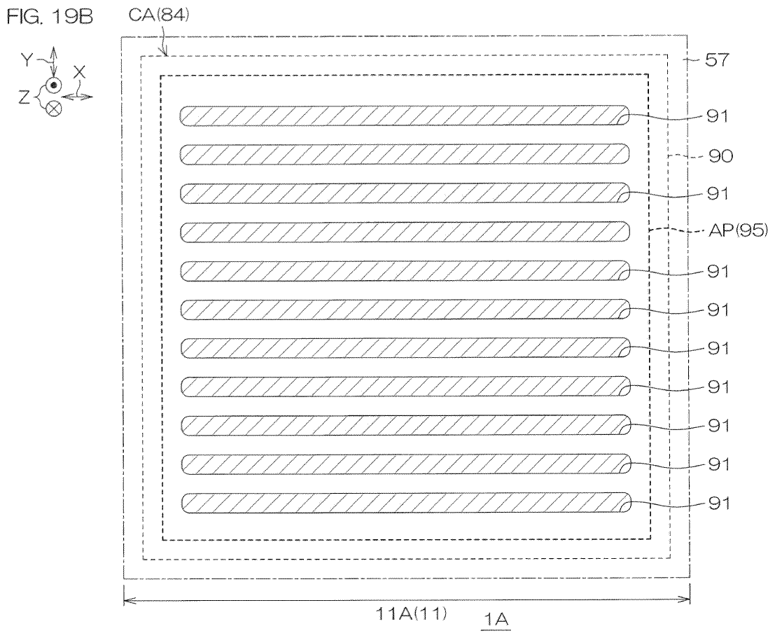

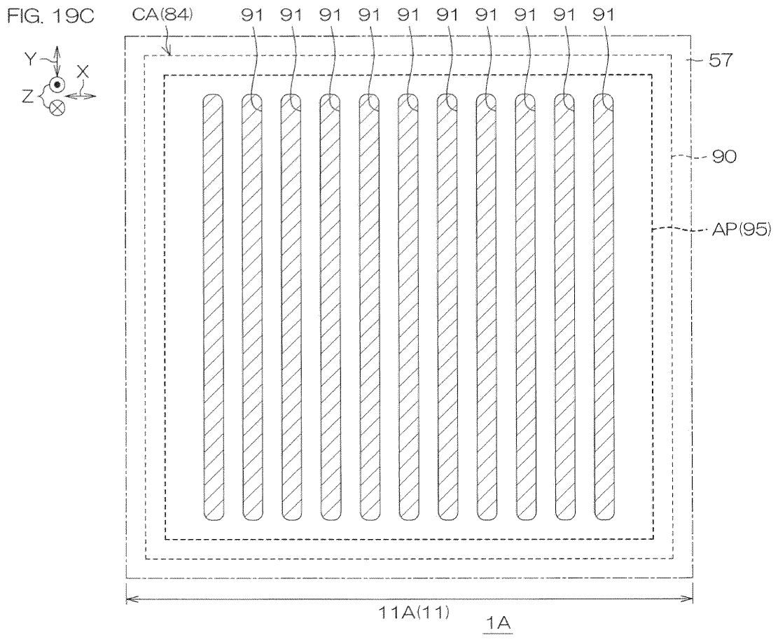

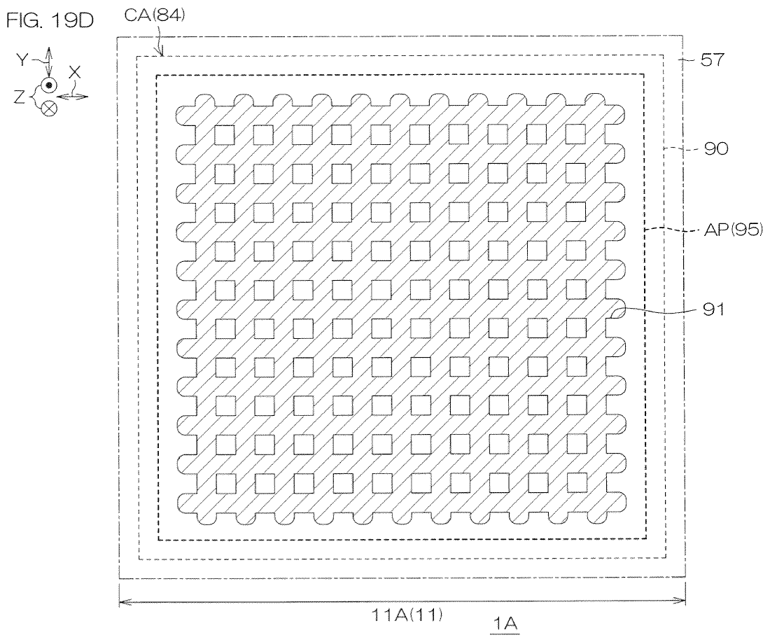

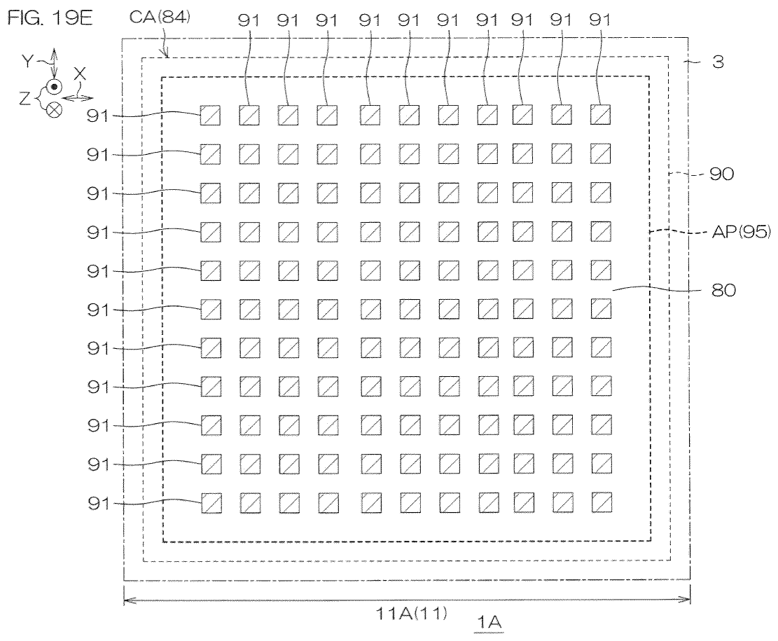

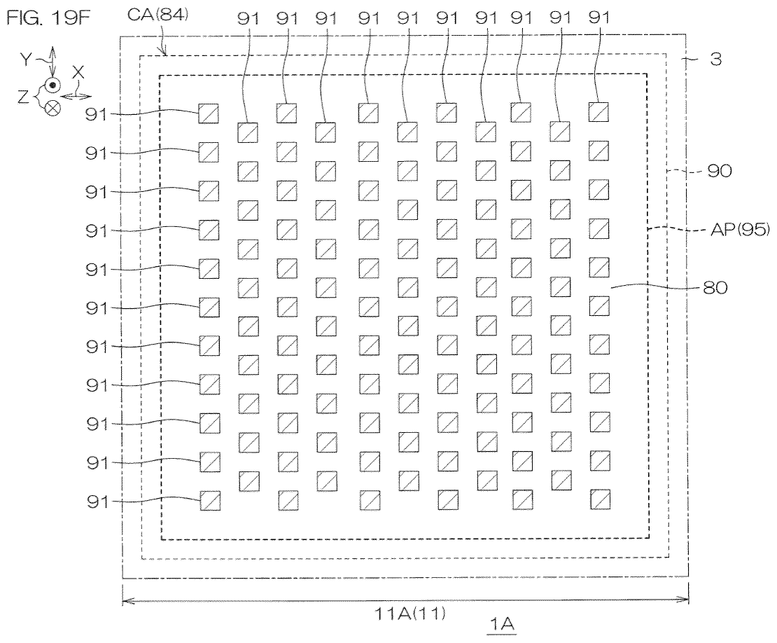

Hereinafter, other layout examples of the pad opening 91 shall be described. FIG. 19A to FIG. 19F are plan views showing the pad openings 91 according to the second to seventh layout examples. In FIG. 19A to FIG. 19F, a portion of the capacitor electrode film 90 exposed from the pad opening 91 is indicated by hatching.

Each of the pad openings 91 according to the first to seventh layout examples can be combined with any one of the pad capacitor structures 84 according to the first to nineteenth layout examples. Also, the pad openings 91 according to the first to seventh layout examples can be appropriately combined with each other.

That is, the monitor pad region 11M may have at least one of the pad openings 91 according to the first to seventh layout examples. The anode pad region 11A may have at least one of the pad openings 91 according to the first to seventh layout examples. The cathode pad region 11C may have at least one of the pad openings 91 according to the first to seventh layout examples.

The monitor pad region 11M, the anode pad region 11A, and the cathode pad region 11C do not necessarily have the pad opening 91 according to the same layout example, and may have the pad openings 91 according to mutually different layout examples.

Referring to FIG. 19A (second layout example), the pad capacitor structure 84 includes the single pad opening 91 that has a plane area less than the plane area of the capacitor electrode film 90 and exposes the inner portion of the capacitor electrode film 90 at an interval from the peripheral edge of the capacitor electrode film 90. The pad opening 91 has a wall surface extending along the peripheral edge of the capacitor electrode film 90 in plan view, and is formed in a region overlapping the plurality of capacitor structures 85.

The area ratio of the plane area of the pad opening 91 to the plane area of the capacitor electrode film 90 may be not less than 0.1 and less than 1. The area ratio may have a value belonging to at least one range among not less than 0.1 and not more than 0.25, not less than 0.25 and not more than 0.5, not less than 0.5 and not more than 0.75, and not less than 0.75 and less than 1. The area ratio is preferably not less than 0.5.

Referring to FIG. 19B (third layout example), the pad capacitor structure 84 includes a plurality of the pad openings 91. The plurality of pad openings 91 each extend in a band shape in the first direction X and are formed at intervals in the second direction Y. That is, the plurality of pad openings 91 extend in a stripe shape extending in the first direction X.

The plurality of pad openings 91 may have portions overlapping the single or the plurality of capacitor structures 85 in a lamination direction. The plurality of pad openings 91 may each be formed in a region not overlapping the capacitor structure 85 in the lamination direction. When the pad capacitor structure 84 includes the single or the plurality of capacitor structures 85 extending in the second direction Y, the plurality of pad openings 91 may intersect (be orthogonal to) the single or the plurality of capacitor structures 85.

Referring to FIG. 19C (fourth layout example), the pad capacitor structure 84 includes the plurality of pad openings 91. The plurality of pad openings 91 each extend in a band shape in the second direction Y and are formed at intervals in the first direction X. That is, the plurality of pad openings 91 extend in a stripe shape extending in the second direction Y.

The plurality of pad openings 91 may have portions overlapping the single or the plurality of capacitor structures 85 in a lamination direction. The plurality of pad openings 91 may each be formed in a region not overlapping the capacitor structure 85 in the lamination direction. When the pad capacitor structure 84 includes the single or the plurality of capacitor structures 85 extending in the first direction X, the plurality of pad openings 91 may intersect (be orthogonal to) the single or the plurality of capacitor structures 85.

Referring to FIG. 19D (fifth layout example), the pad capacitor structure 84 may include the single pad opening 91 formed in a lattice shape in plan view. The pad opening 91 may intersect the plurality of capacitor structures 85 in plan view.

Referring to FIG. 19E (sixth layout example), the pad capacitor structure 84 may include the plurality of pad openings 91 arrayed as dots in the first direction X and the second direction Y in plan view. The plurality of pad openings 91 may be arrayed in a matrix at intervals in the first direction X and the second direction Y so that a plurality of intersections are demarcated on the insulating surface of the interlayer film 57.

The plurality of pad openings 91 may have portions overlapping the single or the plurality of capacitor structures 85 in a lamination direction. The plurality of pad openings 91 may each be formed in a region not overlapping the capacitor structure 85 in the lamination direction. The plurality of pad openings 91 may each be formed in a polygonal shape, a circular shape, etc., in plan view. In this embodiment, the plurality of pad openings 91 are formed in quadrangular shapes.

Referring to FIG. 19F (seventh layout example), the pad capacitor structure 84 may include the plurality of pad openings 91 arrayed as dots in the first direction X and the second direction Y in plan view. The plurality of pad openings 91 may be arrayed in a staggered manner at intervals in the first direction X and the second direction Y so that a plurality of T-junctions are demarcated on the insulating surface of the interlayer film 57.

The plurality of pad openings 91 may have portions overlapping the single or the plurality of capacitor structures 85 in a lamination direction. The plurality of pad openings 91 may each be formed in a region not overlapping the capacitor structure 85 in the lamination direction. The plurality of pad openings 91 may each be formed in a polygonal shape, a circular shape, etc., in plan view. In this embodiment, the plurality of pad openings 91 are formed in quadrangular shapes.

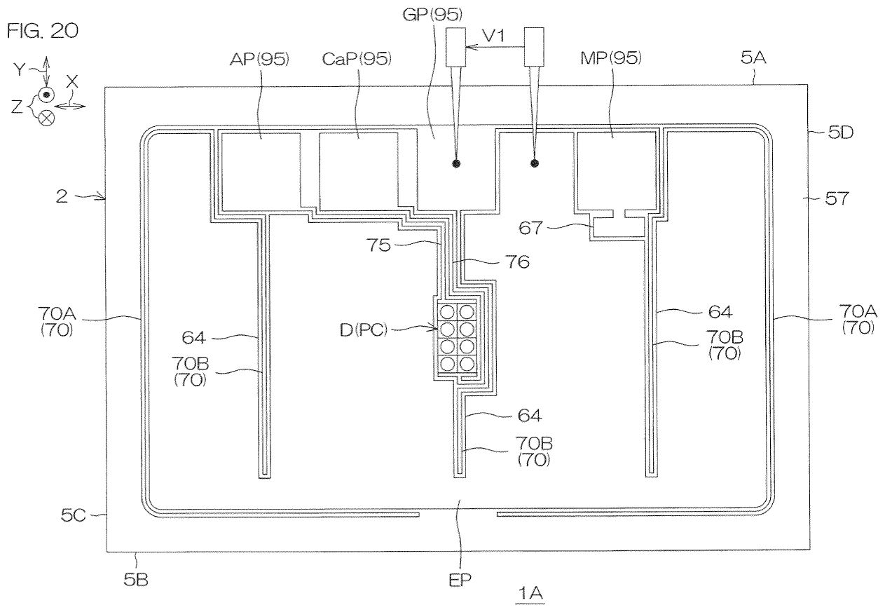

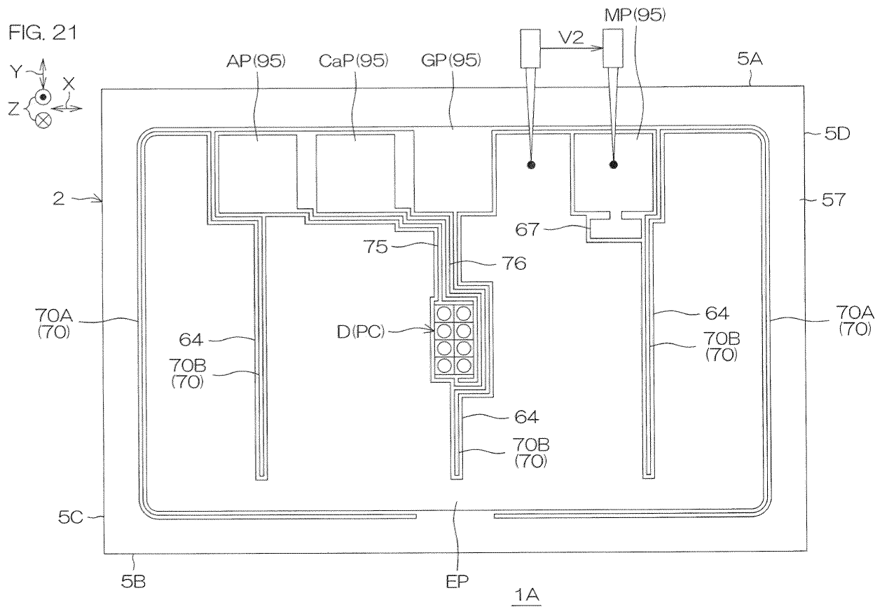

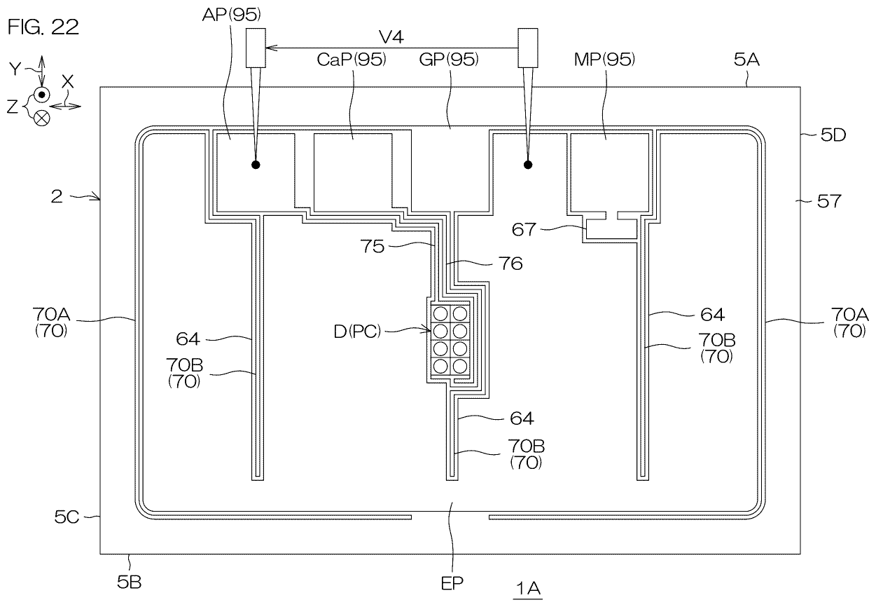

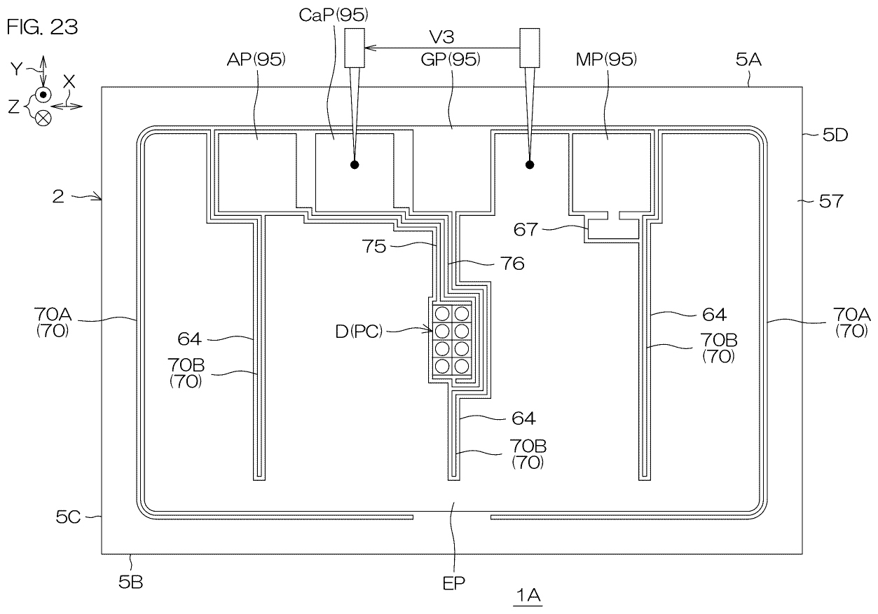

Hereinafter, an example of an electric test performed on the semiconductor device 1A shall be described. FIG. 20 is a plan view for explaining an electric test on the gate pad GP side. FIG. 21 is a plan view for explaining an electric test on the monitor pad MP side. FIG. 22 is a plan view for explaining an electric test on the anode pad AP side. FIG. 23 is a plan view for explaining an electric test on the cathode pad CaP side.

The electric test is an ESD (electro static discharge) tolerance measurement test of an HBM (human body model) with respect to the semiconductor device 1A (the plurality of pad electrodes 95). The HBM is a model assuming that the ESD occurs between the human body and the plurality of pad electrodes 95.

Referring to FIG. 20, in the test on the gate pad GP side, a predetermined first test voltage V1 is applied between the emitter pad EP and the gate pad GP. As the first test voltage V1, various values are adopted according to the specification of the semiconductor device 1A. The first test voltage V1 is typically not less than 500 V and not more than 8000 V.

When the first test voltage V1 is applied, a predetermined test current is generated at the emitter pad EP and the gate pad GP, and the ESD tolerance between the emitter pad EP and the gate pad GP is measured. Since a relatively high capacitance value is secured between the emitter pad EP and the gate pad GP by the plurality of gate structures 20, a relatively high ESD tolerance is achieved.

Referring to FIG. 21, in the test on the monitor pad MP side, a predetermined second test voltage V2 is applied between the emitter pad EP and the monitor pad MP. The second test voltage V2 may be applied between the gate pad GP and the monitor pad MP. As the second test voltage V2, various values are adopted according to the specification of the semiconductor device 1A. The second test voltage V2 is typically not less than 500 V and not more than 8000 V.

When the second test voltage V2 is applied, a predetermined test current is generated at the emitter pad EP and the monitor pad MP, and the ESD tolerance between the emitter pad EP and the monitor pad MP is measured.

The number of gate structures 20 formed in the monitor region 7 is less than the number of gate structures 20 related to the plurality of active regions 6. That is, the capacitance values associated with the plurality of gate structures 20 in the monitor region 7 are lower than the capacitance values associated with the plurality of gate structures 20 in the plurality of active regions 6. Therefore, the ESD tolerance between the emitter pad EP and the monitor pad MP is less than the ESD tolerance between the emitter pad EP and the gate pad GP.

In this regard, in the semiconductor device 1A, the plurality of capacitor structures 85 are formed in the monitor pad region 11M, and the capacitance value between the emitter pad EP and the monitor pad MP is complemented by the plurality of capacitor structures 85. Also, in the monitor pad region 11M, the capacitance value is further increased by the capacitor electrode film 90. The ESD tolerance is thereby improved as compared with a case where the pad capacitor structure 84 is not present in the monitor pad region 11M.

Referring to FIG. 22, in the test on the anode pad AP side, a predetermined third test voltage V3 is applied between the emitter pad EP and the anode pad AP. The third test voltage V3 may be applied between the gate pad GP and the anode pad AP. As the third test voltage V3, various values are adopted according to the specification of the semiconductor device 1A. The third test voltage V3 is typically not less than 500 V and not more than 8000 V.

When the third test voltage V3 is applied, a predetermined test current is generated at the emitter pad EP and the anode pad AP, and the ESD tolerance between the emitter pad EP and the anode pad AP is measured. The gate structure 20 is not electrically interposed in a region between the emitter pad EP and the anode pad AP. Therefore, the ESD tolerance between the emitter pad EP and the anode pad AP is less than the ESD tolerance between the emitter pad EP and the gate pad GP.

In this regard, in the semiconductor device 1A, the plurality of capacitor structures 85 are formed in the anode pad region 11A, and the capacitance value between the emitter pad EP and the anode pad AP is complemented by the plurality of capacitor structures 85. Also, in the anode pad region 11A, the capacitance value is further increased by the capacitor electrode film 90. The ESD tolerance is thereby improved as compared with a case where the pad capacitor structure 84 is not present in the anode pad region 11A.

Referring to FIG. 23, in the test on the cathode pad CaP side, a predetermined fourth test voltage V4 is applied between the emitter pad EP and the cathode pad CaP. The fourth test voltage V4 may be applied between the gate pad GP and the cathode pad CaP. As the fourth test voltage V4, various values are adopted according to the specification of the semiconductor device 1A. The fourth test voltage V4 is typically not less than 500 V and not more than 8000 V.

When the fourth test voltage V4 is applied, a predetermined test current is generated at the emitter pad EP and the cathode pad CaP, and the ESD tolerance between the emitter pad EP and the cathode pad CaP is measured.

The gate structure 20 is not electrically interposed in a region between the emitter pad EP and the cathode pad CaP. Therefore, the ESD tolerance between the emitter pad EP and the cathode pad CaP is less than the ESD tolerance between the emitter pad EP and the gate pad GP.

In this regard, in the semiconductor device 1A, the plurality of capacitor structures 85 are formed in the cathode pad region 11C, and the capacitance value between the emitter pad EP and the cathode pad CaP is complemented by the plurality of capacitor structures 85. Also, in the cathode pad region 11C, the capacitance value is further increased by the capacitor electrode film 90. The ESD tolerance is thereby improved as compared with a case where the pad capacitor structure 84 is not present in the cathode pad region 11C.

As described above, the semiconductor device 1A may include the chip 2, the active region 6, the pad region 11, the transistor structure T3 of the insulated gate type, the capacitor structure 85 of the trench electrode type, and the pad electrode 95. The chip 2 may have the first main surface 3. The active region 6 may be provided in the first main surface 3.

The pad region 11 may be provided outside the active region 6 in the first main surface 3. The transistor structure T3 may be formed in the first main surface 3 in the active region 6. The capacitor structure 85 may be formed in the first main surface 3 in the pad region 11 and form capacitive coupling with the chip 2. The pad electrode 95 may be arranged on the first main surface 3 in the pad region 11 and electrically connected to the capacitor structure 85.

According to this arrangement, the semiconductor device 1A capable of improving electrical characteristics is provided. Specifically, according to the semiconductor device 1A, as a result of an increase in the capacitance value below the pad electrode 95 by the capacitor structure 85, the ESD tolerance is improved.

The transistor structure T3 may include the gate structure 20 of the trench electrode type to which a gate potential is to be applied. In this case, the pad electrode 95 may apply a potential other than the gate potential to the capacitor structure 85. According to this arrangement, the capacitance value can be improved in a region below the pad electrode 95 to which the potential other than the gate potential is to be applied.

The capacitor structure 85 may have a depth equal to the depth of the gate structure 20. According to this arrangement, the capacitance value below the pad electrode 95 is increased by the capacitor structure 85 having a depth equal to the depth of the gate structure 20. In this case, the capacitor structure 85 can be manufactured simultaneously with the gate structure 20.

The transistor structure T3 may include the emitter structure 30 of the trench electrode type to which an emitter potential is to be applied. In this case, the pad electrode 95 may apply a potential other than the emitter potential to the capacitor structure 85. According to this arrangement, the capacitance value can be improved in a region below the pad electrode 95 to which the potential other than the emitter potential is to be applied.

The capacitor structure 85 may have a depth equal to the depth of the emitter structure 30. According to this arrangement, the capacitance value below the pad electrode 95 is increased by the capacitor structure 85 having a depth equal to the depth of the emitter structure 30. In this case, the capacitor structure 85 can be manufactured simultaneously with the emitter structure 30.

The semiconductor device 1A may include the monitor region 7 and the monitor transistor structure T2 for current monitoring. The monitor region 7 may be provided outside the active region 6 in the first main surface 3. The monitor transistor structure T2 may be formed in the first main surface 3 in the monitor region 7.

In this case, a potential for the monitor transistor structure T2 may be applied to the pad electrode 95. According to this arrangement, the capacitance value can be improved in a region below the pad electrode 95 to which the potential for the monitor transistor structure T2 is to be applied.

The semiconductor device 1A may include the monitor electrode 67. The monitor electrode 67 may be electrically connected to the monitor transistor structure T2 on the first main surface 3 in the monitor region 7. In this case, the pad electrode 95 may be electrically connected to the monitor electrode 67 and apply a potential to the monitor transistor structure T2 via the monitor electrode 67.

The semiconductor device 1A may include the temperature detecting region 10 (diode region) and the temperature sensitive diode structure D (diode structure). The temperature detecting region 10 may be provided outside the active region 6 in the first main surface 3. The temperature sensitive diode structure D may be formed in the first main surface 3 in the temperature detecting region 10.

In this case, a potential for the temperature sensitive diode structure D may be applied to the pad electrode 95. According to this arrangement, the capacitance value can be improved in a region below the pad electrode 95 to which the potential for the temperature sensitive diode structure D is to be applied.

The semiconductor device 1A may include the anode wiring 75. The anode wiring 75 may be electrically connected to the temperature sensitive diode structure D on the first main surface 3. In this case, the pad electrode 95 may be electrically connected to the anode wiring 75 and apply an anode potential to the temperature sensitive diode structure D via the anode wiring 75. According to this arrangement, the capacitance value can be improved in a region below the pad electrode 95 to which the anode potential is to be applied.

The semiconductor device 1A may include the cathode wiring 76. The cathode wiring 76 may be electrically connected to the temperature sensitive diode structure D on the first main surface 3. In this case, the pad electrode 95 may be electrically connected to the cathode wiring 76 and apply a cathode potential to the temperature sensitive diode structure D via the cathode wiring 76. According to this arrangement, the capacitance value can be improved in a region below the pad electrode 95 to which the cathode potential is to be applied.

The semiconductor device 1A may include the main surface insulating film 48 and the capacitor electrode film 90 (electrode film). The main surface insulating film 48 may cover the first main surface 3 in the pad region 11. The capacitor electrode film 90 may cover the capacitor structure 85 on the main surface insulating film 48 and form capacitive coupling with the chip 2 via the main surface insulating film 48.

In this case, the pad electrode 95 may be arranged on the capacitor electrode film 90 and electrically connected to the capacitor structure 85 via the capacitor electrode film 90. According to this arrangement, the capacitance value below the pad electrode 95 is increased by both the capacitor structure 85 and the capacitor electrode film 90.

The semiconductor device 1A may include the interlayer film 57 with an insulating property and the pad opening 91. The interlayer film 57 may cover the capacitor electrode film 90. The pad opening 91 may be formed in the interlayer film 57 so as to expose the capacitor electrode film 90.

In this case, the pad electrode 95 may be arranged on the interlayer film 57 and electrically connected to the capacitor electrode film 90 via the pad opening 91. According to this arrangement, it is possible to appropriately electrically connect the pad electrode 95 to the capacitor electrode film 90 while suppressing the contact of the pad electrode 95 with another structure.

The capacitor structure 85 may include the capacitor trench 86, the capacitor insulating film 87 (dielectric film), and the capacitor embedded electrode 88. The capacitor trench 86 may be formed in the first main surface 3.

The capacitor insulating film 87 may cover the wall surface of the capacitor trench 86. The capacitor embedded electrode 88 may form capacitive coupling with the chip 2 via the capacitor insulating film 87 in the capacitor trench 86. According to this structure, the capacitance value of the capacitor structure 85 can be adjusted by the film thickness of the capacitor insulating film 87.

In such an arrangement, the semiconductor device 1A may include the main surface insulating film 48 and the capacitor electrode film 90. The main surface insulating film 48 may cover the first main surface 3 in the pad region 11 so as to be connected to the capacitor insulating film 87. The capacitor electrode film 90 may be arranged on the main surface insulating film 48 so as to be connected to the capacitor embedded electrode 88, and may form capacitive coupling with the chip 2 via the main surface insulating film 48.

In this case, the pad electrode 95 may be arranged on the capacitor electrode film 90 and electrically connected to the embedded electrode via the capacitor electrode film 90. According to this arrangement, the capacitance value below the pad electrode 95 is increased by both the capacitor structure 85 and the capacitor electrode film 90.

The semiconductor device 1A may include the drift region 12 of the n-type (first conductivity type) and the pad well region 80 of a p-type (second conductivity type). The drift region 12 may be formed in the chip 2 in the pad region 11. The pad well region 80 may be formed in the surface layer portion of the first main surface 3 in the pad region 11 and electrically connected to the drift region 12.

In this case, the capacitor structure 85 may be arranged in the pad well region 80 and form capacitive coupling with the pad well region 80. According to this arrangement, the capacitance value below the pad electrode 95 can be increased by the capacitor structure 85 that forms capacitive coupling with the pad well region 80.

The capacitor structure 85 may be positioned in the pad well region 80 at an interval toward the first main surface 3 side from the bottom portion of the pad well region 80. According to this arrangement, the capacitor structure 85 can form capacitive coupling with the pad well region 80 over the entire region in the thickness direction.

The semiconductor device 1A may include the p-type base region 15. The base region 15 may be formed in the surface layer portion of the first main surface 3 in the active region 6 and electrically connected to the drift region 12. In this case, the pad well region 80 may be formed deeper than the base region 15. According to this arrangement, the capacitance value below the pad electrode 95 can be increased by the capacitor structure 85 that forms capacitive coupling with the pad well region 80 that is deeper the base region 15.

From another viewpoint, the semiconductor device 1A may include the chip 2, the active region 6, the pad region 11, the transistor structure T3 of the insulated gate type, the main surface insulating film 48, the capacitor electrode film 90, and the pad electrode 95. The chip 2 may have the first main surface 3. The active region 6 may be provided in the first main surface 3. The pad region 11 may be provided outside the active region 6 in the first main surface 3. The transistor structure T3 may be formed in the active region 6.

The main surface insulating film 48 may have a portion covering the first main surface 3 in the pad region 11. The main surface insulating film 48 may have a thickness of not less than 10 nm and not more than 200 nm. The capacitor electrode film 90 may be arranged on the main surface insulating film 48 in the pad region 11 and form capacitive coupling with the chip 2 via the main surface insulating film 48. The pad electrode 95 may be arranged on the capacitor electrode film 90 in the pad region 11 and electrically connected to the capacitor electrode film 90.

According to this arrangement, the semiconductor device 1A capable of improving electrical characteristics is provided. Specifically, according to the semiconductor device 1A, in the pad region 11, the capacitance value between the capacitor electrode film 90 and the chip 2 is increased by the main surface insulating film 48 as a dielectric thin film. Thereby, as a result of an increase in the capacitance value below the pad electrode 95 by the capacitor electrode film 90, the ESD tolerance is improved.

The semiconductor device 1A may include the p-type pad well region 80. The pad well region 80 may be formed in the surface layer portion of the first main surface 3 in the pad region 11. In this case, the capacitor electrode film 90 may form capacitive coupling with the pad well region 80 via the main surface insulating film 48. According to this arrangement, the capacitance value below the pad electrode 95 can be increased by the capacitor electrode film 90 that forms capacitive coupling with the pad well region 80.

The semiconductor device 1A may include the p-type base region 15. The base region 15 may be formed in the surface layer portion of the first main surface 3 in the active region 6. In this case, the pad well region 80 may be formed deeper than the base region 15. According to this arrangement, the capacitance value below the pad electrode 95 can be increased by the capacitor electrode film 90 that forms capacitive coupling with the pad well region 80 that is deeper the base region 15.

The semiconductor device 1A may include the gate trench 21, the gate insulating film 22, and the gate embedded electrode 23. The gate trench 21 may be formed in the first main surface 3 in the active region 6. The gate insulating film 22 may cover the wall surfaces of the gate trench 21. The gate insulating film 22 may have a thickness of not less than 10 nm and not more than 200 nm.

The gate embedded electrode 23 may be embedded in the gate trench 21 with the gate insulating film 22 interposed therebetween. In this case, the main surface insulating film 48 may have a portion connected to the gate insulating film 22. According to the semiconductor device 1A, the capacitor electrode film 90 can form capacitive coupling with the chip 2 via the main surface insulating film 48 having the portion connected to the gate insulating film 22.

The semiconductor device 1A may include the interlayer film 57 with an insulating property and the pad opening 91. The interlayer film 57 may have a thickness larger than the thickness of the main surface insulating film 48, and cover the capacitor electrode film 90. The pad opening 91 may be formed in the interlayer film 57 so as to expose the capacitor electrode film 90.

In this case, the pad electrode 95 may be arranged on the interlayer film 57 and electrically connected to the capacitor electrode film 90 via the pad opening 91. According to this arrangement, the capacitance value below the pad electrode 95 can be increased by using the main surface insulating film 48 having a thickness smaller than the thickness of the interlayer film 57. Also, it is possible to appropriately electrically connect the pad electrode 95 to the capacitor electrode film 90 while suppressing the contact of the pad electrode 95 with another structure.

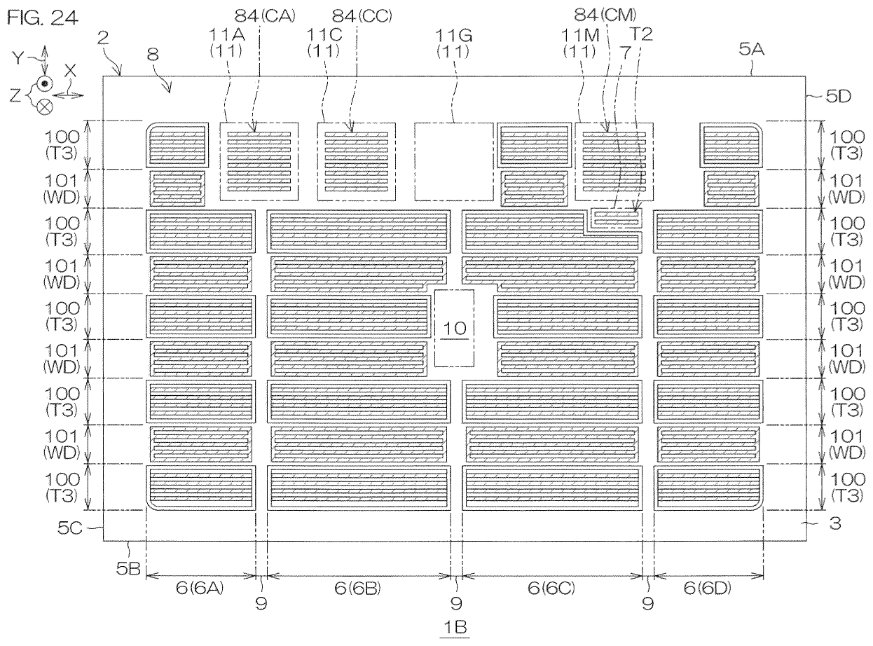

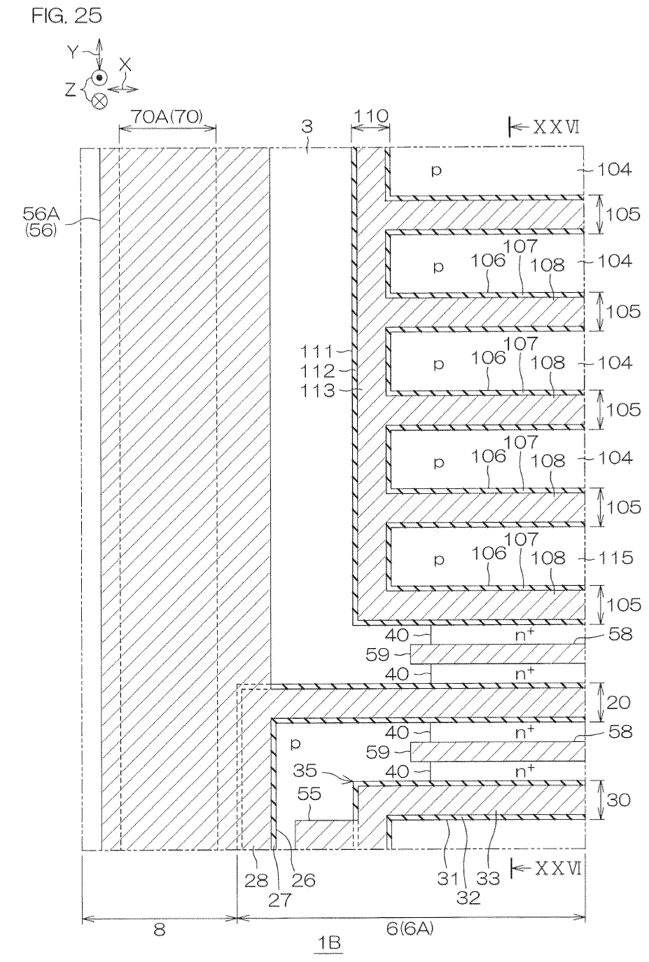

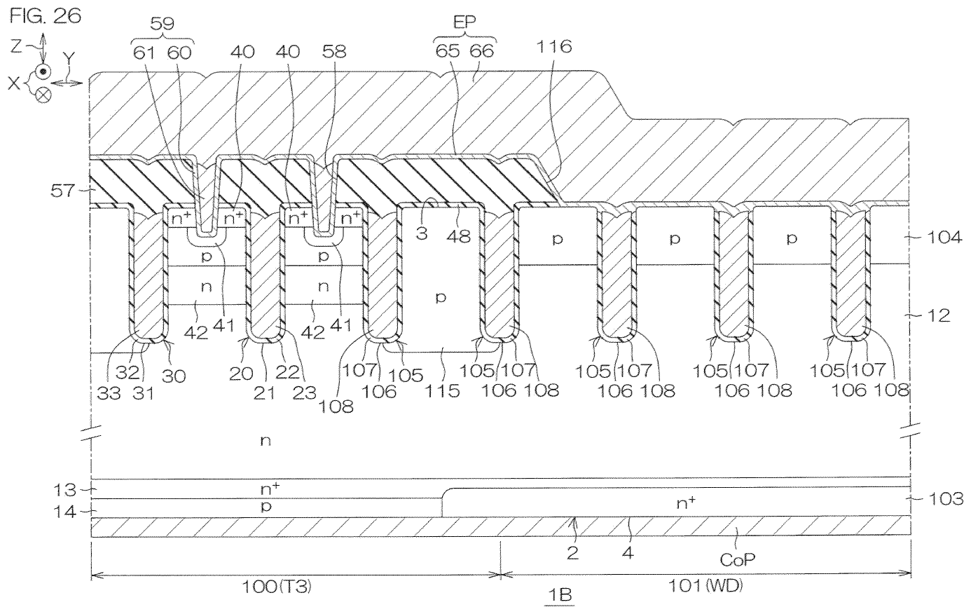

FIG. 24 is a plan view showing a layout example of a first main surface 3 of a semiconductor device 1B according to a second embodiment. FIG. 25 is an enlarged plan view showing a principal portion of an active region 6 of the semiconductor device 1B shown in FIG. 24. FIG. 26 is a sectional view taken along line XXVI-XXVI shown in FIG. 25. The semiconductor device 1B is a semiconductor switching device that includes a main transistor structure T1 as an RC-IGBT (reverse conducting-IGBT) structure having a transistor structure T3 and a free wheeling diode structure WD.

The semiconductor device 1B includes one or a plurality of (in this embodiment, a plurality of) transistor regions 100 respectively provided in the plurality of active regions 6, and one or a plurality of (in this embodiment, a plurality of) free wheeling diode regions 101 respectively provided in the plurality of active regions 6. The plurality of transistor regions 100 are regions each including the above-described transistor structure T3. The plurality of transistor regions 100 are provided at intervals in the second direction Y in the corresponding active region 6.

With respect to the plurality of active regions 6 adjacent to each other, the plurality of transistor regions 100 arranged in one active region 6 respectively face the plurality of transistor regions 100 arranged in the other active region 6 in the first direction X in a one-to-one correspondence. That is, the plurality of transistor regions 100 are arranged in a matrix at intervals in the first direction X and the second direction Y in the first main surface 3.

The plurality of free wheeling diode regions 101 are regions each including the free wheeling diode structure WD. The plurality of free wheeling diode regions 101 are respectively provided in regions adjacent to one or the plurality of transistor regions 100 in the second direction Y in the corresponding active region 6. Specifically, the plurality of free wheeling diode regions 101 and the plurality of transistor regions 100 are alternately arrayed in the second direction Y.

With respect to the plurality of active regions 6 adjacent to each other, the plurality of free wheeling diode regions 101 arranged in one active region 6 respectively face the plurality of free wheeling diode regions 101 arranged in the other active region 6 in the first direction X in a one-to-one correspondence. That is, the plurality of free wheeling diode regions 101 are arranged in a matrix at intervals in the first direction X and the second direction Y in the first main surface 3. As a matter of course, the plurality of free wheeling diode regions 101 may face the plurality of transistor regions 100 in the first direction X.

In each transistor region 100, the semiconductor device 1B includes the base region 15, the plurality of gate structures 20, the plurality of gate connection structures 25, the plurality of emitter structures 30, the plurality of emitter connection structures 35, the plurality of emitter regions 40, the contact region 41, the plurality of storage regions 42, and the plurality of well regions 43.

The layout of these components in the transistor region 100 is similar to the layout of the corresponding components in the active region 6 according to the first embodiment. For the description of the layout of these components in the transistor region 100, the description of the layout of the corresponding components in the active region 6 according to the first embodiment is applied.

The semiconductor device 1B includes a free wheeling cathode region 103 of the n-type formed in the surface layer portion of the second main surface 4 in the free wheeling diode region 101. The free wheeling cathode region 103 has an n-type impurity concentration higher than the n-type impurity concentration of the drift region 12.

The n-type impurity concentration of the free wheeling cathode region 103 may be higher than the n-type impurity concentration of the buffer region 13. In this embodiment, the free wheeling cathode region 103 has a n-type impurity concentration higher than the p-type impurity concentration of the collector region 14, and replaces the conductivity type of the collector region 14 from the p-type to the n-type.

The free wheeling cathode region 103 passes through the collector region 14 and is electrically connected to the drift region 12. In this embodiment, the free wheeling cathode region 103 has an upper end portion positioned within the buffer region 13 and is electrically connected to the drift region 12 via the buffer region 13. The free wheeling cathode region 103 may have an upper end portion that passes through the buffer region 13 and is positioned within the drift region 12.

The semiconductor device 1B includes the free wheeling diode structure WD formed in the first main surface 3 in the free wheeling diode region 101. Hereinafter, the arrangement of on free wheeling diode structure WD as one component of the semiconductor device 1B shall be described.

The free wheeling diode structure WD includes a free wheeling anode region 104 of the p-type formed in the surface layer portion of the first main surface 3 in the free wheeling diode region 101. The free wheeling anode region 104 is formed in a surface layer portion of the drift region 12. In this embodiment, the free wheeling anode region 104 has a p-type impurity concentration higher than the n-type impurity concentration of the drift region 12, and replaces the conductivity type of the drift region 12 from the n-type to the p-type.

The p-type impurity concentration of the free wheeling anode region 104 may be substantially equal to the p-type impurity concentration of the base region 15. As a matter of course, the p-type impurity concentration of the free wheeling anode region 104 may be higher than the p-type impurity concentration of the base region 15, or may be lower than the p-type impurity concentration of the base region 15.

The free wheeling anode region 104 is formed in a layer shape extending along the first main surface 3 in the free wheeling diode region 101, and faces the free wheeling cathode region 103 with the drift region 12 interposed therebetween in the thickness direction. The free wheeling anode region 104 is formed at an interval toward the first main surface 3 side from the depth position of the intermediate portion of the drift region 12.

The free wheeling anode region 104 may have a depth substantially equal to the depth of the base region 15. As a matter of course, the depth of the free wheeling anode region 104 may be larger than the depth of the base region 15, or may be smaller than the depth of the base region 15. The depth of the free wheeling anode region 104 is preferably smaller than the depth of the well region 43. As a matter of course, the depth of the free wheeling anode region 104 may be substantially equal to the depth of the well region 43, or may be larger than the depth of the well region 43.

The free wheeling diode structure WD includes a plurality of anode structures 105 of the trench electrode type formed in the first main surface 3 in the free wheeling diode region 101. The anode potential is to be applied to the plurality of anode structures 105. The plurality of anode structures 105 each extend in a band shape in the first direction X and are arrayed at intervals in the second direction Y in the anode pad region 11A.

That is, the plurality of anode structures 105 are arrayed in a stripe shape extending in the first direction X. The extension direction of the plurality of anode structures 105 coincides with the extension direction of the plurality of gate structures 20. The extension direction of the plurality of anode structures 105 coincides with the extension direction of the plurality of emitter structures 30.

The plurality of anode structures 105 may each have a width less than the width of the plurality of street regions 9. The width of the anode structure 105 is a width in a direction (the second direction Y) orthogonal to the extension direction of the anode structure 105 (the first direction X).

The width of the anode structure 105 may be substantially equal to the width of the gate structure 20 (the gate connection structure 25). As a matter of course, the width of the anode structure 105 may be larger than the width of the gate structure 20 (the gate connection structure 25), or may be smaller than the width of the gate structure 20 (the gate connection structure 25).

The width of the anode structure 105 may be substantially equal to the width of the emitter structure 30 (the emitter connection structure 35). As a matter of course, the width of the anode structure 105 may be larger than the width of the emitter structure 30 (the emitter connection structure 35), or may be smaller than the width of the emitter structure 30 (the emitter connection structure 35).

The width of the anode structure 105 may be not less than 0.5 μm and not more than 5 μm. The width of the anode structure 105 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The width of the anode structure 105 is preferably not less than 1 μm and not more than 2.5 μm.

The plurality of anode structures 105 pass through the free wheeling anode region 104 so as to reach the drift region 12. The plurality of anode structures 105 are each formed at an interval toward the first main surface 3 side from the depth position of the intermediate portion of the drift region 12. The plurality of anode structures 105 face the free wheeling cathode region 103 with a portion of the drift region 12 interposed therebetween in the thickness direction.

The plurality of anode structures 105 may each be formed in a shape tapering toward the bottom wall. As a matter of course, the plurality of anode structures 105 may be formed substantially perpendicular to the first main surface 3. The bottom walls of the plurality of anode structures 105 may each be formed in a shape curved toward the second main surface 4. As a matter of course, the bottom walls of the plurality of anode structures 105 may be formed substantially parallel to the first main surface 3. In this case, bottom wall corner portions of the plurality of anode structures 105 may each be formed in a curved shape.

The plurality of anode structures 105 may have a depth substantially equal to the depth of the plurality of gate structures 20 (the gate connection structures 25). As a matter of course, the depth of the anode structure 105 may be larger than the depth of the gate structure 20 (the gate connection structure 25), or may be smaller than the depth of the gate structure 20 (the gate connection structure 25).

The depth of the anode structure 105 may be substantially equal to the depth of the emitter structure 30 (the emitter connection structure 35). As a matter of course, the depth of the anode structure 105 may be larger than the depth of the emitter structure 30 (the emitter connection structure 35), or may be smaller than the depth of the emitter structure 30 (the emitter connection structure 35).

The depth of the anode structure 105 may be not less than 0.5 μm and not more than 10 μm. The depth of the anode structure 105 may have a value belonging to at least one range among not less than 0.5 μm and not more than 1 μm, not less than 1 μm and not more than 2 μm, not less than 2 μm and not more than 4 μm, not less than 4 μm and not more than 6 μm, not less than 6 μm and not more than 8 μm, and not less than 8 μm and not more than 10 μm. The depth of the anode structure 105 is preferably not less than 4 μm and not more than 8 μm.

A third trench pitch between the central portions of the plurality of anode structures 105 may be substantially equal to the first trench pitch between the central portion of the gate structure 20 and the central portion of the emitter structure 30. As a matter of course, the third trench pitch may be larger than the first trench pitch, or may be smaller than the first trench pitch.

The third trench pitch may be not less than 1 μm and not more than 5 μm. The third trench pitch may have a value belonging to at least one range among not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The third trench pitch is preferably not less than 1.5 μm and not more than 3.5 μm.

The plurality of anode structures 105 each include an anode trench 106, an anode insulating film 107, and an anode embedded electrode 108. The anode trench 106 is formed in the first main surface 3 and demarcates the wall surfaces (side walls and bottom wall) of the anode structure 105.

The anode insulating film 107 may include at least one among a silicon oxide film, a silicon nitride film, and a silicon oxynitride film. The anode insulating film 107 preferably includes the same type of insulator as the gate insulating film 22 (the emitter insulating film 32). In this embodiment, the anode insulating film 107 has a single layer structure constituted of a silicon oxide film. The anode insulating film 107 particularly preferably includes the silicon oxide film constituted of the oxide of the chip 2.

The anode insulating film 107 covers the wall surface of the anode trench 106. The thickness of the anode insulating film 107 may be substantially equal to the thickness of the gate insulating film 22 (the gate connection insulating film 27). As a matter of course, the thickness of the anode insulating film 107 may be larger than the thickness of the gate insulating film 22 (the gate connection insulating film 27), or may be smaller than the thickness of the gate insulating film 22 (the gate connection insulating film 27).

The thickness of the anode insulating film 107 may be substantially equal to the thickness of the emitter insulating film 32 (the emitter connection insulating film 37). As a matter of course, the thickness of the anode insulating film 107 may be larger than the thickness of the emitter insulating film 32 (the emitter connection insulating film 37), or may be smaller than the thickness of the emitter insulating film 32 (the emitter connection insulating film 37).

The thickness of the anode insulating film 107 may be not less than 10 nm and not more than 200 nm. The thickness of the anode insulating film 107 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm. The thickness of the anode insulating film 107 is preferably not less than 100 nm and not more than 150 nm.

The anode embedded electrode 108 is embedded in the anode trench 106 with the anode insulating film 107 interposed therebetween. The anode embedded electrode 108 faces the drift region 12 and the free wheeling anode region 104 with the anode insulating film 107 interposed therebetween.

The electrode surface of the anode embedded electrode 108 may be positioned on the bottom wall side of the anode trench 106 with respect to the first main surface 3. The anode embedded electrode 108 may contain one or both of a conductive polysilicon of the p-type and a conductive polysilicon of the n-type. The anode embedded electrode 108 preferably includes the same type of conductor as the gate embedded electrode 23.

The free wheeling diode structure WD includes a plurality of anode connection structures 110 of the trench electrode type formed in the first main surface 3 so as to be connected to the plurality of anode structures 105. The anode potential is to be applied to the plurality of anode connection structures 110. The anode connection structure 110 may be referred to as a “trench anode connection structure.”

The plurality of anode connection structures 110 are respectively arranged on both end portion sides of the plurality of anode structures 105 so as to be connected to one end portions and the other end portions of the plurality of anode structures 105 in the first direction X, and demarcate the corresponding free wheeling diode region 101 together with the outermost plurality of anode structures 105.

The plurality of anode connection structures 110 include the anode connection structure 110 on one end portion side of the plurality of anode structures 105 and the anode connection structure 110 on the other end portion side of the plurality of anode structures 105 in the first direction X. The anode connection structure 110 on one end portion side extends in a band shape in the second direction Y and is connected to one end portions of the plurality of anode structures 105. The anode connection structure 110 on the other end portion side extends in a band shape in the second direction Y and is connected to the other end portions of the plurality of anode structures 105.

The plurality of anode connection structure 110 may each have a width substantially equal to the width of the anode structure 105 (the gate structure 20). As a matter of course, the width of the anode connection structure 110 may be larger than the width of the anode structure 105, or may be smaller than the width of the anode structure 105.

The width of the anode connection structure 110 may be not less than 0.5 μm and not more than 5 μm. The width of the anode connection structure 110 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The width of the anode connection structure 110 is preferably not less than 1 μm and not more than 2.5 μm.

The plurality of anode connection structures 110 pass through the free wheeling anode region 104 so as to reach the drift region 12. The plurality of anode connection structures 110 are formed at an interval toward the first main surface 3 side from the depth position of the intermediate portion of the drift region 12, and face the free wheeling cathode region 103 with a portion of the drift region 12 interposed therebetween in the thickness direction.

The plurality of anode connection structures 110 may each be formed in a shape tapering toward the bottom wall. As a matter of course, the plurality of anode connection structures 110 may be formed substantially perpendicular to the first main surface 3.

The plurality of anode connection structures 110 may have bottom walls formed in a shape curved toward the second main surface 4. As a matter of course, the bottom walls of the plurality of anode connection structures 110 may be formed substantially parallel to the first main surface 3. In this case, bottom wall corner portions of the plurality of anode connection structures 110 may each be formed in a curved shape.

The plurality of anode connection structure 110 may have a depth substantially equal to the depth of the anode structure 105 (the gate structure 20). As a matter of course, the depth of the anode connection structure 110 may be larger than the depth of the anode structure 105, or may be smaller than the depth of the anode structure 105.

The depth of the anode connection structure 110 may be not less than 0.5 μm and not more than 10 μm. The depth of the anode connection structure 110 may have a value belonging to at least one range among not less than 0.5 μm and not more than 1 μm, not less than 1 μm and not more than 2 μm, not less than 2 μm and not more than 4 μm, not less than 4 μm and not more than 6 μm, not less than 6 μm and not more than 8 μm, and not less than 8 μm and not more than 10 μm. The depth of the anode connection structure 110 is preferably not less than 4 μm and not more than 8 μm.

The plurality of anode connection structures 110 each include an anode connection trench 111, an anode connection insulating film 112, and an anode connection embedded electrode 113. The anode connection trench 111 is formed in the first main surface 3 and demarcates the wall surfaces (side walls and bottom wall) of the anode connection structure 110. The anode connection trench 111 communicates with the plurality of anode trenches 106.

The anode connection insulating film 112 may include at least one among a silicon oxide film, a silicon nitride film, and a silicon oxynitride film. The anode connection insulating film 112 preferably includes the same type of insulator as the anode insulating film 107 (the gate insulating film 22). In this embodiment, the anode connection insulating film 112 has a single layer structure constituted of a silicon oxide film. The anode connection insulating film 112 particularly preferably includes the silicon oxide film constituted of the oxide of the chip 2.

The anode connection insulating film 112 covers the wall surfaces of the anode connection trench 111 in a film shape. The anode connection insulating film 112 is connected to the anode insulating film 107 at a communication portion of the anode trench 106 and the anode connection trench 111.

The anode connection insulating film 112 may have a thickness substantially equal to the thickness of the anode insulating film 107. As a matter of course, the thickness of the anode connection insulating film 112 may be larger than the thickness of the anode insulating film 107, or may be smaller than the thickness of the anode insulating film 107.

The anode connection insulating film 112 may have a thickness of not less than 10 nm and not more than 200 nm. The thickness of the anode connection insulating film 112 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm. The thickness of the anode connection insulating film 112 is preferably not less than 100 nm and not more than 150 nm.

The anode connection embedded electrode 113 is embedded in the anode connection trench 111 with the anode connection insulating film 112 interposed therebetween. The anode connection embedded electrode 113 is connected to the anode embedded electrode 108 at a communication portion of the anode trench 106 and the anode connection trench 111.

The anode connection embedded electrode 113 faces the drift region 12 and the free wheeling anode region 104 with the anode connection insulating film 112 interposed therebetween. The anode connection embedded electrode 113 is partially covered with the interlayer film 57.

The electrode surface of the anode connection embedded electrode 113 may be positioned on the bottom wall side of the anode connection trench 111 with respect to the first main surface 3. The anode connection embedded electrode 113 may contain one or both of a conductive polysilicon of the p-type and a conductive polysilicon of the n-type. The anode connection embedded electrode 113 preferably includes the same type of conductor as the anode embedded electrode 108.

The free wheeling diode structure WD includes a boundary well region 115 of the p-type formed in the surface layer portion of the first main surface 3 in the free wheeling diode region 101. The boundary well region 115 may have a p-type impurity concentration higher than the p-type impurity concentration of the base region 15.

As a matter of course, the p-type impurity concentration of the boundary well region 115 may be lower than the p-type impurity concentration of the base region 15. The p-type impurity concentration of the boundary well region 115 may be substantially equal to the p-type impurity concentration of the well region 43. In this embodiment, the boundary well region 115 is formed to be in an electrically floating state.

The boundary well region 115 is formed in a region between a pair of anode structures 105 adjacent to the transistor region 100 among the plurality of anode structures 105. Specifically, the boundary well region 115 is formed in a mesa region demarcated by a pair of anode structures 105 and a pair of anode connection structures 110.

Each boundary well region 115 has a bottom portion positioned on the bottom wall side of the plurality of anode structures 105 with respect to the depth position of the bottom portion of the base region 15. The bottom portions of the plurality of anode regions 51 are each positioned further to the bottom wall side of the plurality of anode structures 105 than depth positions of intermediate portions of the plurality of anode structures 105. In this embodiment, the bottom portion of the boundary well region 115 is positioned on the second main surface 4 side with respect to the bottom walls of the plurality of anode structures 105.

The boundary well region 115 extends in a band shape in the first direction X in conformance to the extension direction of the plurality of anode structures 105, and is connected to the plurality of anode structures 105 and the plurality of anode connection structures 110. The boundary well region 115 may have a portion (bottom portion) covering the bottom walls of the plurality of anode structures 105 and the bottom walls of the plurality of anode connection structures 110.

The semiconductor device 1B includes the above-described main surface insulating film 48 that selectively covers the first main surface 3 in the free wheeling diode region 101. The main surface insulating film 48 covers the free wheeling anode region 104 and the boundary well region 115 in the free wheeling diode region 101. The main surface insulating film 48 is connected to the anode insulating film 107 and the anode connection insulating film 112 in the free wheeling diode region 101, and exposes the anode embedded electrode 108 and the anode connection embedded electrode 113.

The main surface insulating film 48 may have a thickness substantially equal to the thickness of the anode insulating film 107 (the anode connection embedded electrode 113). As a matter of course, the thickness of the main surface insulating film 48 may be larger than the thickness of the anode insulating film 107 (the anode connection embedded electrode 113), or may be smaller than the thickness of the anode insulating film 107 (the anode connection embedded electrode 113).

The semiconductor device 1B includes the above-described interlayer film 57 that selectively covers the main surface insulating film 48 in the free wheeling diode region 101. The interlayer film 57 covers the free wheeling anode region 104 and the boundary well region 115 with the main surface insulating film 48 interposed therebetween in the free wheeling diode region 101. The interlayer film 57 selectively covers the plurality of anode structures 105 and the plurality of anode connection structures 110.

In this embodiment, the interlayer film 57 enters the plurality of anode trenches 106 and the plurality of anode connection trenches 111 from above the main surface insulating film 48. The interlayer film 57 has a portion covering the electrode surfaces of the plurality of anode embedded electrodes 108 in the plurality of anode trenches 106. The interlayer film 57 has a portion covering the electrode surfaces of the plurality of anode connection embedded electrodes 113 in the plurality of anode connection trenches 111.

The semiconductor device 1B includes a diode opening 116 formed in the interlayer film 57 in the free wheeling diode region 101. In this embodiment, the diode opening 116 exposes an inner portion of the anode region 51 and an inner portions of the plurality of anode structures 105.

The diode opening 116 exposes the entire anode structure 105. The above-described emitter pad EP enters the diode opening 116 from above the interlayer film 57 and is mechanically and electrically connected to the anode region 51 and the plurality of anode structures 105 in the diode opening 116.

In this embodiment, an example is shown in which the plurality of anode structures 105 and the plurality of anode connection structures 110 are formed, but the plurality of anode structures 105 and the plurality of anode connection structures 110 are not necessarily required and may be removed.

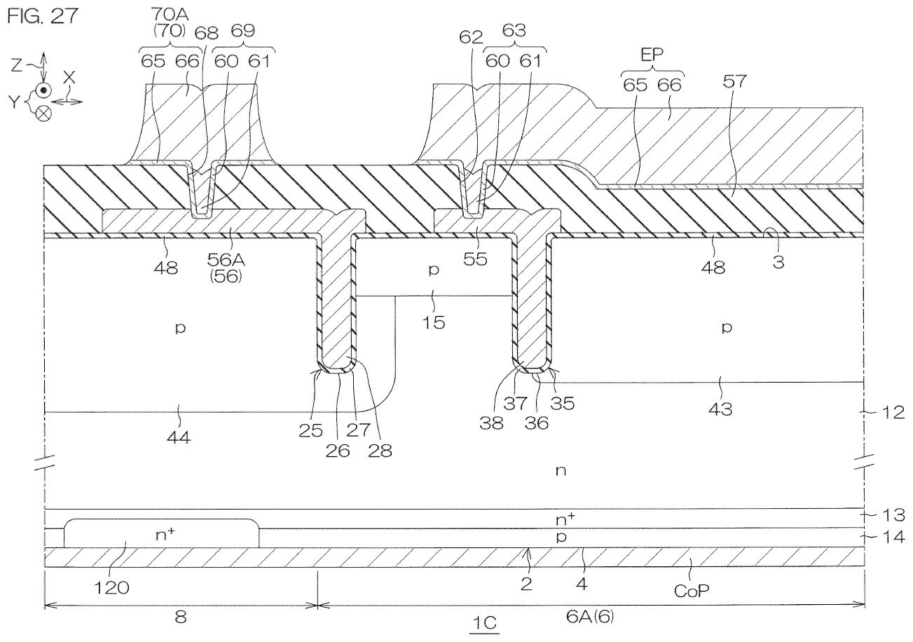

FIG. 27 is a sectional view showing a principal portion of a semiconductor device 1C according to a third embodiment. The semiconductor device 1C is a semiconductor switching device that includes the main transistor structure T1 as an RC-IGBT structure having the transistor structure T3 and the free wheeling diode structure WD. The arrangement of the semiconductor device 1C may be combined with the semiconductor device 1B.

The semiconductor device 1C includes an outer peripheral cathode region 120 of the n-type formed in the surface layer portion of the second main surface 4 around the plurality of active regions 6. The outer peripheral cathode region 120 has an n-type impurity concentration higher than the n-type impurity concentration of the drift region 12.

The n-type impurity concentration of the outer peripheral cathode region 120 may be higher than the n-type impurity concentration of the buffer region 13. In this embodiment, the outer peripheral cathode region 120 has a n-type impurity concentration higher than the p-type impurity concentration of the collector region 14, and replaces the conductivity type of the collector region 14 from the p-type to the n-type.

The outer peripheral cathode region 120 is formed in a region facing the outer peripheral well region 44 in the thickness direction of the chip 2 in the surface layer portion of the second main surface 4. Preferably, the outer peripheral cathode region 120 is formed to be narrower than the outer peripheral well region 44, and faces the outer peripheral well region 44 at an interval inward from both ends of the outer peripheral well region 44. That is, the entire region of the outer peripheral cathode region 120 preferably faces the outer peripheral well region 44 in the thickness direction in sectional view.

The outer peripheral cathode region 120 passes through the collector region 14 and is electrically connected to the drift region 12. In this embodiment, the outer peripheral cathode region 120 has an upper end portion positioned within the buffer region 13 and is electrically connected to the drift region 12 via the buffer region 13. The outer peripheral cathode region 120 may have an upper end portion that passes through the buffer region 13 and is positioned within the drift region 12.

The outer peripheral cathode region 120 extends in a band shape along the peripheral edge of the first main surface 3 at an interval inward from the peripheral edge of the first main surface 3. In this embodiment, the outer peripheral cathode region 120 extends in a band shape in the extension direction of the outer peripheral well region 44 in plan view. The outer peripheral cathode region 120 may be formed in an annular shape surrounding the plurality of active regions 6.

As described above, the semiconductor device 1C may include the free wheeling diode structure WD including the outer peripheral well region 44 as the anode and the outer peripheral cathode region 120 as the cathode.

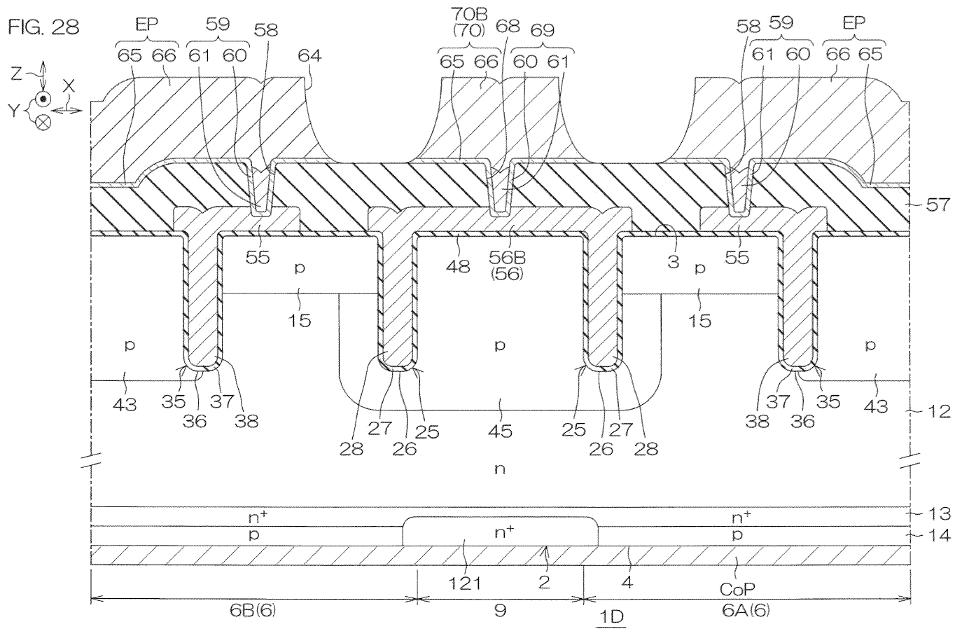

FIG. 28 is a sectional view showing a principal portion of a semiconductor device 1D according to a fourth embodiment. The semiconductor device 1D is a semiconductor switching device that includes the main transistor structure T1 as an RC-IGBT structure having the transistor structure T3 and the free wheeling diode structure WD. The arrangement of the semiconductor device 1D may be combined with the semiconductor device 1B, and the semiconductor device 1C.

The semiconductor device 1D includes a street cathode region 121 of the n-type formed in the surface layer portion of the second main surface 4 in the street region 9. The street cathode region 121 has an n-type impurity concentration higher than the n-type impurity concentration of the drift region 12.

The n-type impurity concentration of the street cathode region 121 may be higher than the n-type impurity concentration of the buffer region 13. In this embodiment, the street cathode region 121 has a n-type impurity concentration higher than the p-type impurity concentration of the collector region 14, and replaces the conductivity type of the collector region 14 from the p-type to the n-type.

The street cathode region 121 is formed in a region facing the street well region 45 in the thickness direction of the chip 2 in the surface layer portion of the second main surface 4. Preferably, the street cathode region 121 is formed to be narrower than the street well region 45, and faces the street well region 45 at an interval inward from both ends of the street well region 45.

The street cathode region 121 is preferably formed at an interval from the plurality of active regions 6. That is, it is preferable that the street cathode region 121 is formed at an interval toward the inner side of the street region 9 from the plurality of gate structures 20 and the plurality of gate connection structures 25. That is, the entire region of the street cathode region 121 preferably faces the street well region 45 in the thickness direction in sectional view.

As a matter of course, the street cathode region 121 may have a width larger than the width of the street region 9 and have a portion led out from the street region 9 into the plurality of active regions 6. In this case, the street cathode region 121 may face the plurality of gate structures 20 and the plurality of gate connection structures 25 in the thickness direction. The street cathode region 121 is formed in a band shape extending in the second direction Y in conformance to the extension direction of the street region 9.

The street cathode region 121 passes through the collector region 14 and is electrically connected to the drift region 12. In this embodiment, the street cathode region 121 has an upper end portion positioned within the buffer region 13 and is electrically connected to the drift region 12 via the buffer region 13. The street cathode region 121 may have an upper end portion that passes through the buffer region 13 and is positioned within the drift region 12.

As described above, the semiconductor device 1D may include the free wheeling diode structure WD including the street well region 45 as the anode and the street cathode region 121 as the cathode.

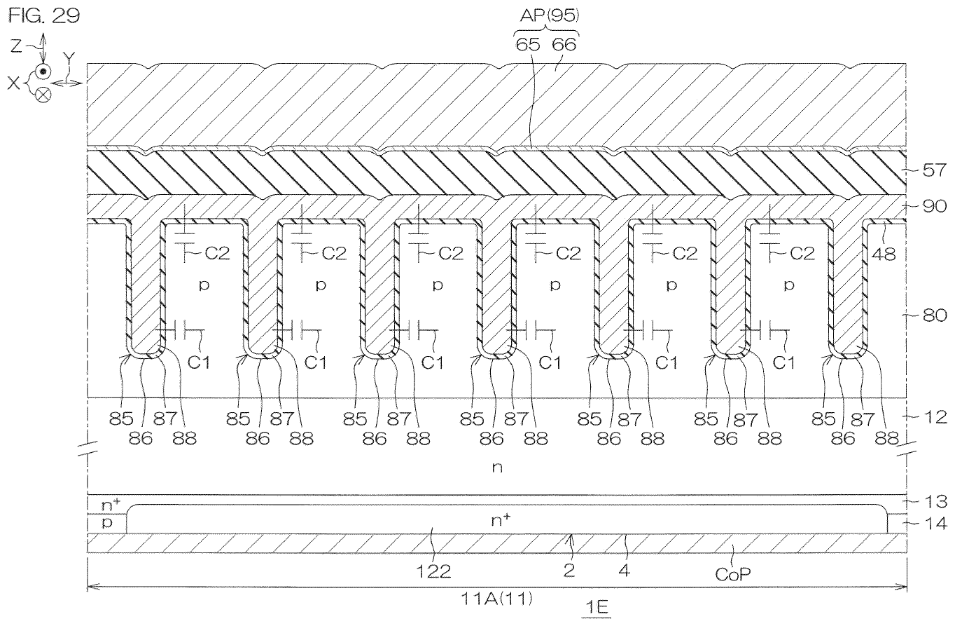

FIG. 29 is a sectional view showing a principal portion of a semiconductor device 1E according to a fifth embodiment. The semiconductor device 1E is a semiconductor switching device that includes the main transistor structure T1 as an RC-IGBT structure having the transistor structure T3 and the free wheeling diode structure WD. The arrangement of the semiconductor device 1E may be combined with the semiconductor device 1B, the semiconductor device 1C, and the semiconductor device 1D.

The semiconductor device 1E includes a pad cathode region 122 of the n-type formed in the surface layer portion of the second main surface 4 in one or a plurality of pad regions 11. FIG. 29 shows an example in which the pad cathode region 122 is formed in the anode pad region 11A. As a matter of course, the pad cathode region 122 may be formed in at least one of the gate pad region 11G, the monitor pad region 11M, and the cathode pad region 11C.

The pad cathode region 122 has an n-type impurity concentration higher than the n-type impurity concentration of the drift region 12. The n-type impurity concentration of the pad cathode region 122 may be higher than the n-type impurity concentration of the buffer region 13. In this embodiment, the pad cathode region 122 has a n-type impurity concentration higher than the p-type impurity concentration of the collector region 14, and replaces the conductivity type of the collector region 14 from the p-type to the n-type.

The pad cathode region 122 is formed in a region facing the pad well region 80 in the thickness direction of the chip 2 in the surface layer portion of the second main surface 4. In this embodiment, the pad cathode region 122 faces the pad well region 80 and the plurality of capacitor structures 85 in the thickness direction.

The pad cathode region 122 may be formed in the entire region of the corresponding pad region 11, or may be partially formed in a portion of the corresponding pad region 11. The pad cathode region 122 may face all of the capacitor structures 85, or may face some of the capacitor structures 85. The pad cathode region 122 may face the entire region of the plurality of capacitor structures 85, or may partially face some of the plurality of capacitor structures 85.

The pad cathode region 122 passes through the collector region 14 and is electrically connected to the drift region 12. In this embodiment, the pad cathode region 122 has an upper end portion positioned within the buffer region 13 and is electrically connected to the drift region 12 via the buffer region 13. The pad cathode region 122 may have an upper end portion that passes through the buffer region 13 and is positioned within the drift region 12.

As described above, the semiconductor device 1E may include the free wheeling diode structure WD including the pad well region 80 as the anode and the pad cathode region 122 as the cathode.

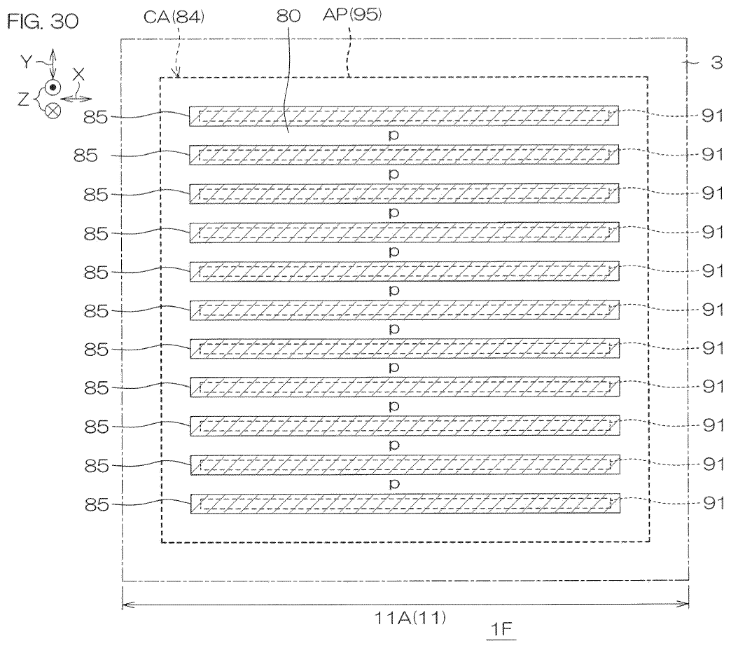

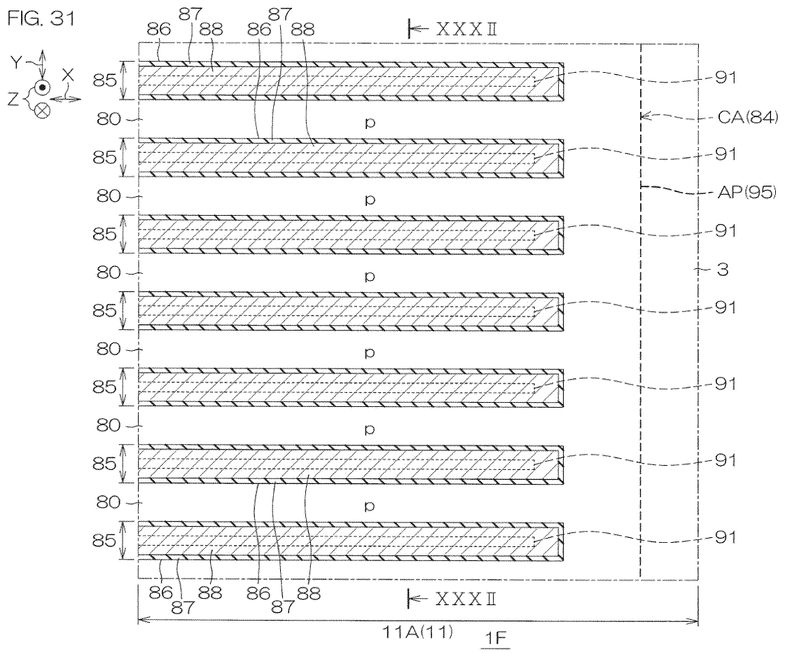

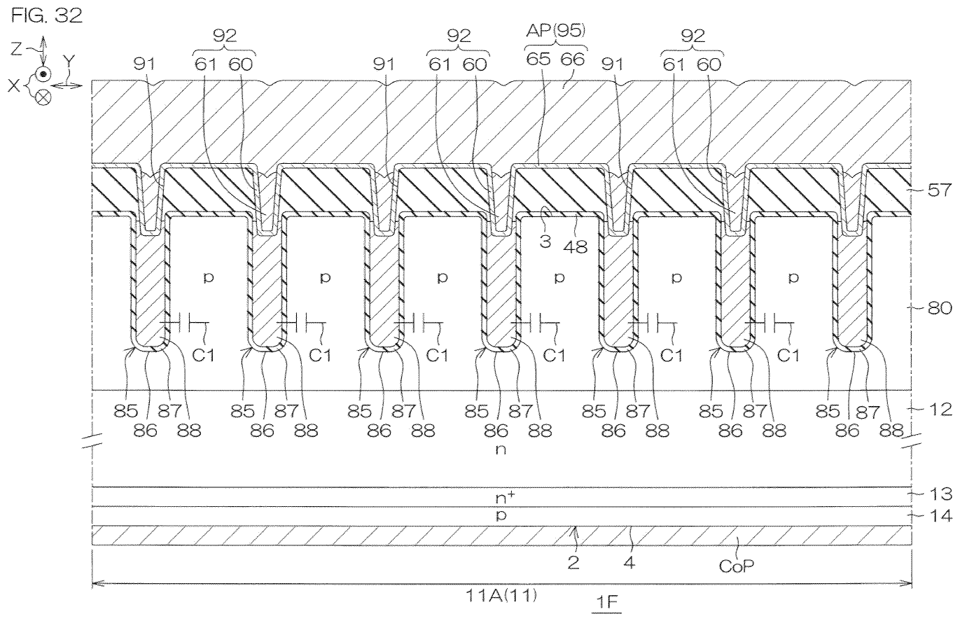

FIG. 30 is a plan view showing a pad region 11 of a semiconductor device 1F according to a sixth embodiment. FIG. 31 is an enlarged plan view showing a principal portion of the pad region 11 shown in FIG. 30. FIG. 32 is a sectional view taken along line XXXII-XXXII shown in FIG. 31.

Referring to FIG. 30 to FIG. 32, the semiconductor device 1F has a form in which the plurality of pad capacitor structures 84 (the monitor capacitor structure CM, the anode capacitor structure CA, and the cathode capacitor structure CC) according to the semiconductor device 1A are modified. The pad capacitor structure 84 according to the semiconductor device 1F is also applicable to the semiconductor devices 1B to 1D.

The plurality of pad capacitor structures 84 have the same arrangement. Hereinafter, the arrangement of the anode capacitor structure CA shall be described as an example of the pad capacitor structure 84. The arrangement of the monitor capacitor structure CM is obtained by replacing the “anode capacitor structure CA” with the “monitor capacitor structure CM” and replacing the “anode pad region 11A” with the “monitor pad region 11M” in the following description.

The arrangement of the cathode capacitor structure CC is obtained by replacing the “anode capacitor structure CA” with the “cathode capacitor structure CC” and replacing the “anode pad region 11A” with the “cathode pad region 11C” in the following description.

As in the case of the semiconductor device 1A, the anode capacitor structure CA includes the plurality of capacitor structures 85 according to the first layout example. The anode capacitor structure CA may have at least one of the capacitor structures 85 (see FIG. 18A to FIG. 18R) according to the second to nineteenth layout examples.

In this embodiment, the plurality of capacitor embedded electrodes 88 are embedded in the plurality of capacitor trenches 86 so as to be exposed from the openings of the plurality of capacitor trenches 86. The plurality of capacitor embedded electrodes 88 may each have an electrode surface positioned on the bottom wall side of the plurality of capacitor trenches 86 with respect to the height position of the first main surface 3.

In this embodiment, the anode capacitor structure CA does not have the capacitor electrode film 90. In this embodiment, the anode capacitor structure CA includes the above-described interlayer film 57 directly covering the plurality of capacitor structures 85 in the anode pad region 11A. The interlayer film 57 has a portion covering the electrode surfaces of the plurality of capacitor embedded electrodes 88 in the plurality of capacitor trenches 86.

The semiconductor device 1F includes one or a plurality of (in this embodiment, a plurality of) the pad openings 91 formed in the interlayer film 57 in the anode pad region 11A. The plurality of pad openings 91 pass through the interlayer film 57 and respectively expose the plurality of capacitor structures 85. In this embodiment, the plurality of pad openings 91 are respectively formed in a one-to-one correspondence with respect to the plurality of capacitor structures 85, and each extend in a band shape in conformance to the extension direction of the corresponding capacitor structures 85 (in this embodiment, the first direction X).

As a matter of course, the plurality of pad openings 91 may be formed at intervals in conformance to the extension direction of the corresponding capacitor structures 85. In this case, the plurality of pad openings 91 may be arrayed in a matrix at intervals in the first direction X and the second direction Y. In this case, the plurality of pad openings 91 may each be formed in a polygonal shape (a quadrangular shape, a hexagonal shape, etc.) or a circular shape in plan view.

The plurality of pad openings 91 are formed to be narrower than the corresponding capacitor structure 85, and expose an inner portion of the corresponding capacitor structure 85 at an interval inward from the side wall of the corresponding capacitor structure 85. In other words, the plurality of pad openings 91 are formed to be narrower than the corresponding capacitor trench 86, and expose an inner portion of the corresponding capacitor embedded electrode 88 at an interval inward from the side wall of the corresponding capacitor trench 86.

That is, the plurality of pad openings 91 expose only the corresponding capacitor structures 85 (the capacitor embedded electrodes 88), and do not expose the first main surface 3 (the chip 2) and the main surface insulating film 48. The plurality of pad openings 91 respectively have a portion positioned above the height position of the first main surface 3 and a portion positioned on the bottom wall side of the corresponding capacitor structure 85 (the capacitor trench 86) with respect to the height position of the first main surface 3.

In this embodiment, the plurality of pad openings 91 are further dug in from the electrode surface of the corresponding capacitor embedded electrode 88 toward the bottom wall side of the corresponding capacitor trench 86 and have a bottom wall positioned in the capacitor embedded electrode 88. The bottom walls of the plurality of pad openings 91 are preferably formed at an interval toward the opening side of the capacitor structure 85 (the capacitor trench 86) from the depth position of an intermediate portion of the corresponding capacitor structure 85 (the capacitor trench 86).

The anode capacitor structure CA includes a plurality of pad via electrodes 92 embedded in the plurality of pad openings 91 in the anode pad region 11A. In this embodiment, the plurality of pad via electrodes 92 each extend in a band shape in conformance to the extension direction of the corresponding pad opening 91 (in this embodiment, the first direction X).

As a matter of course, when the plurality of pad openings 91 are formed at intervals in conformance to the extension direction of the corresponding capacitor structures 85, the plurality of pad via electrodes 92 may be arrayed at intervals in the extension direction of the corresponding capacitor structures 85.

The plurality of pad via electrodes 92 each have a portion in contact with the interlayer film 57 and the corresponding capacitor embedded electrode 88 in the corresponding pad opening 91. The plurality of pad via electrodes 92 are mechanically and electrically connected to the corresponding capacitor embedded electrodes 88 in the plurality of pad openings 91.

The plurality of pad via electrodes 92 each have a portion positioned above the height position of the first main surface 3 in the thickness direction and a portion positioned on the bottom wall side of the corresponding capacitor structure 85 (the capacitor trench 86) with respect to the height position of the first main surface 3.

That is, the plurality of pad via electrodes 92 have a portion facing the chip 2 with the capacitor insulating film 87 and the capacitor embedded electrode 88 corresponding in the horizontal direction in the corresponding capacitor trench 86 interposed therebetween. In this embodiment, the plurality of pad via electrodes 92 face the pad well region 80 with the capacitor insulating film 87 and the capacitor embedded electrode 88 interposed therebetween.

Each of the pad via electrode 92 may have a laminated structure including the first electrode 60 and the second electrode 61 that are laminated in that order from the wall surface side of the corresponding pad opening 91. The first electrode 60 is formed as a barrier electrode in a film shape on the wall surface of the pad opening 91. The first electrode 60 is mechanically and electrically connected to the capacitor embedded electrode 88 in the corresponding pad opening 91.

The first electrode 60 may have a single layer structure that includes a titanium film or a titanium nitride film. The first electrode 60 may have a laminated structure that includes a titanium film and a titanium nitride film. In this case, the titanium nitride film may be laminated on the titanium film.

The second electrode 61 is embedded in the corresponding pad opening 91 with the first electrode 60 interposed therebetween, and is electrically connected to the capacitor embedded electrode 88 via the first electrode 60. The second electrode 61 may include at least one of a tungsten film, a molybdenum film, a nickel film, a pure aluminum film, a pure copper film, an AlCu alloy film, an AlSi alloy film, and an AlSiCu alloy film. The second electrode 61 preferably includes a tungsten film.

In this embodiment, the anode pad AP collectively covers the plurality of capacitor structures 85 in plan view, and has a peripheral edge (electrode side wall) surrounding the plurality of capacitor structures 85. The anode pad AP is mechanically and electrically connected to the plurality of pad via electrodes 92 on the interlayer film 57, and is electrically connected to the plurality of capacitor structures 85 (the capacitor embedded electrodes 88) via the plurality of pad via electrodes 92.

As described above, the semiconductor device 1F may include the chip 2, the active region 6, the pad region 11, the transistor structure T3 of the insulated gate type, and the capacitor structure 85 of the trench electrode type. The chip 2 has the first main surface 3. The active region 6 is provided in the first main surface 3. The pad region 11 is provided outside the active region 6 in the first main surface 3.

The transistor structure T3 is formed in the first main surface 3 in the active region 6. The capacitor structure 85 is formed in the first main surface 3 in the pad region 11 and forms capacitive coupling with the chip 2. According to this arrangement, the semiconductor device 1F capable of improving electrical characteristics is provided. Specifically, according to the semiconductor device 1F, as a result of an increase in the capacitance value of the pad region 11 by the capacitor structure 85, the ESD tolerance is improved.

The transistor structure T3 may include the gate structure 20 of the trench electrode type to which a gate potential is to be applied. In this case, a potential other than the gate potential may be applied to the capacitor structure 85. According to this arrangement, the capacitance value of the pad region 11 can be improved by the capacitor structure 85 to which the potential other than the gate potential is to be applied.

The capacitor structure 85 may have a depth equal to the depth of the gate structure 20. According to this arrangement, the capacitance value of the pad region 11 is increased by the capacitor structure 85 having a depth equal to the depth of the gate structure 20. In this case, the capacitor structure 85 can be manufactured simultaneously with the gate structure 20.

The transistor structure T3 may include the emitter structure 30 of the trench electrode type to which an emitter potential is to be applied. In this case, a potential other than the emitter potential may be applied to the capacitor structure 85. According to this arrangement, the capacitance value of the pad region 11 can be improved by the capacitor structure 85 to which the potential other than the emitter potential is to be applied.

The capacitor structure 85 may have a depth equal to the depth of the emitter structure 30. According to this arrangement, the capacitance value of the pad region 11 is increased by the capacitor structure 85 having a depth equal to the depth of the emitter structure 30. In this case, the capacitor structure 85 can be manufactured simultaneously with the emitter structure 30.

The semiconductor device 1F may include the monitor region 7 and the monitor transistor structure T2 for current monitoring. The monitor region 7 may be provided outside the active region 6 in the first main surface 3.

The monitor transistor structure T2 may be formed in the first main surface 3 in the monitor region 7. In this case, a potential for the monitor transistor structure T2 may be applied to the capacitor structure 85. According to this arrangement, the capacitance value of the pad region 11 can be improved by the capacitor structure 85 to which a potential with respect to the monitor transistor structure T2 is to be applied.

The semiconductor device 1F may include the monitor electrode 67. The monitor electrode 67 may be electrically connected to the monitor transistor structure T2 on the first main surface 3 in the monitor region 7. In this case, the capacitor structure 85 may be electrically connected to the monitor electrode 67.

The semiconductor device 1F may include the temperature detecting region 10 as the diode region and the temperature sensitive diode structure D as the diode structure. The temperature detecting region 10 may be provided outside the active region 6 in the first main surface 3. The temperature sensitive diode structure D may be formed in the first main surface 3 in the temperature detecting region 10.

In this case, a potential for the temperature sensitive diode structure D may be applied to the capacitor structure 85. According to this arrangement, the capacitance value of the pad region 11 can be improved by the capacitor structure 85 to which a potential with respect to the temperature sensitive diode structure D is to be applied.

The semiconductor device 1F may include the anode wiring 75. The anode wiring 75 may be electrically connected to the temperature sensitive diode structure D on the first main surface 3. In this case, the capacitor structure 85 may be electrically connected to the anode wiring 75. According to this arrangement, the capacitance value of the pad region 11 can be improved by the capacitor structure 85 to which the anode potential is to be applied.

The semiconductor device 1F may include the cathode wiring 76. The cathode wiring 76 may be electrically connected to the temperature sensitive diode structure D on the first main surface 3. In this case, the capacitor structure 85 may be electrically connected to the cathode wiring 76. According to this arrangement, the capacitance value of the pad region 11 can be improved by the capacitor structure 85 to which the cathode potential is to be applied.

The semiconductor device 1F may include the interlayer film 57 with an insulating property, the pad via electrode 92, and the pad electrode 95. The interlayer film 57 may cover the capacitor structure 85. The pad via electrode 92 may be embedded in the interlayer film 57 so as to be electrically connected to the capacitor structure 85.

The pad electrode 95 may be arranged on the interlayer film 57 and electrically connected to the capacitor structure 85 via the pad via electrode 92. According to this arrangement, it is possible to appropriately electrically connect the pad electrode 95 to the capacitor structure 85 while suppressing the contact of the pad electrode 95 with another structure.

In this case, the pad via electrode 92 may be connected to the capacitor structure 85 in a region further to the bottom wall of the capacitor structure 85 than the height position of the first main surface 3. According to this arrangement, the pad via electrode 92 can be appropriately mechanically and electrically connected to the capacitor structure 85.

The capacitor structure 85 may include the capacitor trench 86, the capacitor insulating film 87 (capacitance insulating film), and the capacitor embedded electrode 88. The capacitor trench 86 may be formed in the first main surface 3. The capacitor insulating film 87 may cover the wall surface of the capacitor trench 86.

The capacitor embedded electrode 88 may form capacitive coupling with the chip 2 via the capacitor insulating film 87 in the capacitor trench 86. According to this structure, the capacitance value of the capacitor structure 85 can be adjusted by the film thickness of the capacitor insulating film 87. The capacitor insulating film 87 may have a thickness of not less than 10 nm and not more than 200 nm.

In this case, the semiconductor device 1F may include the interlayer film 57, the pad via electrode 92, and the pad electrode 95. The interlayer film 57 may cover the capacitor structure 85. The pad via electrode 92 may be embedded in the interlayer film 57 so as to be electrically connected to the capacitor embedded electrode 88.

The pad electrode 95 may be arranged on the interlayer film 57 and electrically connected to the capacitor embedded electrode 88 via the pad via electrode 92. According to this arrangement, it is possible to appropriately electrically connect the pad electrode 95 to the capacitor embedded electrode 88 while suppressing the contact of the pad electrode 95 with another structure.

The capacitor embedded electrode 88 may have an electrode surface positioned on the bottom wall side of the capacitor trench 86 with respect to the height position of the first main surface 3. The interlayer film 57 has a portion covering the electrode surface of the capacitor embedded electrode 88 in the capacitor trench 86.

The pad via electrode 92 may be mechanically and electrically connected to the capacitor embedded electrode 88 in the capacitor trench 86. According to this arrangement, the pad via electrode 92 can be appropriately mechanically and electrically connected to the capacitor embedded electrode 88.

The semiconductor device 1F may include the main surface insulating film 48. The main surface insulating film 48 may cover the first main surface 3 in the pad region 11 so as to be connected to the capacitor insulating film 87. In this case, the interlayer film 57 may cover the main surface insulating film 48.

The semiconductor device 1F may include the drift region 12 of the n-type (first conductivity type) and the pad well region 80 of a p-type (second conductivity type). The drift region 12 may be formed in the chip 2 in the pad region 11. The pad well region 80 may be formed in the surface layer portion of the first main surface 3 in the pad region 11 and electrically connected to the drift region 12.

In this case, the capacitor structure 85 may be arranged in the pad well region 80 and form capacitive coupling with the pad well region 80. According to this arrangement, the capacitance value of the pad region 11 can be increased by the capacitor structure 85 that forms capacitive coupling with the pad well region 80.

The capacitor structure 85 may be positioned in the pad well region 80 at an interval toward the first main surface 3 side from the bottom portion of the pad well region 80. According to this arrangement, the capacitor structure 85 can form capacitive coupling with the pad well region 80 over the entire region in the thickness direction.

The semiconductor device 1F may include the p-type base region 15. The base region 15 may be formed in the surface layer portion of the first main surface 3 in the active region 6 and electrically connected to the drift region 12. In this case, the pad well region 80 may be formed deeper than the base region 15. According to this arrangement, the capacitance value of the pad region 11 can be increased by the capacitor structure 85 that forms capacitive coupling with the pad well region 80 that is deeper than the base region 15.

From another viewpoint, the semiconductor device 1F may include the chip 2, the active region 6, the pad region 11, the transistor structure T3 of the insulated gate type, the capacitor trench 86, the capacitor insulating film 87 (insulating film), and the capacitor embedded electrode 88. The chip 2 may have the first main surface 3. The active region 6 may be provided in the first main surface 3. The pad region 11 may be provided outside the active region 6 in the first main surface 3. The transistor structure T3 may be formed in the active region 6.

The capacitor trench 86 may be formed in the first main surface 3 in the pad region 11. The capacitor insulating film 87 may cover the wall surface of the capacitor trench 86. The capacitor embedded electrode 88 may form capacitive coupling with the chip 2 via the capacitor insulating film 87 in the capacitor trench 86. A potential other than the gate potential may be applied to the capacitor embedded electrode 88.

According to this arrangement, the semiconductor device 1F capable of improving electrical characteristics is provided. Specifically, according to the semiconductor device 1F, as a result of an increase in the capacitance value of the pad region 11 by the capacitor embedded electrode 88 to which the potential other than the gate potential is to be applied, the ESD tolerance is improved. The capacitor insulating film 87 may have a thickness of not less than 10 nm and not more than 200 nm.

The semiconductor device 1F may include the p-type pad well region 80. The pad well region 80 may be formed in the surface layer portion of the first main surface 3 in the pad region 11. In this case, the capacitor embedded electrode 88 may form capacitive coupling with the pad well region 80 via the capacitor insulating film 87. According to this arrangement, the capacitance value of the pad region 11 can be increased by the capacitor embedded electrode 88 that forms capacitive coupling with the pad well region 80.

The semiconductor device 1F may include the p-type base region 15. The base region 15 may be formed in the surface layer portion of the first main surface 3 in the active region 6. In this case, the pad well region 80 may be formed deeper than the base region 15. According to this arrangement, the capacitance value of the pad region 11 can be increased by the capacitor embedded electrode 88 that forms capacitive coupling with the pad well region 80 that is deeper than the base region 15.

The semiconductor device 1F may include the gate trench 21, the gate insulating film 22, and the gate embedded electrode 23. The gate trench 21 may be formed in the first main surface 3 in the active region 6. The gate insulating film 22 may cover the wall surfaces of the gate trench 21. The gate embedded electrode 23 may be embedded in the gate trench 21 with the gate insulating film 22 interposed therebetween.

The gate insulating film 22 may have a thickness of not less than 10 nm and not more than 200 nm. The semiconductor device 1F may include the main surface insulating film 48 covering the first main surface 3. The main surface insulating film 48 may be connected to the gate insulating film 22 and the capacitor insulating film 87.

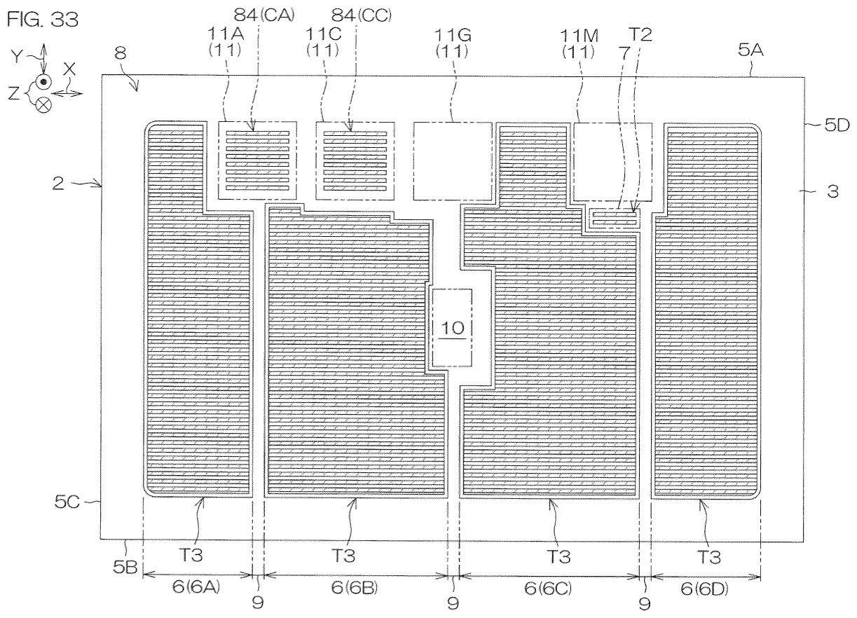

Hereinafter, modification examples applied to the semiconductor devices 1A to 1F according to the first to sixth embodiments shall be illustrated. FIG. 33 to FIG. 36 are plan views showing first to fourth modification examples of the semiconductor devices 1A to 1F according to the first to sixth embodiments. The semiconductor devices 1A to 1F according to the first to sixth embodiments may have at least one of the arrangements according to the first to fourth modification examples. As a matter of course, the semiconductor devices 1A to 1F according to the first to sixth embodiments may have an arrangement in which at least two of the arrangements according to the first to fourth modification examples are combined.

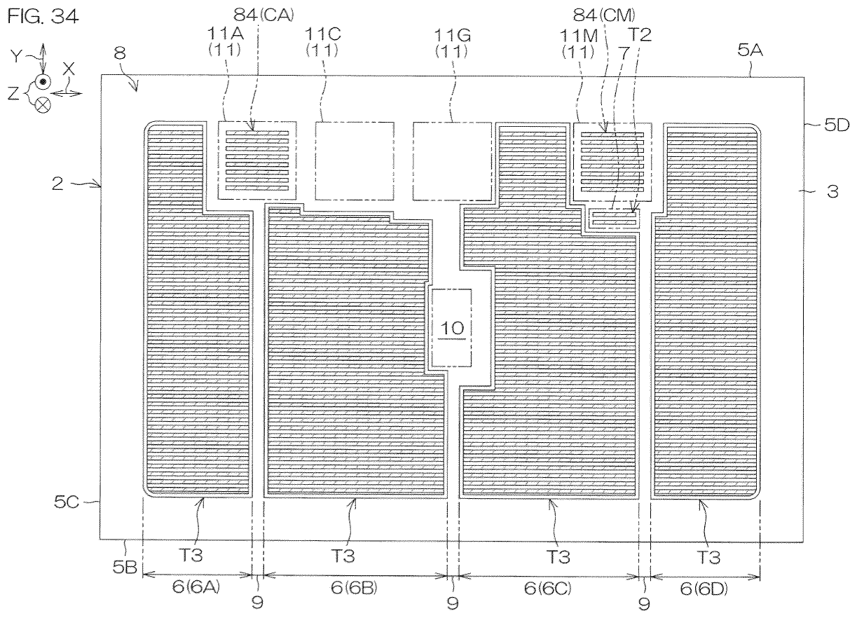

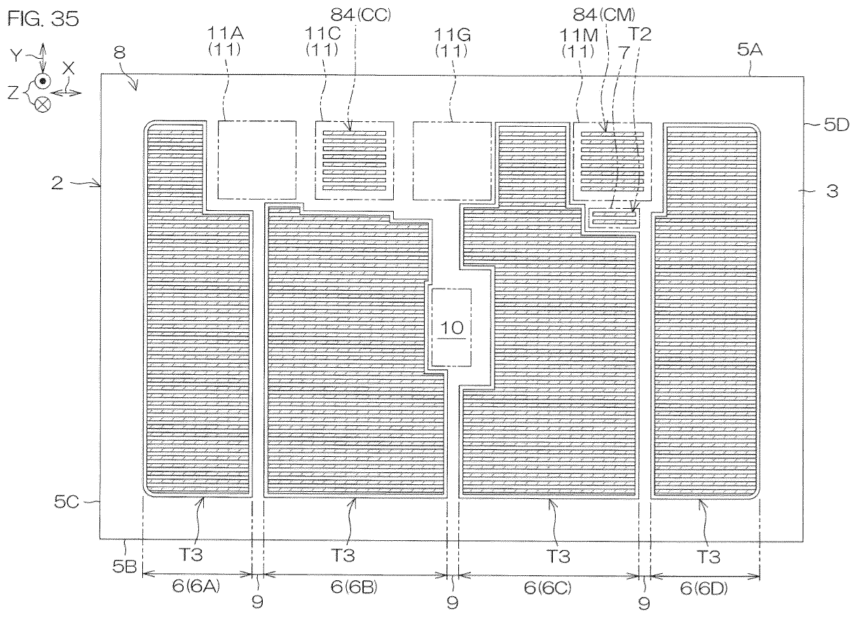

Referring to FIG. 33 (first modification example), the semiconductor devices 1A to 1F not having the monitor capacitor structure CM may be adopted. Referring to FIG. 34 (second modification example), the semiconductor devices 1A to 1F not having the anode capacitor structure CA may be adopted. Referring to FIG. 35 (third modification example), the semiconductor devices 1A to 1F not having the cathode capacitor structure CC may be adopted.

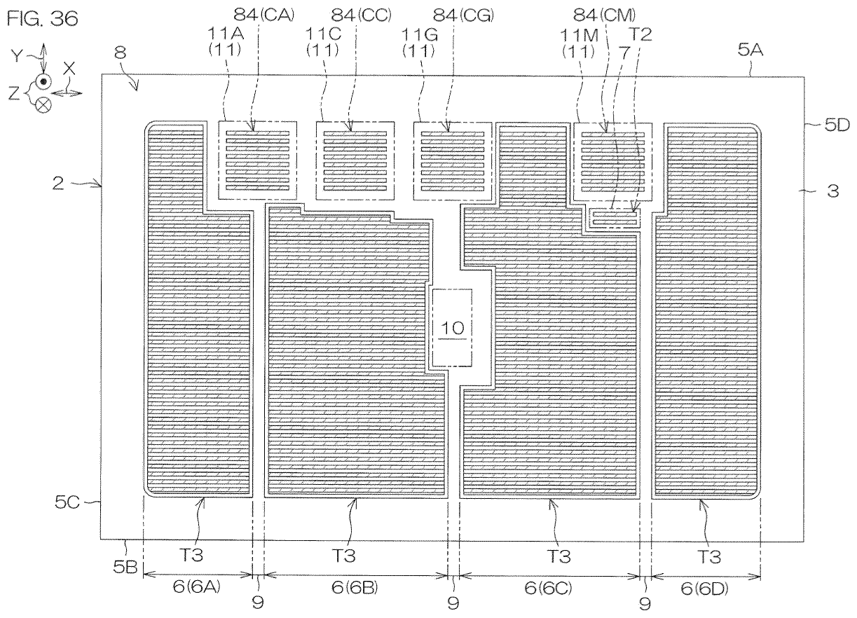

Referring to FIG. 36 (fourth modification example), the semiconductor devices 1A to 1F may include a gate capacitor structure CG as the pad capacitor structure 84 formed in the gate pad region 11G. A gate potential is to be applied to the gate capacitor structure CG.

The gate capacitor structure CG has the same arrangement as the anode capacitor structure CA, etc. The arrangement of the gate capacitor structure CG is obtained by replacing the “anode capacitor structure CA” with the “gate capacitor structure CG” and replacing the “anode pad region 11A” with the “gate pad region 11G” in the above description.

As a matter of course, the gate capacitor structure CG may have at least one feature of the pad capacitor structures 84 (see FIG. 18A to FIG. 18R) according to the first to nineteenth layout examples. Also, the gate capacitor structure CG may have at least one feature of the pad openings 91 (see FIG. 19A to FIG. 19F) according to the first to seventh layout examples. The above-described gate pad GP is electrically connected to the gate capacitor structure CG.

The embodiments (including the modification examples) described above can be implemented in yet other forms. For example, in each of the above-described embodiments (including the modification examples), an arrangement not having the monitor region 7 (the monitor transistor structure T2) but having the active region 6 (the transistor structure T3) and the temperature detecting region 10 (the temperature sensitive diode structure D) may be adopted.

In each of the above-described embodiments, an arrangement not having the temperature detecting region 10 (the temperature sensitive diode structure D) but having the active region 6 (the transistor structure T3) and the monitor region 7 (the monitor transistor structure T2) may be adopted.

In each of the above-described embodiments (including the modification examples), an arrangement not having the active region 6 (the transistor structure T3) but having one of both of the monitor region 7 (the monitor transistor structure T2) and the temperature detecting region 10 (the temperature sensitive diode structure D) may be adopted.

In the embodiment described above, a structure in which the conductivity type of a semiconductor region of the “n-type” is inverted to the “p-type” and the conductivity type of a semiconductor region of the “p-type” is inverted to the “n-type” may be adopted. The specific arrangement in this case is obtained by replacing “n-type” with “p-type” and replacing “p-type” with “n-type” at the same time in the above description and attached drawings.

In the above-described embodiments, the collector region 14 may be removed. In this case, the main transistor structure T1 (the transistor structure T3) includes an MISFET structure instead of the IGBT structure.

The specific arrangement in this case is obtained by replacing the “emitter” of the IGBT structure with a “source” of the MISFET structure and replacing the “collector” of the IGBT structure with a “drain” of the MISFET structure in the above description. In this case, the chip 2 may have a laminated structure including an n-type semiconductor substrate on the second main surface 4 side and an n-type epitaxial layer on the first main surface 3 side.

Hereinafter, examples of features extracted from the present description and the drawings shall be indicated below. Hereinafter, the alphanumeric characters, etc., in parentheses represent the corresponding constituent elements, etc., in the embodiment described above, but are not intended to limit the scope of each clause to the embodiment. The “semiconductor device” in the following clauses may be replaced with a “SiC semiconductor device,” a “wide bandgap semiconductor device,” “a semiconductor switching device,” an “IGBT device,” an “RC-IGBT device,” an “MISFET device,” a “semiconductor rectifier,” etc., as needed.

[A1] A semiconductor device (1A to 1F) comprising: a chip (2) having a main surface (3); an active region (6, 6A to 6D) provided in the main surface (3); a pad region (11, 11A, 11C, 11G, 11M) provided outside the active region (6, 6A to 6D) in the main surface (3); a transistor structure (T1, T3) of an insulated gate type formed in the main surface (3) in the active region (6, 6A to 6D); a capacitor structure (85, 85A, 85B) of a trench electrode type that is formed in the main surface (3) in the pad region (11, 11A, 11C, 11G, 11M) and forms capacitive coupling with the chip (2); and a pad electrode (95, GP, MP, AP, CaP) that is arranged on the main surface (3) in the pad region (11, 11A, 11C, 11G, 11M) and is electrically connected to the capacitor structure (85, 85A, 85B).

[A2] The semiconductor device (1A to 1F) according to A1, wherein the transistor structure (T1, T3) includes a gate structure (20) of a trench electrode type to which a gate potential is to be applied; and wherein the pad electrode (95, GP, MP, AP, CaP) applies a potential other than the gate potential to the capacitor structure (85, 85A, 85B).

[A3] The semiconductor device (1A to 1F) according to A2, wherein the capacitor structure (85, 85A, 85B) has a depth equal to a depth of the gate structure (20).

[A4] The semiconductor device (1A to 1F) according to any one of A1 to A3, wherein the transistor structure (T1, T3) includes an emitter structure (30) of a trench electrode type to which an emitter potential is to be applied; and wherein the pad electrode (95, GP, MP, AP, CaP) applies a potential other than the emitter potential to the capacitor structure (85, 85A, 85B).

[A5] The semiconductor device (1A to 1F) according to A4, wherein the capacitor structure (85, 85A, 85B) has a depth equal to a depth of the emitter structure (30).

[A6] The semiconductor device (1A to 1F) according to any one of A1 to A5, further comprising: a monitor region (7) provided outside the active region (6, 6A to 6D) in the main surface (3); and a monitor transistor structure (T2) for current monitoring formed in the main surface (3) in the monitor region (7), wherein a potential with respect to the monitor transistor structure (T2) is to be applied to the pad electrode (95, GP, MP, AP, CaP).

[A7] The semiconductor device (1A to 1F) according to A6, further comprising: a monitor electrode (67) electrically connected to the monitor transistor structure (T2) on the main surface (3) in the monitor region (7), wherein the pad electrode (95, GP, MP, AP, CaP) is electrically connected to the monitor electrode (67) and applies a potential to the monitor transistor structure (T2) via the monitor electrode (67).

[A8] The semiconductor device (1A to 1F) according to any one of A1 to A5, further comprising: a diode region (10) provided outside the active region (6, 6A to 6D) in the main surface (3); and a diode structure (D) formed in the main surface (3) in the diode region (10), wherein a potential with respect to the diode structure (D) is to be applied to the pad electrode (95, GP, MP, AP, CaP).

[A9] The semiconductor device (1A to 1F) according to A8, further comprising: a wiring (75, 76) electrically connected to the diode structure (D) on the main surface (3), wherein the pad electrode (95, GP, MP, AP, CaP) is electrically connected to the wiring (75, 76) and applies a potential to the diode structure (D) via the wiring (75, 76).

[A10] The semiconductor device (1A to 1F) according to any one of A1 to A9, further comprising: a main surface insulating film (48) covering the main surface (3) in the pad region (11, 11A, 11C, 11G, 11M); and an electrode film (90) that covers the capacitor structure (85, 85A, 85B) on the main surface insulating film (48) and forms capacitive coupling with the chip (2) via the main surface insulating film (48), wherein the pad electrode (95, GP, MP, AP, CaP) is arranged on the electrode film (90) and is electrically connected to the capacitor structure (85, 85A, 85B) via the electrode film (90).

[A11] The semiconductor device (1A to 1F) according to A10, further comprising: an interlayer film (57) with an insulating property covering the electrode film (90); and a pad opening (91) formed in the interlayer film (57) so as to expose the electrode film (90), wherein the pad electrode (95, GP, MP, AP, CaP) is arranged on the interlayer film (57) and is electrically connected to the electrode film (90) via the pad opening (91).

[A12] The semiconductor device (1A to 1F) according to any one of A1 to A9, wherein the capacitor structure (85, 85A, 85B) includes a trench (86) formed in the main surface (3), an insulating film (87) covering a wall surface of the trench (86), and an embedded electrode (88) forming capacitive coupling with the chip (2) via the insulating film (87) in the trench (86).

[A13] The semiconductor device (1A to 1F) according to A12, further comprising: a main surface insulating film (48) covering the main surface (3) in the pad region (11, 11A, 11C, 11G, 11M) so as to be connected to the insulating film (87); and an electrode film (90) that is arranged on the main surface insulating film (48) so as to be connected to the embedded electrode (88) and forms capacitive coupling with the chip (2) via the main surface insulating film (48), wherein the pad electrode (95, GP, MP, AP, CaP) is arranged on the electrode film (90) and is electrically connected to the embedded electrode (88) via the electrode film (90).

[A14] The semiconductor device (1A to 1F) according to any one of A1 to A13, further comprising: a semiconductor region (12) of a first conductivity type (n-type) formed in the chip (2) in the pad region (11, 11A, 11C, 11G, 11M); and a well region (80) of a second conductivity type (p-type) that is formed in a surface layer portion of the main surface (3) in the pad region (11, 11A, 11C, 11G, 11M) and is electrically connected to the semiconductor region (12), wherein the capacitor structure (85, 85A, 85B) is arranged in the well region (80) and forms capacitive coupling with the well region (80).

[A15] The semiconductor device (1A to 1F) according to A14, wherein the capacitor structure (85, 85A, 85B) is positioned in the well region (80) at an interval toward the main surface (3) side from a bottom portion of the well region (80).

[A16] The semiconductor device (1A to 1F) according to A14 or A15, further including: the semiconductor region (12) formed in the chip (2) in the active region (6, 6A to 6D); and a channel region (15) of a second conductivity type (p-type) that is formed in a surface layer portion of the main surface (3) in the active region (6, 6A to 6D) and is electrically connected to the semiconductor region (12), wherein the well region (80) is formed deeper than the channel region (15).

[A17] A semiconductor device (1A to 1F) comprising: a chip (2) having a main surface (3); an active region (6, 6A to 6D) provided in the main surface (3); a pad region (11, 11A, 11C, 11G, 11M) provided outside the active region (6, 6A to 6D) in the main surface (3); a transistor structure (T1, T3) formed in the active region (6, 6A to 6D); a main surface insulating film (48) that has a portion covering the main surface (3) in the pad region (11, 11A, 11C, 11G, 11M) and has a thickness of not less than 10 nm and not more than 200 nm; an electrode film (90) that is arranged on the main surface insulating film (48) in the pad region (11, 11A, 11C, 11G, 11M) and forms capacitive coupling with the chip (2) via the main surface insulating film (48); and a pad electrode (95, GP, MP, AP, CaP) that is arranged on the electrode film (90) in the pad region (11, 11A, 11C, 11G, 11M) and is electrically connected to the electrode film (90).

[A18] The semiconductor device (1A to 1F) according to A17, further comprising: a well region (80) of a p-type formed in a surface layer portion of the main surface (3) in the pad region (11, 11A, 11C, 11G, 11M), wherein the electrode film (90) forms capacitive coupling with the well region (80) via the main surface insulating film (48).

[A19] The semiconductor device (1A to 1F) according to A18, wherein the transistor structure (T1, T3) includes a channel region (15) of a p-type formed in a surface layer portion of the main surface (3); and wherein the well region (80) is formed deeper than the channel region (15).

[A20] The semiconductor device (1A to 1F) according to any one of A17 to A19, wherein the transistor structure (T1, T3) includes a trench (21) formed in the main surface (3), an insulating film (22) that covers a wall surface of the trench (21) and has a thickness of not less than 10 nm and not more than 200 nm, and an embedded electrode (23) embedded in the trench (21) with the insulating film (22) interposed therebetween; and wherein the main surface insulating film (48) has a portion connected to the insulating film (22) in the active region (6, 6A to 6D).

[B1] A semiconductor device (1A to 1F) comprising: a chip (2) having a main surface (3); an active region (6, 6A to 6D) provided in the main surface (3); a pad region (11, 11A, 11C, 11G, 11M) provided outside the active region (6, 6A to 6D) in the main surface (3); a transistor structure (T1, T3) formed in the main surface (3) in the active region (6, 6A to 6D); and a capacitor structure (85, 85A, 85B) of a trench electrode type that is formed in the main surface (3) in the pad region (11, 11A, 11C, 11G, 11M) and forms capacitive coupling with the chip (2).

[B2] The semiconductor device (1A to 1F) according to B1, wherein the transistor structure (T1, T3) includes a gate structure (20) of a trench electrode type to which a gate potential is to be applied.

[B3] The semiconductor device (1A to 1F) according to B2, wherein a potential other than the gate potential is to be applied to the capacitor structure (85, 85A, 85B).

[B4] The semiconductor device (1A to 1F) according to B2 or B3, wherein the capacitor structure (85, 85A, 85B) has a depth equal to a depth of the gate structure (20).

[B5] The semiconductor device (1A to 1F) according to any one of B1 to B4, wherein the transistor structure (T1, T3) includes an emitter structure (30) of a trench electrode type to which an emitter potential is to be applied.

[B6] The semiconductor device (1A to 1F) according to B5, wherein a potential other than the emitter potential is to be applied to the capacitor structure (85, 85A, 85B).

[B7] The semiconductor device (1A to 1F) according to B5 or B6, wherein the capacitor structure (85, 85A, 85B) has a depth equal to a depth of the emitter structure (30).

[B8] The semiconductor device (1A to 1F) according to any one of B1 to B7, further comprising: a monitor region (7) provided outside the active region (6, 6A to 6D) in the main surface (3); and a monitor transistor structure (T2) for current monitoring formed in the main surface (3) in the monitor region (7), wherein a potential with respect to the monitor transistor structure (T2) is to be applied to the capacitor structure (85, 85A, 85B).

[B9] The semiconductor device (1A to 1F) according to any one of B1 to B7, further comprising: a diode region (10) provided outside the active region (6, 6A to 6D) in the main surface (3); and a diode structure (D) formed in the main surface (3) in the diode region (10), wherein a potential with respect to the diode structure (D) is to be applied to the capacitor structure (85, 85A, 85B).

[B10] The semiconductor device (1A to 1F) according to any one of B1 to B9, further comprising: an interlayer film (57) with an insulating property covering the capacitor structure (85, 85A, 85B); a via electrode (92) embedded in the interlayer film (57) so as to be electrically connected to the capacitor structure (85, 85A, 85B); and a pad electrode (95, GP, MP, AP, CaP) that is arranged on the interlayer film (57) and is electrically connected to the capacitor structure (85, 85A, 85B) via the via electrode (92).

[B11] The semiconductor device (1A to 1F) according to B10, wherein the via electrode (92) is connected to the capacitor structure (85, 85A, 85B) in a region further to a bottom wall side of the capacitor structure (85, 85A, 85B) than a height position of the main surface (3).

[B12] The semiconductor device (1A to 1F) according to any one of B1 to B9, wherein the capacitor structure (85, 85A, 85B) includes a trench (86) formed in the main surface (3), an insulating film (87) covering a wall surface of the trench (86), and an embedded electrode (88) forming capacitive coupling with the chip (2) via the insulating film (87) in the trench (86).

[B13] The semiconductor device (1A to 1F) according to B12, further comprising: an interlayer film (57) with an insulating property covering the capacitor structure (85, 85A, 85B); a via electrode (92) embedded in the interlayer film (57) so as to be electrically connected to the embedded electrode (88); and a pad electrode (95, GP, MP, AP, CaP) that is arranged on the interlayer film (57) and is electrically connected to the embedded electrode (88) via the via electrode (92).

[B14] The semiconductor device (1A to 1F) according to B13, wherein the embedded electrode (88) has an electrode surface positioned on a bottom wall side of the trench (86) with respect to a height position of the main surface (3); wherein the interlayer film (57) has a portion covering the electrode surface of the embedded electrode (88) in the trench (86); and wherein the via electrode (92) is mechanically and electrically connected to the embedded electrode (88) in the trench (86).

[B15] The semiconductor device (1A to 1F) according to B13 or B14, further comprising:
a main surface insulating film (48) covering the main surface (3) in the pad region (11, 11A, 11C, 11G, 11M) so as to be connected to the insulating film (87), wherein the interlayer film (57) covers the main surface insulating film (48).

[B16] The semiconductor device (1A to 1F) according to any one of B1 to B15, further comprising: a semiconductor region (12) of a first conductivity type (n-type) formed in the chip (2) in the pad region (11, 11A, 11C, 11G, 11M); and a well region (80) of a second conductivity type (p-type) that is formed in a surface layer portion of the main surface (3) in the pad region (11, 11A, 11C, 11G, 11M) and is electrically connected to the semiconductor region (12), wherein the capacitor structure (85, 85A, 85B) is arranged in the well region (80) and forms capacitive coupling with the well region (80).

[B17] The semiconductor device (1A to 1F) according to B16, wherein the capacitor structure (85, 85A, 85B) is positioned in the well region (80) at an interval toward the main surface (3) side from a bottom portion of the well region (80).

[B18] The semiconductor device (1A to 1F) according to B16 or B17, further comprising: a channel region (15) of a second conductivity type (p-type) that is formed in a surface layer portion of the main surface (3) in the active region (6, 6A to 6D) and is electrically connected to the semiconductor region (12), wherein the well region (80) is formed deeper than the channel region (15).

[B19] A semiconductor device (1A to 1F) comprising: a chip (2) having a main surface (3); an active region (6, 6A to 6D) provided in the main surface (3); a pad region (11, 11A, 11C, 11G, 11M) provided outside the active region (6, 6A to 6D) in the main surface (3); a transistor structure (T1, T3) of an insulated gate type formed in the active region (6, 6A to 6D); a trench (86) formed in the main surface (3) in the pad region (11, 11A, 11C, 11G, 11M); a dielectric film (87) covering a wall surface of the trench (86); and an embedded electrode (88) that forms capacitive coupling with the chip (2) via the dielectric film (87) in the trench (86) and to which a potential other than a gate potential is to be applied.

[B20] The semiconductor device (1A to 1F) according to B19, further comprising: a well region (80) of a p-type formed in a surface layer portion of the main surface (3) in the pad region (11, 11A, 11C, 11G, 11M), wherein the embedded electrode (88) forms capacitive coupling with the well region (80) via the dielectric film (87).

[C1] A semiconductor device (1A to 1F) comprising: a chip (2) having a main surface (3); a diode region (10) provided in the main surface (3); a pad region (11, 11A, 11C) provided outside the diode region (10) in the main surface (3); a diode structure (D) formed in the diode region (10); and a capacitor structure (85, 85A, 85B) of a trench electrode type that is formed in the main surface (3) in the pad region (11, 11A, 11C) and forms capacitive coupling with the chip (2).

[C2] The semiconductor device (1A to 1F) according to C1, further comprising: a pad electrode (95, AP, CaP) that is arranged on the main surface (3) in the pad region (11, 11A, 11C) and is electrically connected to the capacitor structure (85, 85A, 85B).

[D1] A semiconductor device (1A to 1F) comprising: a chip (2) having a main surface (3); a monitor region (7) provided in the main surface (3); a pad region (11, 11M) provided outside the monitor region (7) in the main surface (3); a monitor transistor structure (TM) of an insulated gate type for current monitoring formed in the monitor region (7); and a capacitor structure (85, 85A, 85B) of a trench electrode type that is formed in the main surface (3) in the pad region (11, 11M) and forms capacitive coupling with the chip (2).

[D2] The semiconductor device (1A to 1F) according to D1, further comprising: a pad electrode (95, MP) that is arranged on the main surface (3) in the pad region (11, 11M) and is electrically connected to the capacitor structure (85, 85A, 85B).

While a specific embodiment of the present invention has been described in detail above, this is merely a specific example used to clarify the technical contents. The various technical ideas extracted from this Description and the attached drawings can be combined as appropriate with each other without being limited by the order of description, the order of configuration examples, the order of modification examples, etc., in this Description.

What is claimed is:

1. A semiconductor device comprising:
a chip having a main surface;
an active region provided in the main surface;
a pad region provided outside the active region in the main surface;
a transistor structure formed in the main surface in the active region; and
a capacitor structure of a trench electrode type that is formed in the main surface in the pad region and forms capacitive coupling with the chip.

2. The semiconductor device according to claim 1,
wherein the transistor structure includes a gate structure of a trench electrode type to which a gate potential is to be applied.

3. The semiconductor device according to claim 2,
wherein a potential other than the gate potential is to be applied to the capacitor structure.

4. The semiconductor device according to claim 2,
wherein the capacitor structure has a depth equal to a depth of the gate structure.

5. The semiconductor device according to claim 1,
wherein the transistor structure includes an emitter structure of a trench electrode type to which an emitter potential is to be applied.

6. The semiconductor device according to claim 5,
wherein a potential other than the emitter potential is to be applied to the capacitor structure.

7. The semiconductor device according to claim 5,
wherein the capacitor structure has a depth equal to a depth of the emitter structure.

8. The semiconductor device according to claim 1, further comprising:
a monitor region provided outside the active region in the main surface; and
a monitor transistor structure for current monitoring formed in the main surface in the monitor region;
wherein a potential with respect to the monitor transistor structure is to be applied to the capacitor structure.

9. The semiconductor device according to claim 1, further comprising:
a diode region provided outside the active region in the main surface; and
a diode structure formed in the main surface in the diode region;
wherein a potential with respect to the diode structure is to be applied to the capacitor structure.

10. The semiconductor device according to claim 1, further comprising:
an interlayer film with an insulating property covering the capacitor structure;
a via electrode embedded in the interlayer film so as to be electrically connected to the capacitor structure; and
a pad electrode that is arranged on the interlayer film and is electrically connected to the capacitor structure via the via electrode.

11. The semiconductor device according to claim 10,
wherein the via electrode is connected to the capacitor structure in a region further to a bottom wall side of the capacitor structure than a height position of the main surface.

12. The semiconductor device according to claim 1,
wherein the capacitor structure includes a trench formed in the main surface, an insulating film covering a wall surface of the trench, and an embedded electrode forming capacitive coupling with the chip via the insulating film in the trench.

13. The semiconductor device according to claim 12, further comprising:
an interlayer film with an insulating property covering the capacitor structure;
a via electrode embedded in the interlayer film so as to be electrically connected to the embedded electrode; and
a pad electrode that is arranged on the interlayer film and is electrically connected to the embedded electrode via the via electrode.

14. The semiconductor device according to claim 13,
wherein the embedded electrode has an electrode surface positioned on a bottom wall side of the trench with respect to a height position of the main surface,
the interlayer film has a portion covering the electrode surface of the embedded electrode in the trench, and
the via electrode is mechanically and electrically connected to the embedded electrode in the trench.

15. The semiconductor device according to claims 13, further comprising:
a main surface insulating film covering the main surface in the pad region so as to be connected to the insulating film;
wherein the interlayer film covers the main surface insulating film.

16. The semiconductor device according to claim 1, further comprising:
a semiconductor region of a first conductivity type formed in the chip in the pad region; and
a well region of a second conductivity type that is formed in a surface layer portion of the main surface in the pad region and is electrically connected to the semiconductor region;
wherein the capacitor structure is arranged in the well region and forms capacitive coupling with the well region.

17. The semiconductor device according to claim 16,
wherein the capacitor structure is positioned in the well region at an interval toward the main surface side from a bottom portion of the well region.

18. The semiconductor device according to claim 16, further comprising:
a channel region of a second conductivity type that is formed in the surface layer portion of the main surface in the active region and is electrically connected to the semiconductor region;
wherein the well region is formed deeper than the channel region.

19. A semiconductor device comprising:
a chip having a main surface;
an active region provided in the main surface;
a pad region provided outside the active region in the main surface;
a transistor structure of an insulated gate type formed in the active region;
a trench formed in the main surface in the pad region;
a dielectric film covering a wall surface of the trench; and
an embedded electrode that forms capacitive coupling with the chip via the dielectric film in the trench and to which a potential other than a gate potential is to be applied.

20. The semiconductor device according to claim 19, further comprising:
a well region of a p-type formed in a surface layer portion of the main surface in the pad region;
wherein the embedded electrode forms capacitive coupling with the well region via the dielectric film.
